(19) United States
(12) Patent Application Publication
(10) Pub. No.: US 2025/0123558 A1
(43) Pub. Date: Apr. 17, 2025

(54) PHOTOSENSITIVE COMPOSITION, TRANSFER FILM, LAMINATE AND MANUFACTURING METHOD THEREOF, AND MICRO LED DISPLAY

(71) Applicant: FUJIFILM Corporation, Tokyo (JP)

(72) Inventors: Masaya SUZUKI, Kanagawa (JP); Masatoshi Mizumura, Kanagawa (JP); Kentaro Toyooka, Kanagawa (JP); Daisuke Arioka, Kanagawa (JP)

(73) Assignee: FUJIFILM Corporation, Tokyo (JP)

(21) Appl. No.: 19/002,229

(22) Filed: Dec. 26, 2024

Related U.S. Application Data
(63) Continuation of application No. PCT/JP2023/020176, filed on May 30, 2023.

(30) Foreign Application Priority Data
Jun. 30, 2022 (JP) 2022-106690
Feb. 3, 2023 (JP) 2023-015691

(51) Int. Cl. G03F 7/004; C09K 9/02; G03F 7/028; H10H 29/24

(52) U.S. Cl. CPC G03F 7/0045; C09K 9/02; G03F 7/028; C09K 2211/1018; H10H 29/24

(57) ABSTRACT

Provided are a photosensitive composition containing a coloring material precursor which colors black by a stimulus; and a transfer film, a laminate, a manufacturing method of the laminate, and a micro LED display, each of which uses the photosensitive composition.

### CROSS-REFERENCE TO RELATED APPLICATIONS

This application is a continuation application of International Application No. PCT/JP2023/020176, filed May 30, 2023, the disclosure of which is incorporated herein by reference in its entirety. Further, this application claims priority from Japanese Patent Application No. 2022-106690, filed Jun. 30, 2022, and Japanese Patent Application No. 2023-015691, filed Feb. 3, 2023, the disclosures of which are incorporated herein by reference in their entirety.

### BACKGROUND OF THE INVENTION

### 1. Field of the Invention

The present disclosure relates to a photosensitive composition, a transfer film, a laminate and a manufacturing method thereof, and a micro LED display.

### 2. Description of the Related Art

In recent years, there has been a demand for a black partition wall (so-called black matrix) having a high aspect ratio in a new display manufacturing method, such as a micro light emission diode (LED).

Various reports have been made regarding the black matrix, and for example, JP2022-63445A discloses a technique for forming the black matrix using a photosensitive coloring composition containing carbon black as a coloring material.

### SUMMARY OF THE INVENTION

However, in a case where carbon black is used as a coloring material and, for example, a black matrix of a negative pattern is formed, the carbon black absorbs light to which the carbon black is exposed (for example, ultraviolet rays), and thus incidence ray is gradually attenuated in a film thickness direction of a composition layer for forming a pattern, and a pattern having a favorable shape is hardly obtained after development due to insufficient polymerization curing. Therefore, during pattern exposure, a technique is required that can suppress absorption of the incidence ray and can transmit the incidence ray, and finally form a pattern having excellent light shielding properties.

The present disclosure has been made in view of the above-described circumstances.

An object to be achieved by one embodiment of the present disclosure is to provide a photosensitive composition which is capable of forming a film having excellent light shielding properties and has excellent patterning properties.

An object to be achieved by another embodiment of the present disclosure is to provide a transfer film using the above-described photosensitive composition, a laminate and a manufacturing method thereof, and a micro LED display.

Specific methods for achieving the above-described objects include the following aspects.

<1> A photosensitive composition comprising:
a coloring material precursor which colors black by a stimulus.

<2> The photosensitive composition according to <1>,
in which the stimulus is at least one selected from the group consisting of heat, light, acid, base, and radical.

<3> The photosensitive composition according to <1>,
in which the stimulus is heat.

<4> The photosensitive composition according to any one of <1> to <3>, further comprising:
an alkali-soluble resin;
a polymerizable monomer; and
a photopolymerization initiator.

<5> The photosensitive composition according to any one of <1> to <4>,
in which, in a case where a film having a film thickness of 1 μm is formed of the photosensitive composition, an absorbance of the film at a wavelength of 365 nm is 0.1 or less.

<6> The photosensitive composition according to any one of <1> to <5>,
in which, in a case where a black film having a film thickness of 1 μm is formed of the photosensitive composition by coloring the coloring material precursor by the stimulus in black, an absorbance of the film at a wavelength of 365 nm is 0.2 or more.

<7> The photosensitive composition according to any one of <1> to <6>,
in which, in a case where a black film having a film thickness of 1 μm is formed of the photosensitive composition by coloring the coloring material precursor by the stimulus in black, an average absorbance of the film in a wavelength of 400 nm to 700 nm is 0.2 or more.

<8> The photosensitive composition according to any one of <1> to <7>,
in which the coloring material precursor is a compound represented by Formula (1).

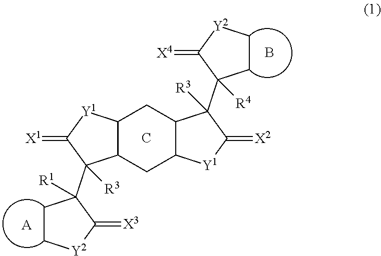

In Formula (1), X¹, X², X³, X⁴, Y¹, and Y² each independently represent an oxygen atom, a sulfur atom, or N-L¹, L¹ represents a hydrogen atom, an alkyl group, an acyl group, an alkoxycarbonyl group, or an aminocarbonyl group, R¹, R², R³, and R⁴ each independently represent a hydrogen atom, —O-L², —OCO-L³, —S-L², or —OSO-L³, L² represents a hydrogen atom or an alkyl group and L³ represents an alkyl group or an amino group, provided that at least one of R¹ or R² represents a hydrogen atom and at least one of R³ or R⁴ represents a hydrogen atom, and A, B, and C each independently represent an aromatic ring.

<9> A photosensitive composition comprising:
a coloring material precursor which colors black by at least one stimulus selected from the group consisting of heat, light, acid, base, and radical;
an alkali-soluble resin;
a polymerizable monomer; and
a photopolymerization initiator,
in which all of the following (1) to (3) are satisfied,
(1) in a case where a film having a film thickness of 1 μm is formed of the photosensitive composition, an absorbance of the film at a wavelength of 365 nm is 0.1 or less,
(2) in a case where a black film having a film thickness of 1 μm is formed of the photosensitive composition by coloring the coloring material precursor by the stimulus in black, an absorbance of the film at a wavelength of 365 nm is 0.2 or more,
(3) in a case where a black film having a film thickness of 1 μm is formed of the photosensitive composition by coloring the coloring material precursor by the stimulus in black, an average absorbance of the film in a wavelength of 400 nm to 700 nm is 0.2 or more.

<10> The photosensitive composition according to <9>,
in which the coloring material precursor is a compound represented by Formula (1).

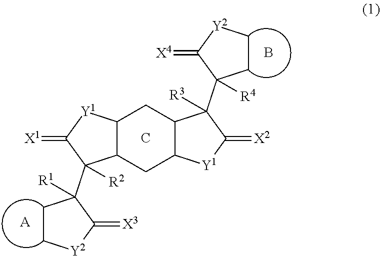

In Formula (1), X¹, X², X³, X⁴, Y¹, and Y² each independently represent an oxygen atom, a sulfur atom, or N-L¹, L¹ represents a hydrogen atom, an alkyl group, an acyl group, an alkoxycarbonyl group, or an aminocarbonyl group, R¹, R², R³, and R⁴ each independently represent a hydrogen atom, —O-L², —OCO-L³, —S-L², or —OSO-L³, L² represents a hydrogen atom or an alkyl group and L³ represents an alkyl group or an amino group, provided that at least one of R¹ or R² represents a hydrogen atom and at least one of R³ or R⁴ represents a hydrogen atom, and A, B, and C each independently represent an aromatic ring.

<11> A transfer film comprising:
a temporary support; and
a photosensitive composition layer containing the photosensitive composition according to any one of <1> to <10>.

<12> The transfer film according to <11>,
in which a film thickness of the photosensitive composition layer is 5 μm or more.

<13> A manufacturing method of a laminate having a black pattern, the manufacturing method comprising, in the following order:
a step of forming a photosensitive composition layer containing the photosensitive composition according to any one of <1> to <10> on a base material;
a step of performing pattern exposure on the photosensitive composition layer; and
a step of developing the photosensitive composition layer,
in which the manufacturing method further includes, after the pattern exposure step, a step of coloring the coloring material precursor in black.

<14> The manufacturing method of a laminate according to <13>,
in which a film thickness of the black pattern is 5 μm or more.

<15> A laminate having a black pattern, which is a laminate manufactured by the manufacturing method of a laminate according to <13> or <14>.

<16> The laminate according to <15>,
in which a film thickness of the black pattern is 5 μm or more.

<17> The laminate according to <15> or <16>,
in which an absorbance of the black pattern at a wavelength of 365 nm is 2.0 or more.

<18> The laminate according to any one of <15> to <17>,
in which an average absorbance of the black pattern in a wavelength of 400 nm to 700 nm is 2.0 or more.

<19> The laminate according to any one of <15> to <18>,
in which an aspect ratio of the black pattern, which is a ratio of a film thickness to a line width of a bottom portion, is 1.0 or more.

<20> A laminate comprising:
a base material; and
a black pattern,
in which a film thickness of the black pattern is 5 μm or more,
an aspect ratio of the black pattern, which is a ratio of a film thickness to a line width of a bottom portion, is 1.0 or more, and
an average absorbance in a wavelength of 400 nm to 700 nm is 2.0 or more.

<21> The laminate according to <20>,
in which a ratio of the black pattern of a line width of an uppermost portion to a line width of a bottom portion is 0.8 to 1.2.

<22> The laminate according to <20> or <21>,
in which the black pattern contains a coloring material represented by Formula (I).

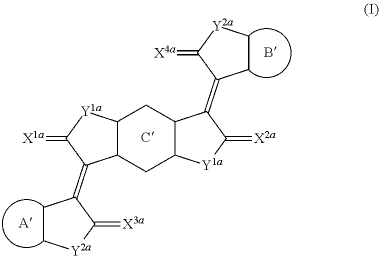

In Formula (I), X^{1a}, X^{2a}, X^{3a}, X⁴a, Y^{1a}, and Y^{2a} each independently represent an oxygen atom, a sulfur atom, or N-L^{1a}, L^{1a} represents a hydrogen atom, an alkyl group, an acyl group, an alkoxycarbonyl group, or an aminocarbonyl group, and A′, B′, and C′ each independently represent an aromatic ring.

<23> A micro LED display comprising:
the laminate according to <20> or <21>.

According to one embodiment of the present disclosure, there is provided a photosensitive composition which is capable of forming a film having excellent light shielding properties and has excellent patterning properties.

According to another embodiment of the present disclosure, there are provided a transfer film using the above-described photosensitive composition, a laminate and a manufacturing method thereof, and a micro LED display.

### DESCRIPTION OF THE PREFERRED EMBODIMENTS

Hereinafter, the present disclosure will be described in detail. The description of the requirements set forth below may be based on representative embodiments of the present disclosure, but the present disclosure is not limited to such embodiments. Within the scope of the purpose of the present disclosure, modifications can be made as appropriate.

In the present disclosure, a numerical range expressed using “to” means a range including numerical values before and after “to” as a lower limit value and an upper limit value.

In a numerical range described in a stepwise manner in the present disclosure, an upper limit or a lower limit described in a certain numerical range may be replaced with an upper limit or a lower limit in another numerical range described in a stepwise manner. In addition, in a numerical range described in the present disclosure, an upper limit or a lower limit described in a certain numerical range may be replaced with a value described in Examples.

In the present disclosure, upon referring to an amount of each component in a composition, the amount means a total amount of a plurality of components present in the composition unless otherwise specified, in a case where a plurality of substances corresponding to individual components are present in the composition.

In the present disclosure, a combination of two or more preferred aspects is a more preferred aspect.

In the present disclosure, a term “step” includes not only an independent step but also a step whose intended purpose is achieved even in a case where the step is not clearly distinguished from other steps.

In the present disclosure, “transparent” means that an average transmittance of visible light having a wavelength of 400 nm to 700 nm is 80% or more, preferably 90% or more.

In the present disclosure, “transmittance” is a value measured using a spectrophotometer. As the spectrophotometer, for example, a spectrophotometer (model number: U-3310) manufactured by Hitachi, Ltd. can be used. However, the spectrophotometer is not limited thereto.

In the present disclosure, a molecular weight of a compound having a molecular weight distribution is a weight-average molecular weight (Mw; the same applies hereinafter), unless otherwise specified.

In the present disclosure, a weight-average molecular weight (Mw) and a number-average molecular weight (Mn) are values measured by gel permeation chromatography (GPC) method, unless otherwise specified.

The values measured by GPC are values in terms of polystyrene measured by a GPC analysis apparatus using TSKgel (registered trademark) GMHxL, TSKgel (registered trademark) G4000HxL, or TSKgel (registered trademark) G2000HxL [all of which are product names manufactured by Tosoh Corporation] as a column, tetrahydrofuran (THF) as an eluent, a differential refractometer as a detector, and polystyrene as a standard substance.

In the present disclosure, a ratio of structural units of a polymer compound is a mass ratio unless otherwise specified.

In the present disclosure, “(meth)acryl” is a term including both “acryl” and “methacryl”; “(meth)acrylate” is a term including both “acrylate” and “methacrylate”; and “(meth)acryloyl” is a term including both “acryloyl” and “methacryloyl”.

In the present disclosure, “alkali-soluble” means that a solubility in 100 g of 1% by mass sodium carbonate aqueous solution at a liquid temperature of 22° C. is 0.1 g or more.

In the present disclosure, “water-soluble” means that a solubility in 100 g of water at a liquid temperature of 22° C. and a pH of 7.0 is 0.1 g or more, and for example, “water-soluble resin” means a resin satisfying the solubility condition.

In the present disclosure, “solid content” in a composition means components which form a composition layer formed of the composition, and in a case where the composition contains a solvent, the “solid content” means all components excluding the solvent. In addition, in a case where a component other than the solvent forms the composition layer, the component is considered to be the solid content even in a case where the component is a liquid component. In the present disclosure, the “solvent” means water and an organic solvent.

In the present disclosure, “n-” means normal, “s-” means secondary, and “t-” means tertiary.

In the present disclosure, “light” refers to, for example, ultraviolet light, visible light, and infrared light.

In the present disclosure, the “ultraviolet rays” refers to light in a wavelength range of 200 nm or more and less than 400 nm, the “visible light” refers to light in a wavelength range of 400 nm or more and less than 780 nm, and the “infrared light” refers to light in a wavelength range of 780 nm or more and less than 1,000 nm.

Regarding a term of a group (atomic group) in the present disclosure, a term with no description of “substituted” and “unsubstituted” includes both a group not having a substituent and a group having a substituent. For example, the concept of “alkyl group” includes not only an alkyl group not having a substituent (unsubstituted alkyl group) but also an alkyl group having a substituent (substituted alkyl group).

The “substituent” in the present disclosure is not particularly limited, and for example, it can be arbitrarily selected from a substituent group consisting of a halogen group, a hydroxy group, an alkyl group, a cycloalkyl group, an alkenyl group, a cycloalkenyl group, an alkynyl group, an aryl group, a heterocyclic group, an alkoxy group, an aryloxy group, a heterocyclicoxy group, a sulfo group, an acyl group, an alkoxycarbonyl group, an aryloxycarbonyl group, a carboxy group, a carbamoyl group, an acyloxy group, a carbamoyloxy group, an alkoxycarbonyloxy group, aryloxycarbonyloxy, a cyano group, a nitro group, an amino group (including an anilino group), an acylamino group, an aminocarbonylamino group, an alkoxycarbonylamino group, an aryloxycarbonylamino group, a sulfamoylamino group, an alkylsulfonylamino group, an arylsulfonylamino group, a mercapto group, an alkylthio group, an arylthio group, a heterocyclicthio group, a sulfamoyl group, an alkylsulfinyl group, an arylsulfinyl group, an alkylsulfonyl group, an arylsulfonyl group, an arylazo group, a heterocyclic azo group, an imide group, a phosphino group, a phosphinyl group, a phosphinyloxy group, and a phosphinylamino group.

More specific examples of the substituent in the present disclosure include:
a halogen group (for example, a fluorine group, a chlorine group, a bromine group, and an iodine group);
an alkyl group (a linear, branched, or cyclic alkyl group having 1 to 10, preferably 1 to 6 carbon atoms; for example, a methyl group, an ethyl group, an n-propyl group, an isopropyl group, a t-butyl group, an n-octyl group, a 2-chloroethyl group, a 2-cyanoethyl group, and a 2-ethylhexyl group);
a cycloalkyl group (for example, a cyclopropyl group or a cyclopentyl group);
an alkenyl group (a linear, branched, or cyclic alkenyl group having 2 to 10, preferably 2 to 6 carbon atoms; for example, a vinyl group, an allyl group, and a prenyl group);
a cycloalkenyl group (for example, a cyclopenten-1-yl group);
an alkynyl group (an alkynyl group having 2 to 10, preferably 2 to 6 carbon atoms; for example, an ethynyl group and a propargyl group);
an aryl group (an aryl group having 6 to 12, preferably 6 to 8 carbon atoms; for example, a phenyl group, a p-tolyl group, a naphthyl group, a 3-chlorophenyl group, and a 2-aminophenyl group);
a heterocyclic group (a monovalent group having 1 to 12, preferably 2 to 6 carbon atoms, which is obtained by removing one hydrogen atom from a 5-membered or 6-membered aromatic or non-aromatic heterocyclic compound; for example, a 1-pyrazolyl group, a 1-imidazolyl group, a 2-furyl group, a 2-thienyl group, a 4-pyrimidinyl group, and a 2-benzothiazolyl group);
a cyano group;
a hydroxy group;
a nitro group;
an alkoxy group (a linear, branched, or cyclic alkoxy group having 1 to 10, preferably 1 to 6 carbon atoms; for example, a methoxy group, an ethoxy group, an isopropoxy group, a t-butoxy group, a cyclopentyloxy group, a 2-buten-1-yloxy group, and a 2-methoxyethoxy group);
an aryloxy group (an aryloxy group having 6 to 12, preferably 6 to 8 carbon atoms; for example, a phenoxy group, a 2-methylphenoxy group, a 4-t-butylphenoxy group, and a 3-nitrophenoxy group);
a heterocyclic oxy group (a heterocyclic oxy group having 1 to 12, preferably 2 to 6 carbon atoms; for example, a 1-phenyltetrazol-5-oxy-2-tetrahydropyranyloxy group);
an acyloxy group (an acyloxy group having 1 to 12, preferably 1 to 8 carbon atoms; for example, a formyloxy group, an acetyloxy group, a pivaloyloxy group, a benzoyloxy group, and a p-methoxycarbonyloxy group);
a carbamoyloxy group (a carbamoyloxy group having 1 to 10, preferably 1 to 6 carbon atoms; for example, an N,N-dimethylcarbamoyloxy group, an N,N-diethylcarbamoyloxy group, a morpholinocarbonyloxy group, and an N,N-octylcarbamoyloxy group);
an alkoxycarbonyloxy group (an alkoxycarbonyloxy group having 2 to 10, preferably 2 to 6 carbon atoms; for example, a methoxycarbonyloxy group, an ethoxycarbonyloxy group, a t-butoxycarbonyloxy group, and an n-octyloxycarbonyloxy group);
an aryloxycarbonyloxy group (an aryloxycarbonyloxy group having 7 to 12, preferably 7 to 10 carbon atoms; for example, a phenoxycarbonyloxy group and a p-methoxyphenoxycarbonyloxy group);
an amino group (including an amino group, an alkylamino group having 1 to 10, preferably 1 to 6 carbon atoms, an anilino group having 6 to 12, preferably 6 to 8 carbon atoms, and a heterocyclic amino group having 1 to 12, preferably 2 to 6 carbon atoms; for example, an amino group, a methylamino group, a dimethylamino group, an anilino group, an N-methyl-anilino group, a diphenylamino group, an imidazol-2-ylamino group, and a pyrazol-3-ylamino group);
an acylamino group (including an alkylcarbonylamino group having 1 to 10, preferably 1 to 6 carbon atoms, an arylcarbonylamino group having 6 to 12, preferably 6 to 8 carbon atoms, and a heterocyclic carbonylamino group having 2 to 12, preferably 2 to 6 carbon atoms; for example, a formylamino group, an acetylamino group, a pivaloylamino group, a benzoylamino group, a pyridine-4-carbonylamino group, and a thiophene-2-carbonylamino group);
an aminocarbonylamino group (an aminocarbonylamino group having 1 to 12, preferably 1 to 6 carbon atoms; for example, a carbamoylamino group, an N,N-dimethylaminocarbonylamino group, an N,N-diethylaminocarbonylamino group, and a morpholin-4-ylcarbonylamino group);
an alkoxycarbonylamino group (an alkoxycarbonylamino group having 2 to 10, preferably 2 to 6 carbon atoms; for example, a methoxycarbonylamino group, an ethoxycarbonylamino group, and a t-butoxycarbonylamino group);
an aryloxycarbonylamino group (an aryloxycarbonylamino group having 7 to 12, preferably 7 to 9 carbon atoms; for example, a phenoxycarbonylamino group, a p-chlorophenoxycarbonylamino group, and a 4-methoxyphenoxycarbonylamino group);
a sulfamoylamino group (a sulfamoylamino group having 0 to 10, preferably 0 to 6 carbon atoms; for example, a sulfamoylamino group, an N,N-dimethylaminosulfonylamino group, and an N-(2-hydroxyethyl) sulfamoylamino group);
an alkylsulfonylamino group (an alkylsulfonylamino group having 1 to 10, preferably 1 to 6 carbon atoms; for example, a methylsulfonylamino group and a butylsulfonylamino group);
an arylsulfonylamino group (an arylsulfonylamino group having 6 to 12, preferably 6 to 8 carbon atoms; for example, a phenylsulfonylamino group, a 2,3,5-trichlorophenylsulfonylamino group, and a p-methylphenylsulfonylamino group);
a mercapto group;
an alkylthio group (an alkylthio group having 1 to 10, preferably 1 to 6 carbon atoms;
for example, a methylthio group, an ethylthio group, and a butylthio group);
an arylthio group (an arylthio group having 6 to 12, preferably 6 to 8 carbon atoms; for example, a phenylthio group, a p-chlorophenylthio group, and a m-methoxythio group);
a heterocyclic thio group (a heterocyclic thio group having 2 to 10, preferably 1 to 6 carbon atoms; for example, a 2-benzothiazolylthio group and a 1-phenyltetrazol-5-ylthio group);
a sulfamoyl group (a sulfamoyl group having 0 to 10, preferably 0 to 6 carbon atoms;
for example, a sulfamoyl group, an N-ethylsulfamoyl group, an N,N-dimethylsulfamoyl group, an N-acetylsulfamoyl group, and an N-benzoylsulfamoyl group);
an alkylsulfinyl group (an alkylsulfinyl group having 1 to 10, preferably 1 to 6 carbon atoms; for example, a methylsulfinyl group and an ethylsulfinyl group);
an arylsulfinyl group (an arylsulfinyl group having 6 to 12, preferably 6 to 8 carbon atoms; for example, a phenylsulfinyl group and a p-methylphenylsulfinyl group);
an alkylsulfonyl group (an alkylsulfonyl group having 1 to 10, preferably 1 to 6 carbon atoms; for example, a methylsulfonyl group and an ethylsulfonyl group);
an arylsulfonyl group (arylsulfonyl group having 6 to 12, preferably 6 to 8 carbon atoms; for example, a phenylsulfonyl group and a p-chlorophenylsulfonyl group);
a sulfo group;
an acyl group (a formyl group, an alkylcarbonyl group having 2 to 10, preferably 2 to 6 carbon atoms, or an arylcarbonyl group having 7 to 12, preferably 7 to 9 carbon atoms; for example, an acetyl group, a pivaloyl group, a 2-chloroacetyl group, a benzoyl group, and a 2,4-dichlorobenzoyl group);
an alkoxycarbonyl group (an alkoxycarbonyl group having 2 to 10, preferably 2 to 6 carbon atoms; for example, a methoxycarbonyl group, an ethoxycarbonyl group, a t-butoxycarbonyl group, and an isobutyloxycarbonyl group);
an aryloxycarbonyl group (an aryloxycarbonyl group having 7 to 12, preferably 7 to 9, carbon atoms; for example, a phenoxycarbonyl-2-chlorophenoxycarbonyl group, a 3-nitrophenoxycarbonyl group, and a 4-t-butylphenoxycarbonyl group);
a carbamoyl group (a carbamoyl group having 1 to 10, preferably 1 to 6 carbon atoms; for example, a carbamoyl group, an N-methylcarbamoyl group, an N,N-dimethylcarbamoyl group, an N-(2-hydroxyethyl) carbamoyl group, and an N-(methylsulfonyl) carbamoyl group);
an arylazo group (an arylazo group having 6 to 12, preferably 6 to 8 carbon atoms; for example, a phenylazo group and a p-chlorophenylazo group);
a heterocyclic azo group (a heterocyclic azo group having 1 to 10, preferably 1 to 6 carbon atoms; for example, a pyrazol-3-ylazo group, a thiazol-2-ylazo group, and a 5-methylthio-1,3,4-thiadiazol-2-ylazo group);
an imido group (an imido group having 2 to 10, preferably 4 to 8 carbon atoms; for example, a succinimido group and a phthalimido group);
a phosphino group (a phosphinyl group having 2 to 12, preferably 2 to 6 carbon atoms;
for example, a dimethylphosphino group, a diphenylphosphino group, and methylphenoxyphosphino group);
a phosphinyl group (a phosphinyl group having 2 to 12, preferably 2 to 6 carbon atoms;
for example, a phosphinyl group and a diethoxyphosphinyl group);
a phosphinyloxy group (a phosphinyloxy group having 2 to 12, preferably 2 to 6 carbon atoms; for example, a diphenoxyphosphinyloxy group and a dibutoxyphosphinyloxy group); and
a phosphinylamino group (a phosphinylamino group having 2 to 12, preferably 2 to 6 carbon atoms; for example, a dimethoxyphosphinylamino group and dimethylaminophosphinylamino group).

In a case where these groups are groups which can be further substituted, these groups can further include a substituent. In a case where two or more of these groups are substituted with a substituent, the substituents may be the same or different from each other.

### [Photosensitive Composition]

The photosensitive composition according to the present disclosure contains a coloring material precursor which colors black by a stimulus.

In the present disclosure, the “coloring material precursor which colors black by a stimulus” is also referred to as “specific coloring material precursor”. Since the photosensitive composition according to the present disclosure contains the specific coloring material precursor, it is possible to form a film having excellent light shielding properties and excellent patterning properties.

As a coloring material used for forming a black matrix, carbon black has been known. However, in a case where a composition containing the carbon black as a coloring material is used and, for example, a black matrix of a negative pattern is formed, the carbon black absorbs light to which the carbon black is exposed (for example, ultraviolet rays), and thus incidence ray is gradually attenuated in a film thickness direction of a composition layer for forming a pattern, and a pattern having a favorable shape is hardly obtained after development due to insufficient polymerization curing.

On the other hand, since the photosensitive composition according to the present disclosure contains a coloring material precursor which colors black by a stimulus, and a timing of coloring can be controlled by a timing of the stimulus, for example, it is possible to perform pattern exposure before coloring of the coloring material precursor black, and to color the coloring material precursor black by the stimulus after the pattern exposure. With the photosensitive composition according to the present disclosure, by performing the pattern exposure before coloring of the coloring material precursor black, absorption of incidence ray can be suppressed and the incidence ray can be transmitted during the pattern exposure, and thus a pattern having a favorable shape can be obtained after development. In addition, by coloring the coloring material precursor in black by a stimulus after the pattern exposure, excellent light shielding properties can be imparted to the pattern.

### <Specific Coloring Material Precursor>

The photosensitive composition according to the present disclosure contains a coloring material precursor which colors black by a stimulus (that is, the specific coloring material precursor).

The “coloring material precursor which colors black by a stimulus” in the present disclosure is preferably a compound which satisfies the following requirement A, requirement B, and requirement C.

### (Requirement A)

In an absorption spectrum measured using a spectrophotometer for a solution in which 1.1 mg of the compound before coloring is dissolved in 50 mL of tetrahydrofuran (THF), an average value of molar absorption coefficients (ε) (so-called average molar absorption coefficient) at any continuous 100 nm in a wavelength range of 400 nm to 700 nm is 400 L/(mol·cm) or less.

In the requirement A, the above-described average molar absorption coefficient is preferably 200 L/(mol·cm) or less, and more preferably 100 L/(mol·cm) or less.

The average value of the molar absorption coefficients (8) at every 100 nm in a wavelength range of 400 nm to 700 nm can be obtained by obtaining the molar absorption coefficient at each wavelength for every 1 nm and calculating an arithmetic mean of the molar absorption coefficients in a continuous range of 100 nm (for example, 421 nm to 520 nm, 560 nm to 659 nm, and the like). The same applies to the requirement C described later.

The expression “the average value of the molar absorption coefficients (E) at any continuous 100 nm in a wavelength range of 400 nm to 700 nm is 400 L/(mol·cm) or less” means that, even in a case where any continuous range of 100 nm in the wavelength range of 400 nm to 700 nm is selected, the average molar absorption coefficient in the continuous range of 100 nm is 400 L/(mol·cm) or less.

### (Requirement B)

In an absorption spectrum measured using a spectrophotometer for a solution in which 1.1 mg of the compound after coloring is dissolved in 50 mL of tetrahydrofuran (THF), a maximal absorption wavelength is present in a wavelength range of 400 nm to 700 nm.

The number of the above-described maximal absorption wavelengths in a wavelength range of 400 nm to 700 nm is preferably 2 or more.

The upper limit of the number of the above-described maximal absorption wavelengths in a wavelength range of 400 nm to 700 nm is not particularly limited, and examples thereof include 10 or less, 5 or less, and 3 or less.

In a case where there are two or more maximal absorption wavelengths in a wavelength range of 400 nm to 700 nm, it is preferable that the two or more maximal absorption wavelength are separated by 100 nm or more, and it is more preferable that the two or more maximal absorption wavelength are separated by 200 nm or more.

Among the above-described maximal absorption wavelengths in a wavelength range of 400 nm to 700 nm, a molar absorption coefficient (8) at a wavelength having the maximum absorption is preferably 3,000 L/(mol·cm) or more, more preferably 4,000 L/(mol·cm) or more, and still more preferably 5,000 L/(mol·cm) or more.

In addition, among the above-described maximal absorption wavelengths in a wavelength range of 400 nm to 700 nm, the molar absorption coefficient (E) at a wavelength having the maximum absorption is preferably 100,000 L/(mol·cm) or less, more preferably 40,000 L/(mol·cm) or less, and still more preferably 20,000 L/(mol·cm) or less.

### (Requirement C)

In an absorption spectrum measured using a spectrophotometer for a solution in which 1.1 mg of the compound after coloring is dissolved in 50 mL of tetrahydrofuran (THF), an average value of molar absorption coefficients (ε) (so-called average molar absorption coefficient) at any continuous 100 nm in a wavelength range of 400 nm to 700 nm is 2,000 L/(mol·cm) or more.

In the requirement C, the above-described average molar absorption coefficient is preferably 3,000 L/(mol·cm) or more, and more preferably 4,000 L/(mol·cm) or more.

The expression “the average value of the molar absorption coefficients (8) at any continuous 100 nm in a wavelength range of 400 nm to 700 nm is 2,000 L/(mol·cm) or more” means that, even in a case where any continuous range of 100 nm in the wavelength range of 400 nm to 700 nm is selected, the average molar absorption coefficient in the continuous range of 100 nm is 2,000 L/(mol·cm) or more.

The “stimulus” in the present disclosure includes both a direct factor and an indirect factor, which cause the coloring material precursor to color black. That is, the stimulus may be a stimulus which directly acts on the coloring material precursor to change a structure of the coloring material precursor to color the coloring material precursor black; or may be a stimulus which acts as a trigger for changing a structure of the coloring material precursor and does not directly act on the coloring material precursor to change the structure of the coloring material precursor.

The stimulus is not particularly limited as long as it can directly or indirectly cause the coloring material precursor to color black.

The stimulus is preferably at least one selected from the group consisting of heat, light, acid, base, and radical, more preferably heat or acid, and still more preferably heat.

The type of the specific coloring material precursor is not particularly limited.

As the specific coloring material precursor, a compound which colors black by acid or a compound which colors black by heat is preferable; a compound which colors black by heat is more preferable; and a compound which colors black by oxidation due to heat (so-called thermal oxidation) is still more preferable.

The compound which colors black by heat is more preferable than the compound which colors black by acid from the viewpoint that inconvenience due to the acid is less likely to occur in a case where the formed film is applied to a device.

Examples of the specific coloring material precursor include a leuco coloring agent compound (so-called leuco dye). The leuco dye is a compound which colors by acid or the like, and specifically, the leuco dye colors by a ring-opened state of a lactone ring in the molecule by a reaction with the acid.

The above-described reaction in the leuco dye is a reversible reaction, and the lactone ring in a ring-opened state is brought into contact with a base to be ring-closed and decolorized.

As the leuco dye, known dyes can be used without particular limitation as long as the dye colors black.

Examples of the leuco dye which colors black include 2′-anilino-6′-(dibutylamino)-3′-methylfluoran, 2′-anilino-3′-methyl-6′-(dipentylamino)spiro[isobenzofran-1 (3H),9′-[9H]xanthene]-3-one, 2′-anilino-6′-dibutylamino-3′-methylspiro[phthalido-3,9′-[9H]xanthene], 2′-anilino-6′-(N-ethyl-N-isopentylamino)-3′-methylspiro[phthalido-3,9′-[9H]xanthene], and 2-(phenylamino)-3-methyl-6-[ethyl(p-tolyl)amino]spiro[9H-xanthene-9,1′ (3′H)-isobenzofran]-3′-one.

Among these, as the leuco dye, 2′-anilino-3′-methyl-6′-(dipentylamino)spiro[isobenzofran-1 (3H),9′-[9H]xanthene]-3-one is preferable.

Examples of a commercially available product of the leuco dye include BLACK 305 (CAS No. 129473-78-5), BLACK 400 (CAS No. 89331-94-2), S-205 (CAS No. 70516-41-5), and ETAC (CAS No. 59129-79-2) manufactured by Fukui Yamada Chemical Co., Ltd.; and 2′-anilino-6′-(dibutylamino)-3′-methylfluoran manufactured by Tokyo Chemical Industry Co., Ltd.

In a case where the photosensitive composition according to the present disclosure contains a leuco dye as the specific coloring material precursor, it is preferable that the photosensitive composition contains a compound which absorbs red and/or green light, from the viewpoint of forming a film having more excellent light shielding properties. Examples of such a compound include compounds such as EXCOLOR series manufactured by Nippon Shokubai Co., Ltd.; and FDG series and FDR series manufactured by Fukui Yamada Chemical Co., Ltd.

In a case where the photosensitive composition according to the present disclosure contains the above-described compound, a content of the above-described compound in the photosensitive composition is not particularly limited and can be appropriately set according to the purpose, and for example, it is preferable to adjust the content such that the average absorbance of the film to be formed in a wavelength of 400 nm to 700 nm is 2.0 or more.

Examples of the specific coloring material precursor include a compound represented by Formula (1).

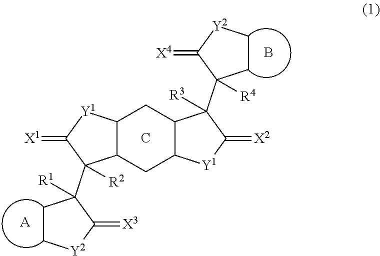

In Formula (1), X¹, X², X³, X⁴, Y¹, and Y² each independently represent an oxygen atom, a sulfur atom, or N-L¹, L¹ represents a hydrogen atom, an alkyl group, an acyl group, an alkoxycarbonyl group, or an aminocarbonyl group, R¹, R², R³, and R⁴ each independently represent a hydrogen atom, —O-L², —OCO-L³, —S-L², or —OSO-L³, L² represents a hydrogen atom or an alkyl group and L³ represents an alkyl group or an amino group, provided that at least one of R¹ or R² represents a hydrogen atom and at least one of R³ or R⁴ represents a hydrogen atom, and A, B, and C each independently represent an aromatic ring.

The compound represented by Formula (1) is a compound which colors black by heat (specifically, thermal oxidation). The mechanism by which the compound represented by Formula (1) colors black is not clear, but the present inventors have considered as follows.

It is considered that the compound represented by Formula (1) reacts with oxygen in the air upon heating, and thus a structure thereof changes to an oxidant, resulting in black coloration. That is, it is considered that the oxidant exhibits black color. Specifically, it is considered that, for example, the compound represented by Formula (1) reacts with oxygen in the air, R¹, R², R³, and R⁴ in Formula (1) are eliminated (for example, dehydration, de-alcoholization, and the like), a single bond between R¹ and R² and a single bond between R³ and R⁴ are changed to a double bond, and thus conjugation is extended, so that the structure is changed to a structure which absorbs visible light and the compound exhibits black color.

The above-described reaction of the compound represented by Formula (1) is an irreversible reaction unlike the leuco dye, and thus fading is unlikely to occur. Therefore, from the viewpoint of reducing the risk of fading of the pattern, the specific coloring material precursor is more preferably the compound represented by Formula (1).

Hereinafter, details of the compound represented by Formula (1) will be described.

X¹, X², X³, and X⁴ are preferably oxygen atoms.

In Formula (1), two Y¹'s may be the same or different from each other, but are preferably the same.

Y¹ is preferably an oxygen atom.

In Formula (1), two Y²'s may be the same or different from each other, but are preferably the same.

Y² is preferably N-L¹.

L¹ is preferably a hydrogen atom, an alkyl group, an acyl group, or an alkoxycarbonyl group; and more preferably an alkyl group, an acyl group, or an alkoxycarbonyl group.

The alkyl group represented by L¹ may have a substituent or may not have a substituent. The alkyl group represented by L¹ may be a linear alkyl group, a branched alkyl group, or an alkyl group having a cyclic structure.

The alkyl group represented by L¹ is preferably an alkyl group having 1 to 30 carbon atoms, and more preferably an alkyl group having 1 to 12 carbon atoms.

As the alkyl group represented by L¹, for example, an s-butyl group, an n-hexyl group, a 2-ethoxyethyl group, a methoxycarbonylmethyl group, an isopropyl group, an n-pentyl group, or a 2-ethylhexyl group is preferable.

The acyl group represented by L¹ is preferably an acyl group having 2 to 30 carbon atoms, and more preferably an acyl group having 2 to 15 carbon atoms.

As the acyl group represented by L¹, for example, an acetyl group, a 2-ethylhexanoyl group, a 3,3,5-trimethylhexanoyl group, a propionyl group, a butyryl group, an isobutyryl group, or a pivaloyl group is preferable.

The alkoxycarbonyl group represented by L¹ is preferably an alkoxycarbonyl group having 1 to 30 carbon atoms in an alkoxy moiety.

As the alkoxycarbonyl group represented by L¹, for example, a methoxycarbonyl group, an ethoxycarbonyl group, a butoxycarbonyl group, a t-butoxycarbonyl group, a 9-fluorenylmethyloxycarbonyl group, a benzyloxycarbonyl group, or a 2,2,2-trichloroethyloxycarbonyl group is preferable.

In a case where one of R¹ or R² is a hydrogen atom, the other is preferably a hydrogen atom or a hydroxy group (that is, —O-L² in which L² is a hydrogen atom), and more preferably a hydrogen atom.

In a case where one of R³ or R⁴ is a hydrogen atom, the other is preferably a hydrogen atom or a hydroxy group (that is, —O-L² in which L² is a hydrogen atom), and more preferably a hydrogen atom.

L² is preferably a hydrogen atom.

The alkyl group represented by L² may have a substituent or may not have a substituent. The alkyl group represented by L² may be a linear alkyl group, a branched alkyl group, or an alkyl group having a cyclic structure.

The alkyl group represented by L² is preferably an alkyl group having 1 to 30 carbon atoms, and more preferably an alkyl group having 1 to 12 carbon atoms.

As the alkyl group represented by L², for example, a methyl group, an ethyl group, an n-propyl group, or a 2-ethylhexyl group is preferable.

The alkyl group represented by L³ may have a substituent or may not have a substituent. The alkyl group represented by L³ may be a linear alkyl group, a branched alkyl group, or an alkyl group having a cyclic structure.

The alkyl group represented by L³ is preferably an alkyl group having 1 to 30 carbon atoms, and more preferably an alkyl group having 1 to 12 carbon atoms.

As the alkyl group represented by L³, for example, a methyl group, an ethyl group, a propyl group, or a 2-ethylhexyl group is preferable.

The aromatic ring represented by A and the aromatic ring represented by B may be the same or different from each other. The aromatic ring represented by A and B may have a substituent or may not have a substituent. The aromatic ring represented by A and B may be, for example, an aromatic hydrocarbon ring, an aromatic heterocyclic ring, or a fused ring thereof.

In a case where the aromatic ring represented by A and B is an aromatic hydrocarbon ring, the aromatic hydrocarbon ring represented by A and B is preferably a 5-membered ring or a 6-membered ring, and more preferably a 6-membered ring.

In a case where the aromatic ring represented by A and B is an aromatic hydrocarbon ring, the aromatic hydrocarbon ring represented by A and B is preferably an aromatic hydrocarbon ring having 6 to 30 carbon atoms, more preferably an aromatic hydrocarbon ring having 6 to 20 carbon atoms, and still more preferably an aromatic hydrocarbon ring having 6 to 10 carbon atoms.

In a case where the aromatic ring represented by A and B is an aromatic hydrocarbon ring, the aromatic hydrocarbon ring represented by A is, for example, preferably a benzene ring, a naphthalene ring, or an anthracene ring, and more preferably a benzene ring.

In a case where the aromatic ring represented by A and B is an aromatic heterocyclic ring, the aromatic heterocyclic ring represented by A and B is preferably a 5-membered ring or a 6-membered ring, and more preferably a 5-membered ring.

In a case where the aromatic ring represented by A and B is an aromatic heterocyclic ring, the aromatic heterocyclic ring represented by A and B is preferably an aromatic heterocyclic ring including one or more heteroatoms selected from the group consisting of an oxygen atom, a sulfur atom, and a nitrogen atom in a ring. The number of heteroatoms in the aromatic heterocyclic ring is preferably 1 or 2, and more preferably 1.

In a case where the aromatic ring represented by A and B is an aromatic heterocyclic ring, the aromatic heterocyclic ring represented by A and B is, for example, preferably a thiophene ring, a furan ring, a pyrrole ring, an imidazole ring, a triazole ring, or a pyridine ring, and more preferably a thiophene ring.

The aromatic ring represented by C may have a substituent or may not have a substituent.

Examples of the aromatic ring represented by C include a benzene ring and a heterocyclic ring.

Examples of the heterocyclic ring include a pyridine ring and a pyrazine ring.

As the aromatic ring represented by C, a benzene ring is preferable.

In Formula (1), X¹, X², X³, X⁴, R¹, R², R³, and R⁴ are, for example, preferably the following aspect A, and more preferably the following aspect B.

Aspect A: aspect that X¹, X², X³, and X⁴ are oxygen atoms, at least one of R¹ or R² is a hydrogen atom and the other is a hydroxy group, and at least one of R³ or R⁴ is a hydrogen atom and the other is a hydroxy group

Aspect B: aspect that X¹, X², X³, and X⁴ are oxygen atoms, and R¹, R², R³, and R⁴ are hydrogen atoms

A preferred aspect of the compound represented by Formula (1) is an aspect that X¹, X², X³, and X⁴ are oxygen atoms, Y¹ and Y² are each independently an oxygen atom, a sulfur atom, or N-L¹, L¹ is a hydrogen atom, an alkyl group, an acyl group, or an alkoxycarbonyl group, one of R¹ or R² is a hydrogen atom and the other is a hydroxy group, one of R³ or R⁴ is a hydrogen atom and the other is a hydroxy group, A and B are each independently a benzene ring or a thiophene ring, and C is a benzene ring.

A more preferred aspect of the compound represented by Formula (1) is an aspect that X¹, X², X³, and X⁴ are oxygen atoms, Y¹ is an oxygen atom, Y² is N-L¹, L¹ is an alkyl group, an acyl group, or an alkoxycarbonyl group, R¹, R², R³, and R⁴ are hydrogen atoms, A and B are benzene rings, and C is a benzene ring.

Specific examples of the compound represented by Formula (1) will be described below. However, the compound represented by Formula (1) is not limited to the following specific examples. “Me” represents a methyl group.

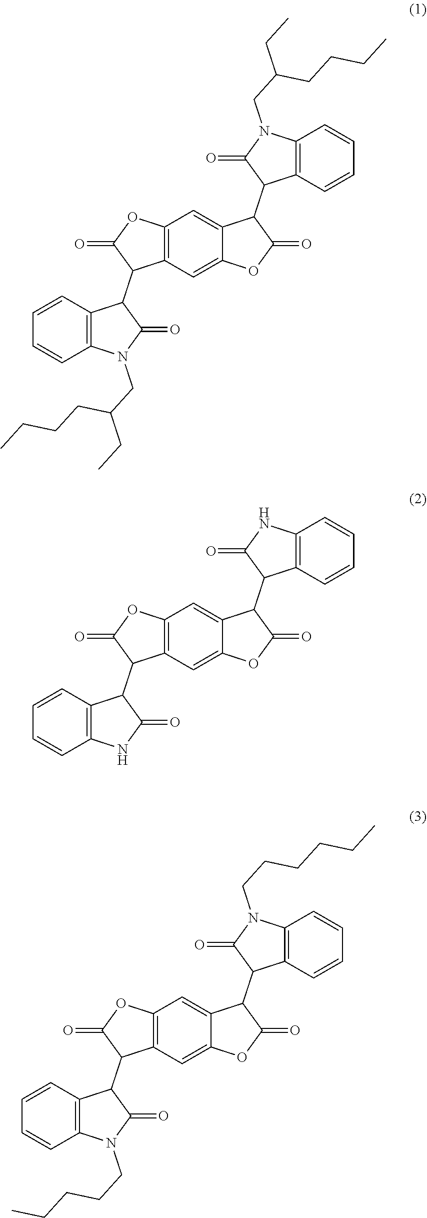

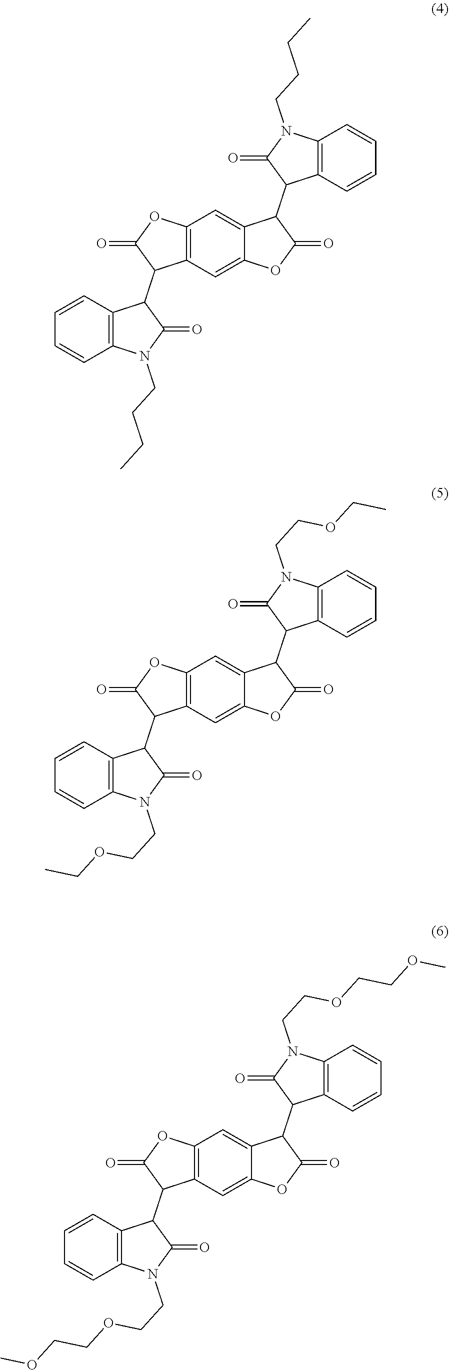

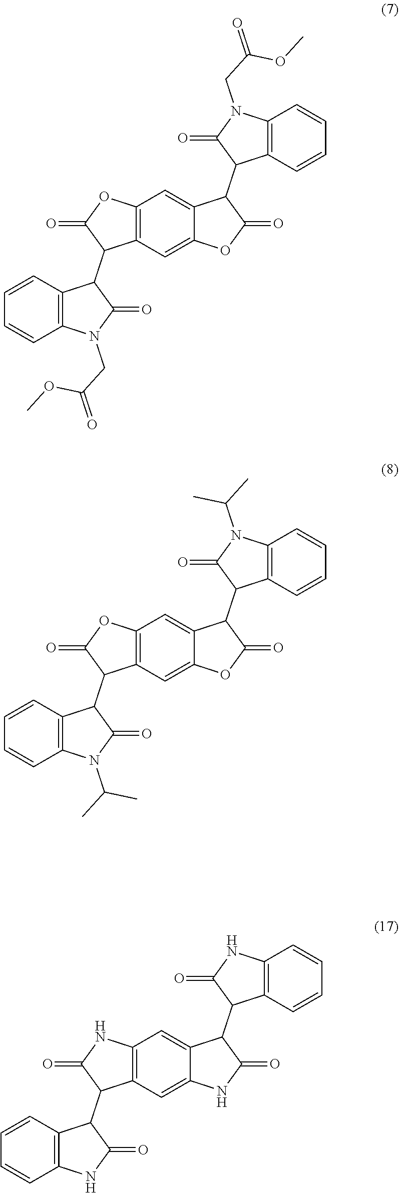 [SMILES: COC(=O)CN1C(=O)C(C2C(=O)Oc3cc4c(cc32)OC(=O)C4C2C(=O)N(CC(=O)OC)c3ccccc32)c2ccccc21 ; CC(C)N1C(=O)C(C2C(=O)Oc3cc4c(cc32)OC(=O)C4C2C(=O)N(C(C)C)c3ccccc32)c2ccccc21 ; O=C1Nc2ccccc2C1C1C(=O)Nc2cc3c(cc21)NC(=O)C3C1C(=O)Nc2ccccc21]

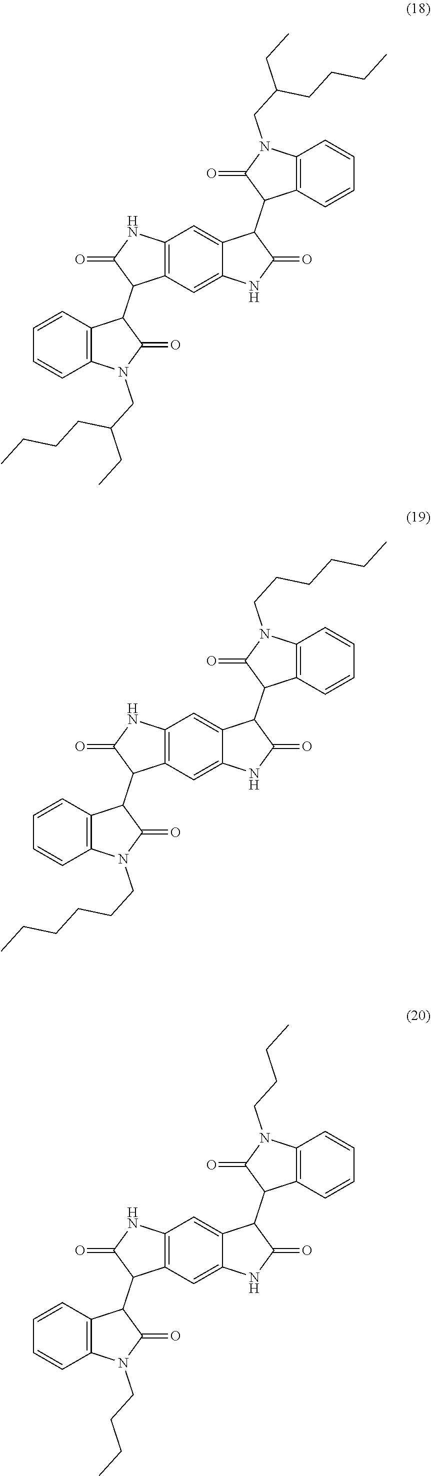

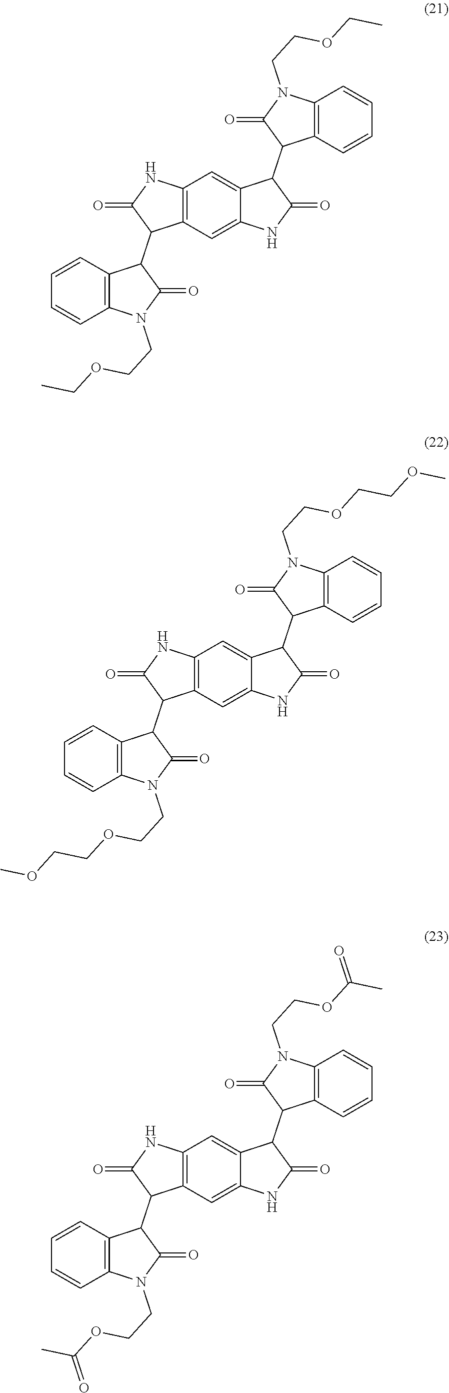

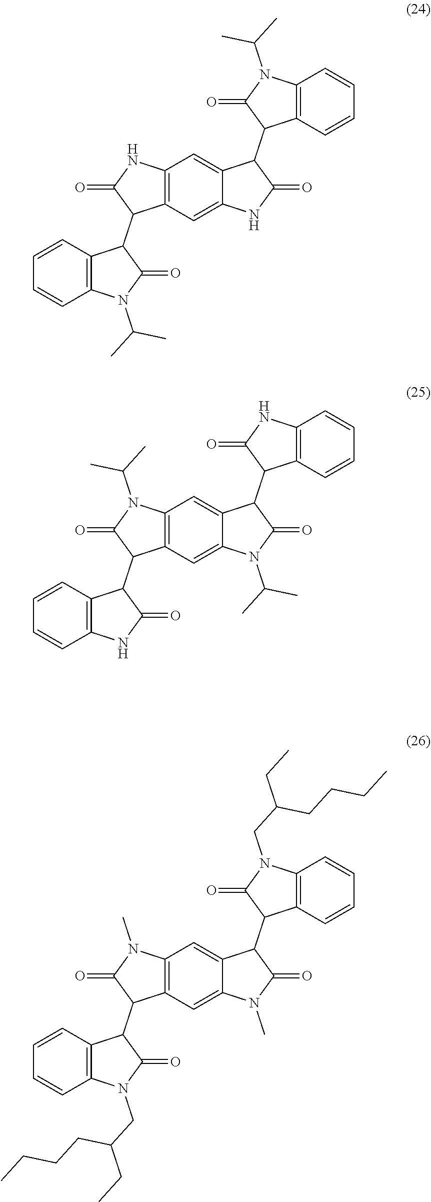 [SMILES: CC(C)N1C(=O)C(C2C(=O)Nc3cc4c(cc32)NC(=O)C4C2C(=O)N(C(C)C)c3ccccc32)c2ccccc21 ; CC(C)N1C(=O)C(C2C(=O)Nc3ccccc32)c2cc3c(cc21)C(C1C(=O)Nc2ccccc21)C(=O)N3C(C)C ; CCCCC(CC)CN1C(=O)C(C2C(=O)N(C)c3cc4c(cc32)N(C)C(=O)C4C2C(=O)N(CC(CC)CCCC)c3ccccc32)c2ccccc21]

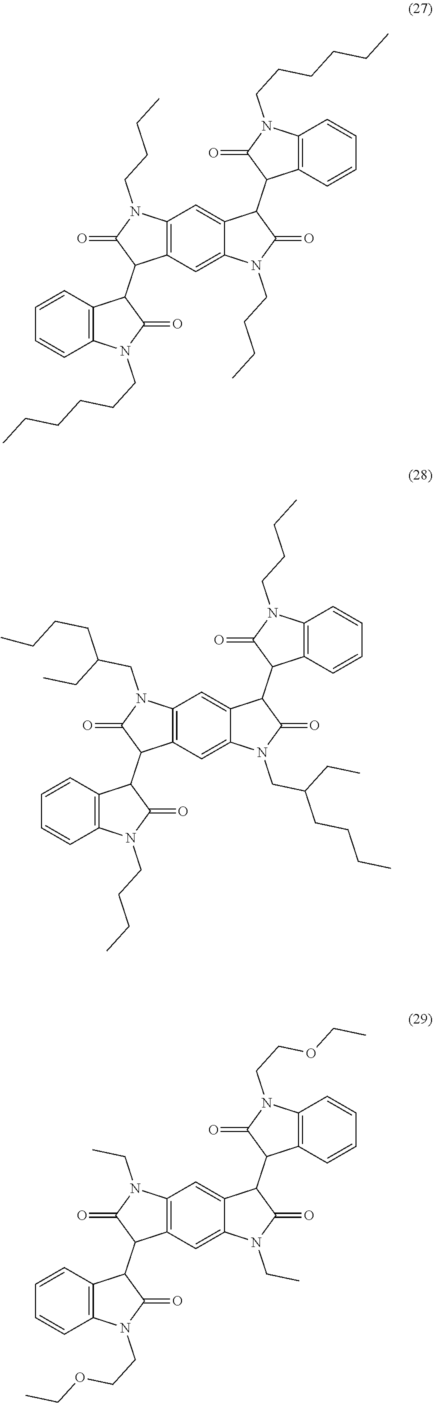

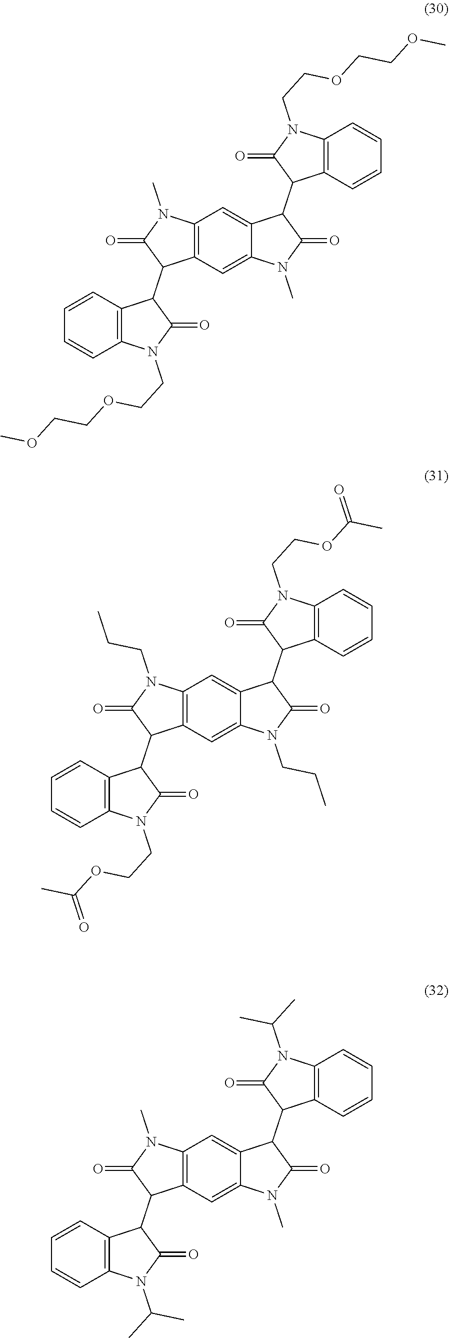

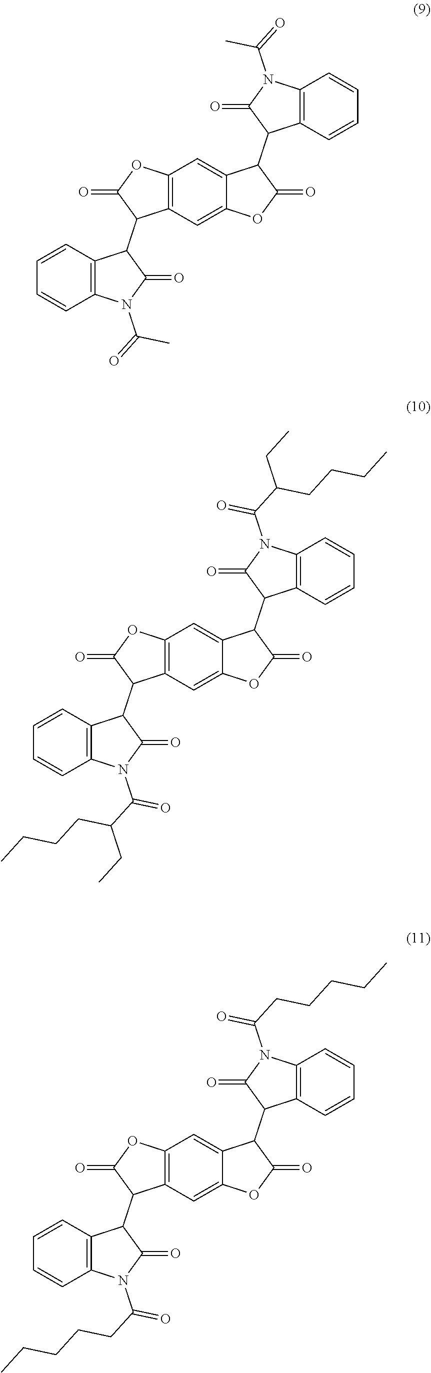

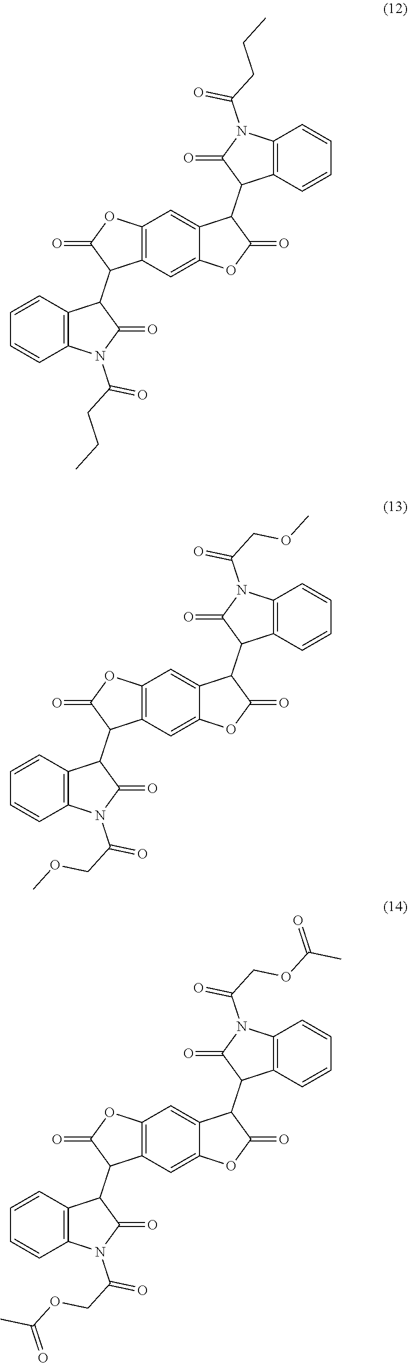 [SMILES: CCCC(=O)N1C(=O)C(C2C(=O)Oc3cc4c(cc32)OC(=O)C4C2C(=O)N(C(=O)CCC)c3ccccc32)c2ccccc21 ; COCC(=O)N1C(=O)C(C2C(=O)Oc3cc4c(cc32)OC(=O)C4C2C(=O)N(C(=O)COC)c3ccccc32)c2ccccc21 ; CC(=O)OCC(=O)N1C(=O)C(C2C(=O)Oc3cc4c(cc32)OC(=O)C4C2C(=O)N(C(=O)COC(C)=O)c3ccccc32)c2ccccc21]

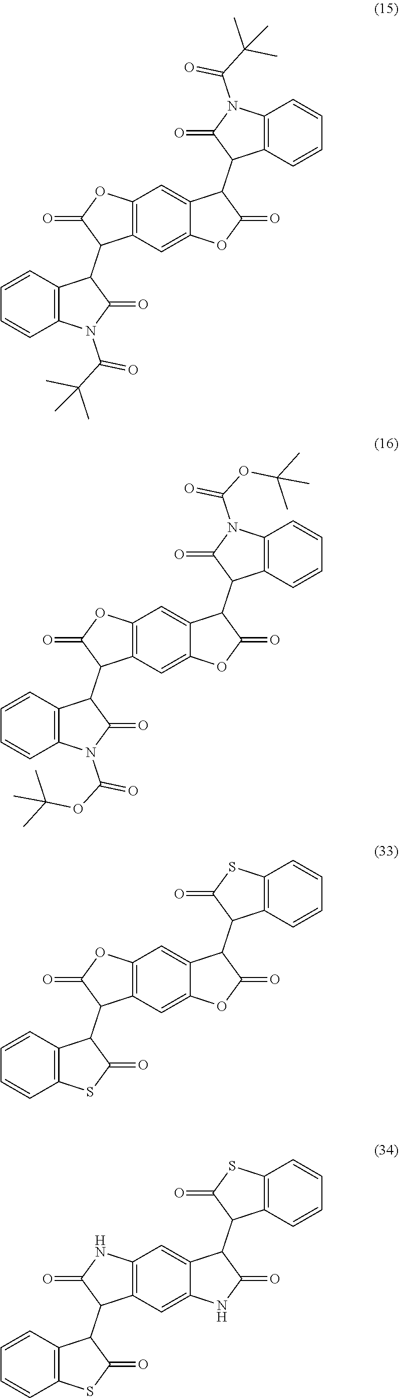 [SMILES: CC(C)(C)C(=O)N1C(=O)C(C2C(=O)Oc3cc4c(cc32)OC(=O)C4C2C(=O)N(C(=O)C(C)(C)C)c3ccccc32)c2ccccc21 ; CC(C)(C)OC(=O)N1C(=O)C(C2C(=O)Oc3cc4c(cc32)OC(=O)C4C2C(=O)N(C(=O)OC(C)(C)C)c3ccccc32)c2ccccc21 ; O=C1Oc2cc3c(cc2C1C1C(=O)Sc2ccccc21)OC(=O)C3C1C(=O)Sc2ccccc21 ; O=C1Nc2cc3c(cc2C1C1C(=O)Sc2ccccc21)NC(=O)C3C1C(=O)Sc2ccccc21]

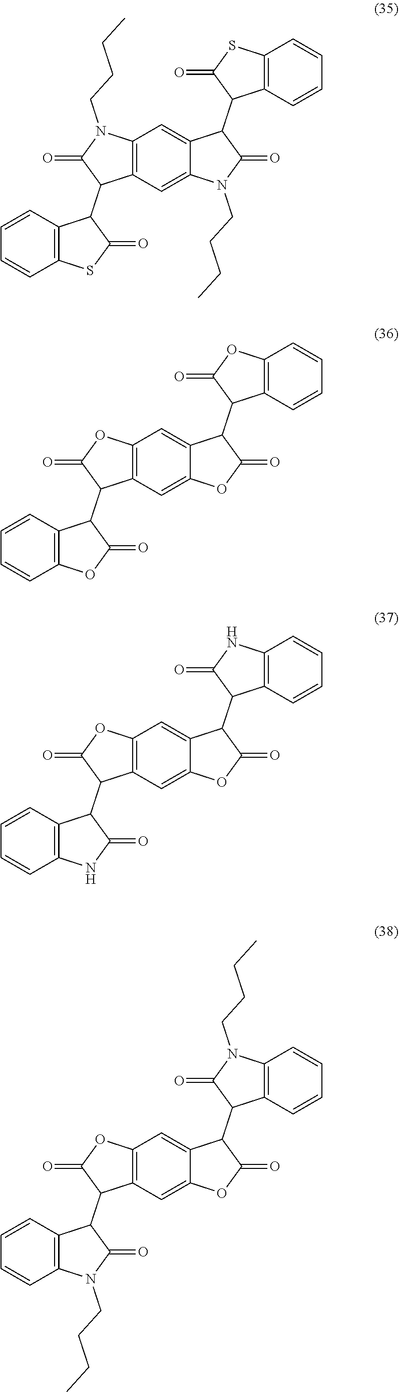 [SMILES: CCCCN1C(=O)C(C2C(=O)Sc3ccccc32)c2cc3c(cc21)C(C1C(=O)Sc2ccccc21)C(=O)N3CCCC ; O=C1Oc2ccccc2C1C1C(=O)Oc2cc3c(cc21)OC(=O)C3C1C(=O)Oc2ccccc21 ; O=C1Nc2ccccc2C1C1C(=O)Oc2cc3c(cc21)OC(=O)C3C1C(=O)Nc2ccccc21 ; CCCCN1C(=O)C(C2C(=O)Oc3cc4c(cc32)OC(=O)C4C2C(=O)N(CCCC)c3ccccc32)c2ccccc21]

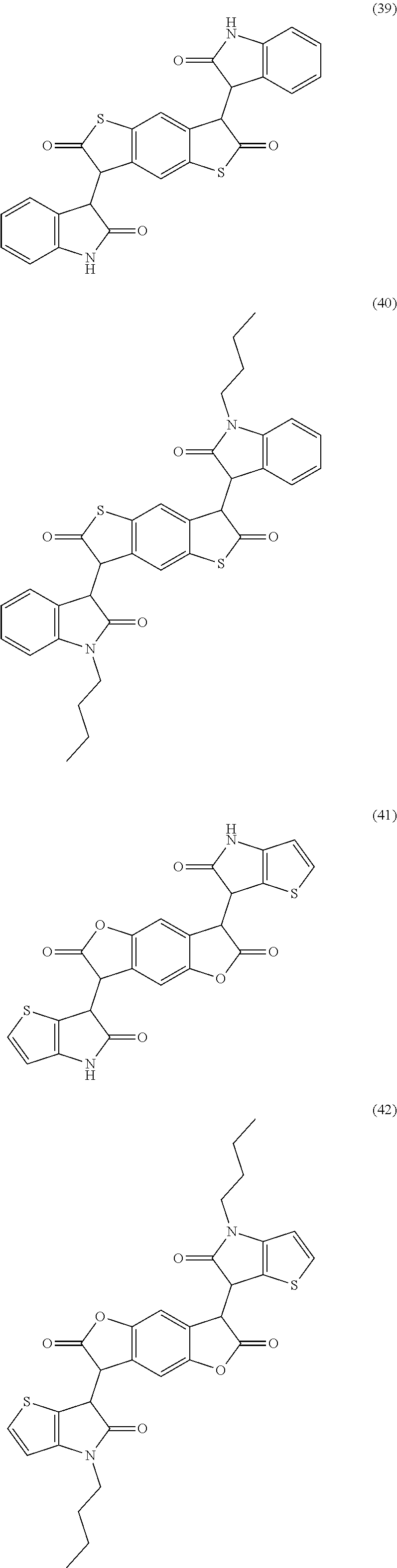 [SMILES: O=C1Nc2ccccc2C1C1C(=O)Sc2cc3c(cc21)SC(=O)C3C1C(=O)Nc2ccccc21 ; CCCCN1C(=O)C(C2C(=O)Sc3cc4c(cc32)SC(=O)C4C2C(=O)N(CCCC)c3ccccc32)c2ccccc21 ; O=C1Oc2cc3c(cc2C1C1C(=O)Nc2ccsc21)OC(=O)C3C1C(=O)Nc2ccsc21 ; CCCCN1C(=O)C(C2C(=O)Oc3cc4c(cc32)OC(=O)C4C2C(=O)N(CCCC)c3ccsc32)c2sccc21]

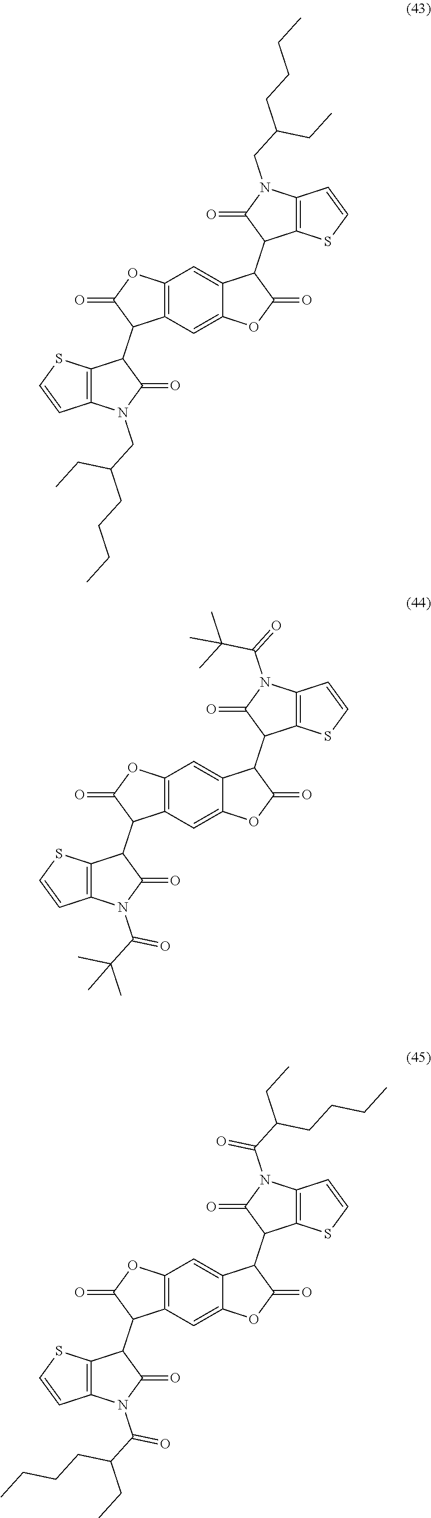 [SMILES: CCCCC(CC)CN1C(=O)C(C2C(=O)Oc3cc4c(cc32)OC(=O)C4C2C(=O)N(CC(CC)CCCC)c3ccsc32)c2sccc21 ; CC(C)(C)C(=O)N1C(=O)C(C2C(=O)Oc3cc4c(cc32)OC(=O)C4C2C(=O)N(C(=O)C(C)(C)C)c3ccsc32)c2sccc21 ; CCCCC(CC)C(=O)N1C(=O)C(C2C(=O)Oc3cc4c(cc32)OC(=O)C4C2C(=O)N(C(=O)C(CC)CCCC)c3ccsc32)c2sccc21]

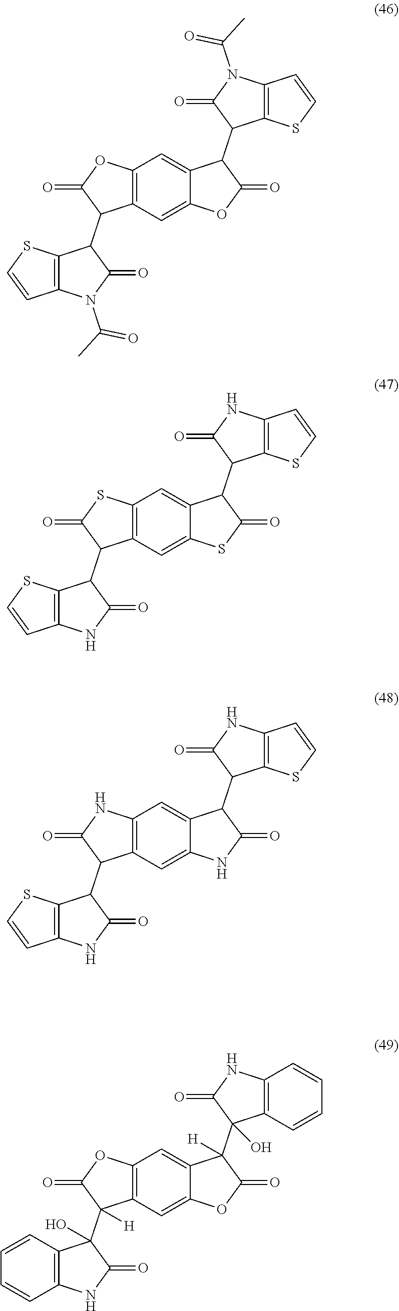 [SMILES: CC(=O)N1C(=O)C(C2C(=O)Oc3cc4c(cc32)OC(=O)C4C2C(=O)N(C(C)=O)c3ccsc32)c2sccc21 ; O=C1Sc2cc3c(cc2C1C1C(=O)Nc2ccsc21)SC(=O)C3C1C(=O)Nc2ccsc21 ; O=C1Nc2cc3c(cc2C1C1C(=O)Nc2ccsc21)NC(=O)C3C1C(=O)Nc2ccsc21 ; O=C1Oc2cc3c(cc2C1C1(O)C(=O)Nc2ccccc21)OC(=O)C3C1(O)C(=O)Nc2ccccc21]

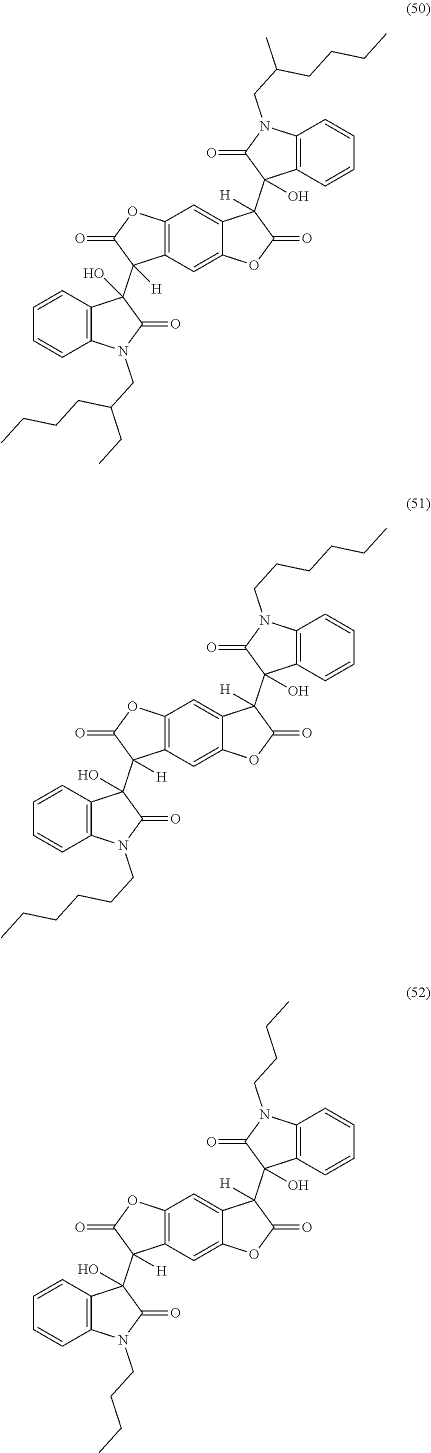

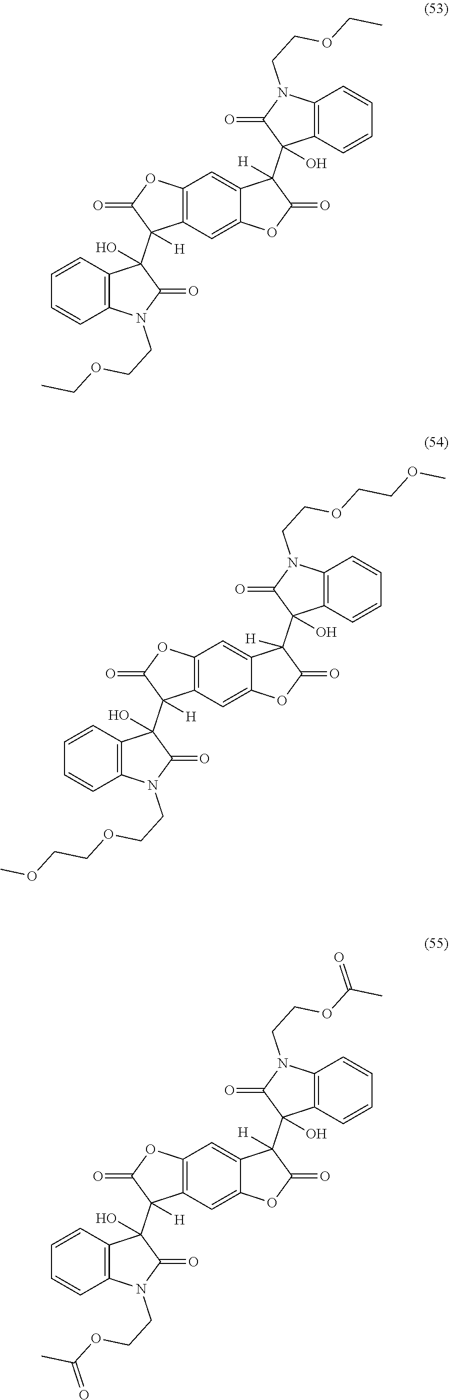

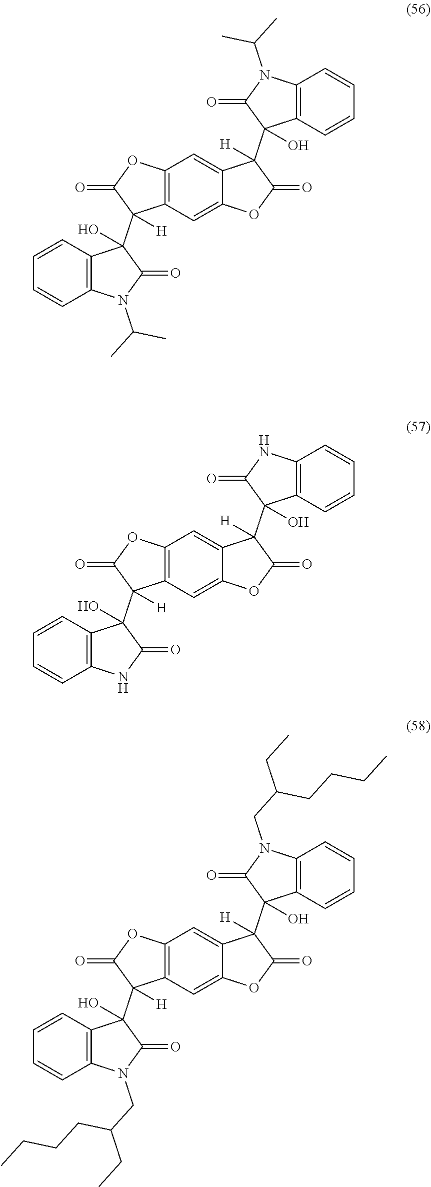 [SMILES: CC(C)N1C(=O)C(O)(C2C(=O)Oc3cc4c(cc32)OC(=O)C4C2(O)C(=O)N(C(C)C)c3ccccc32)c2ccccc21 ; O=C1Oc2cc3c(cc2C1C1(O)C(=O)Nc2ccccc21)OC(=O)C3C1(O)C(=O)Nc2ccccc21 ; CCCCC(CC)CN1C(=O)C(O)(C2C(=O)Oc3cc4c(cc32)OC(=O)C4C2(O)C(=O)N(CC(CC)CCCC)c3ccccc32)c2ccccc21]

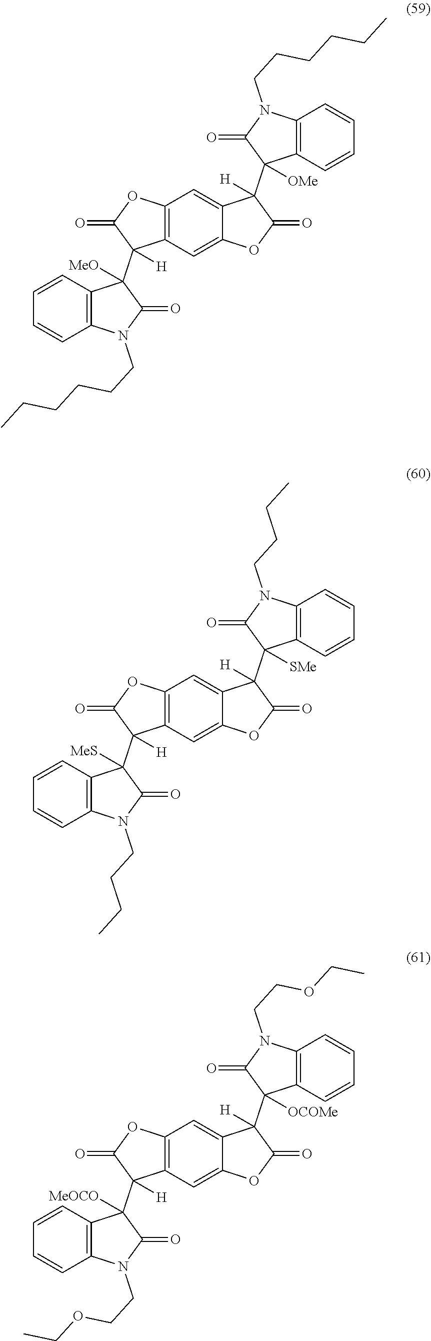

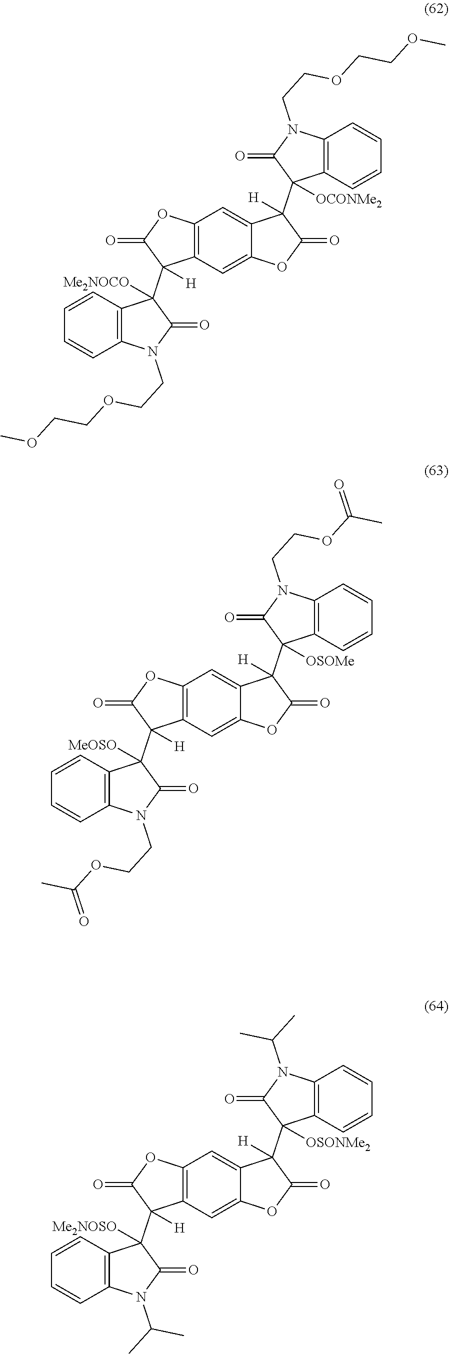

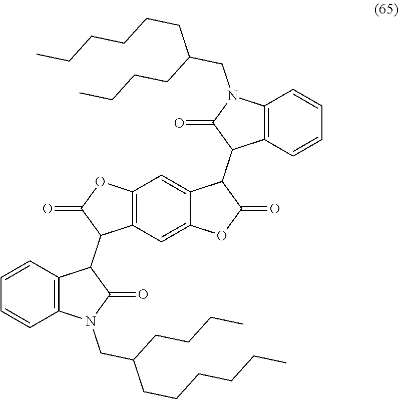 [SMILES: CCCCCCC(CCCC)CN1C(=O)C(C2C(=O)Oc3cc4c(cc32)OC(=O)C4C2C(=O)N(CC(CCCC)CCCCCC)c3ccccc32)c2ccccc21]

Among the above specific examples, as the compound represented by Formula (1), at least one selected from the group consisting of the compound (1) to the compound (16), the compound (25) to the compound (32), and the compound (65) is preferable; at least one selected from the group consisting of the compound (1) to the compound (16) and the compound (65) is more preferable; at least one selected from the group consisting of the compound (1) to the compound (3), the compound (5), the compound (7), and the compound (8) is still more preferable; and at least one selected from the group consisting of the compound (1) to the compound (3), the compound (5), the compound (7), and the compound (8) is particularly preferable.

A heating temperature for causing the compound represented by Formula (1) to color black is, for example, preferably 80° C. to 260° C.

A method for producing the compound represented by Formula (1) is not particularly limited.

The compound represented by Formula (1) can be produced with reference to a known method.

The compound represented by Formula (1) can be produced, for example, by synthesizing an isatin derivative using isatin as a starting material, reacting the synthesized isatin derivative with 3,7-dihydrobenzo[1,2-b: 4,5-b′]difuran-2,6-dione in an organic solvent under an acid catalyst, and reducing the compound obtained by the reaction, with reference to known documents.

The method for synthesizing the isatin derivative is described in, for example, J. Am. Chem. Soc. 2015, 137, pp. 15947 to 15956, Journal of Medicinal Chemistry, 2008, 51, pp. 4932 to 4947, Chemistry-A European Journal, 2021, 27, pp. 4302 to 4306, Org. Lett., 2021, 23, pp. 2273 to 2278, and the like. The description of these documents is incorporated in the present specification by reference.

Examples of the organic solvent include an ether-based organic solvent; and tetrahydrofuran (THF) and/or 1,4-dioxane is preferable, and tetrahydrofuran (THF) is more preferable.

Examples of a method of reducing the compound obtained by the reaction include a method using a reducing agent such as zinc powder, trifluoroacetic acid, acetic acid, and hydrochloric acid. In addition, the reduction may be contact reduction using a palladium catalyst. As the reduction method, reduction using zinc powder (so-called zinc reduction) or contact reduction using a palladium catalyst is preferable, and zinc reduction is more preferable.

A reaction temperature is not particularly limited, but is, for example, preferably 20° C. to 40° C. and more preferably 30° C. to 40° C.

A reaction time is not particularly limited, but is, for example, preferably 1 hour to 6 hours and more preferably 1 hour to 2 hours.

The compound represented by Formula (1) can be suitably produced by a method described in Examples later.

The photosensitive composition according to the present disclosure may contain only one kind of the specific coloring material precursor, or may contain two or more kinds thereof.

A content of the specific coloring material precursor in the photosensitive composition according to the present disclosure is not particularly limited, but for example, from the viewpoint that the effects of the present disclosure are more excellent, it is preferably 1% by mass to 20% by mass, more preferably 2% by mass to 15% by mass, and still more preferably 3% by mass to 10% by mass with respect to the total solid content of the photosensitive composition.

<Component Other than Specific Coloring Material Precursor>

The photosensitive composition according to the present disclosure may further contain an alkali-soluble resin, a polymerizable monomer, and a photopolymerization initiator, in addition to the specific coloring material precursor. In addition, the photosensitive composition according to the present disclosure may contain additives such as a heterocyclic compound, an aliphatic thiol compound, a thermal crosslinking compound, a surfactant, a polymerization inhibitor, a hydrogen donating compound, and a solvent.

Hereinafter, these components will be described in detail.

### (Alkali-Soluble Resin)

The photosensitive composition according to the present disclosure may contain an alkali-soluble resin.

Examples of the alkali-soluble resin include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and an acid-modified epoxy acrylate resin obtained by a reaction of an epoxy acrylate resin and acid anhydride.

From the viewpoint of excellent alkali developability and film formability, examples of a suitable aspect of the alkali-soluble resin include a (meth)acrylic resin.

In the present disclosure, the (meth)acrylic resin means a resin including a structural unit derived from a (meth)acrylic compound.

A content of the structural unit derived from a (meth)acrylic compound is preferably 50% by mass or more, more preferably 70% by mass or more, and still more preferably 90% by mass or more with respect to all structural units of the (meth)acrylic resin.

The (meth)acrylic resin may be composed of only the structural unit derived from a (meth)acrylic compound, or may include a structural unit derived from a polymerizable monomer other than the (meth)acrylic compound. That is, the upper limit of the content of the structural unit derived from a (meth)acrylic compound is 100% by mass or less with respect to all structural units of the (meth)acrylic resin.

Examples of the (meth)acrylic compound include (meth)acrylic acid, (meth)acrylic acid ester, (meth)acrylamide, and (meth)acrylonitrile.

Examples of the (meth)acrylic acid ester include (meth)acrylic acid alkyl ester, (meth)acrylic acid tetrahydrofurfuryl ester, (meth)acrylic acid dimethylaminoethyl ester, (meth)acrylic acid diethylaminoethyl ester, (meth)acrylic acid glycidyl ester, (meth)acrylic acid benzyl ester, 2,2,2-trifluoroethyl (meth)acrylate, and 2,2,3,3-tetrafluoropropyl (meth)acrylate, and (meth)acrylic acid alkyl ester is preferable.

Examples of the (meth)acrylamide include acrylamides such as diacetone acrylamide. An alkyl group of the (meth)acrylic alkyl ester may be linear or branched.

Specific examples of the (meth)acrylic acid alkyl ester include (meth)acrylic acid alkyl esters having an alkyl group having 1 to 12 carbon atoms, such as methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate.

As the (meth)acrylic acid alkyl ester, (meth)acrylic acid alkyl ester having an alkyl group having 1 to 4 carbon atoms is preferable, and methyl (meth)acrylate or ethyl (meth)acrylate is more preferable.

The (meth)acrylic resin may include a structural unit other than the structural unit derived from a (meth)acrylic compound.

The polymerizable monomer forming the structural unit other than the structural unit derived from a (meth)acrylic compound is not particularly limited as long as it is a compound other than the (meth)acrylic compound, which is copolymerizable with the (meth)acrylic compound.

Examples of the compound other than the (meth)acrylic compound, which is copolymerizable with the (meth)acrylic compound, include styrene compounds which may have a substituent at an a-position or at an aromatic ring, such as styrene, vinyltoluene, and a-methylstyrene; vinyl alcohol esters such as acrylonitrile and vinyl-n-butyl ether, maleic acid monoesters such as maleic acid, maleic acid anhydride, monomethyl maleate, monoethyl maleate, and monoisopropyl maleate; fumaric acid, cinnamic acid, a-cyanocinnamic acid, itaconic acid, and crotonic acid.

The (meth)acrylic resin may contain only one or two or more kinds of structural units derived from these polymerizable monomers.

In addition, from the viewpoint of improving alkali developability, the (meth)acrylic resin preferably includes a structural unit having an acid group. Examples of the acid group include a carboxy group, a sulfo group, a phosphoric acid group, and a phosphonic acid group.

The (meth)acrylic resin more preferably includes a structural unit having a carboxy group, and still more preferably has a structural unit derived from the above-described (meth)acrylic acid.

In a case where the (meth)acrylic resin includes a structural unit having an acid group in the (meth)acrylic resin (preferably, a structural unit derived from (meth)acrylic acid; the same applies hereinafter), from the viewpoint of excellent developability, a content of the structural unit having an acid group in the (meth)acrylic resin is preferably 10% by mass or more with respect to all structural units of the (meth)acrylic resin. From the viewpoint of excellent alkali resistance, the upper limit of the content of the structural unit having an acid group in the (meth)acrylic resin is preferably 50% by mass or less, and more preferably 40% by mass or less with respect to all structural units of the (meth)acrylic resin.

It is more preferable that the (meth)acrylic resin includes a structural unit derived from the above-described (meth)acrylic acid alkyl ester.

In a case where the (meth)acrylic resin includes a structural unit derived from the (meth)acrylic acid alkyl ester, a content of the structural unit derived from (meth)acrylic acid alkyl ester in the (meth)acrylic resin is preferably 1% by mass to 90% by mass, more preferably 1% by mass to 50% by mass, and still more preferably 1% by mass to 30% by mass with respect to all structural units of the (meth)acrylic resin.

As the (meth)acrylic resin, a resin including both the structural unit derived from (meth)acrylic acid and the structural unit derived from (meth)acrylic acid alkyl ester is preferable, and a resin composed of only the structural unit derived from (meth)acrylic acid and the structural unit derived from (meth)acrylic acid alkyl ester is more preferable.

In addition, as the (meth)acrylic resin, an acrylic resin which has a structural unit derived from methacrylic acid, a structural unit derived from methyl methacrylate, and a structural unit derived from ethyl acrylate may be used.

From the viewpoint that the effects of the present disclosure are more excellent, the (meth)acrylic resin preferably includes at least one selected from the group consisting of a structural unit derived from methacrylic acid and a structural unit derived from methacrylic acid alkyl ester; and preferably includes both the structural unit derived from methacrylic acid and the structural unit derived from methacrylic acid alkyl ester.

From the viewpoint that the effects of the present disclosure are more excellent, the total content of the structural unit derived from methacrylic acid and the structural unit derived from methacrylic acid alkyl ester in the (meth)acrylic resin is preferably 40% by mass or more, and more preferably 60% by mass or more with respect to all structural units of the (meth)acrylic resin. The upper limit of the total content of the structural unit derived from methacrylic acid and the structural unit derived from methacrylic acid alkyl ester in the (meth)acrylic resin may be, for example, 100% by mass or less, preferably 80% by mass or less with respect to all structural units of the (meth)acrylic resin.

From the viewpoint that the effects of the present disclosure are more excellent, the (meth)acrylic resin may also include at least one structural unit selected from the group consisting of the structural unit derived from methacrylic acid and the structural unit derived from methacrylic acid alkyl ester, and at least one structural unit selected from the group consisting of the structural unit derived from acrylic acid and the structural unit derived from acrylic acid alkyl ester.

From the viewpoint that a photosensitive composition layer formed of the photosensitive composition has excellent developability, the (meth)acrylic resin preferably has an ester group at a terminal.

The terminal portion of the (meth)acrylic resin is composed of a site derived from a polymerization initiator used in the synthesis. The (meth)acrylic resin having an ester group at the terminal can be synthesized using a radical polymerization initiator having an ester group.

For example, from the viewpoint of developability, the alkali-soluble resin is preferably a resin having an acid value of 60 mgKOH/g or more.

In addition, from the viewpoint that it is easy to form a strong film by thermally crosslinking with a crosslinking component by heating, for example, the alkali-soluble resin is still more preferably a resin (so-called a carboxy group-containing resin) having an acid value of 60 mgKOH/g or more and having a carboxy group, and particularly preferably a (meth)acrylic resin (so-called a carboxy group-containing (meth)acrylic resin) having an acid value of 60 mgKOH/g or more and having a carboxy group.

In a case where the alkali-soluble resin is a resin having a carboxy group, for example, the three-dimensional crosslinking density can be increased by adding a thermal crosslinking compound such as a blocked isocyanate compound and thermally crosslinking. In addition, in a case where the carboxy group of the resin having a carboxy group is anhydrous and hydrophobized, wet heat resistance can be improved.

The carboxy group-containing (meth)acrylic resin having an acid value of 60 mgKOH/g or more is not particularly limited as long as the above-described conditions of acid value are satisfied, and a known (meth)acrylic resin can be appropriately selected. As the carboxy group-containing (meth)acrylic resin having an acid value of 60 mgKOH/g or more, for example, a carboxy group-containing (meth)acrylic resin having an acid value of 60 mgKOH/g or more among polymers described in paragraph [0025] of JP2011-95716A, or a carboxy group-containing (meth)acrylic resin having an acid value of 60 mgKOH/g or more among polymers described in paragraphs [0033] to [0052] to of JP2010-237589A can be preferably used.

Examples of other suitable aspects of the alkali-soluble resin include a styrene-acrylic copolymer.

In the present disclosure, the styrene-acrylic copolymer means a resin including a structural unit derived from a styrene compound and a structural unit derived from a (meth)acrylic compound.

The total content of the structural unit derived from a styrene compound and the structural unit derived from a (meth)acrylic compound in the styrene-acrylic copolymer is, for example, preferably 30% by mass or more, and more preferably 50% by mass or more with respect to all structural units of the styrene-acrylic copolymer.

In addition, a content of the structural unit derived from a styrene compound in the styrene-acrylic copolymer is, for example, preferably 1% by mass or more, more preferably 5% by mass or more, and still more preferably 5% by mass to 80% by mass with respect to all structural units of the styrene-acrylic copolymer.

In addition, a content of the structural unit derived from a (meth)acrylic compound in the styrene-acrylic copolymer is, for example, preferably 5% by mass or more, more preferably 10% by mass or more, and still more preferably 20% by mass to 95% by mass with respect to all structural units of the styrene-acrylic copolymer.

From the viewpoint that the effects of the present disclosure are more excellent, the alkali-soluble resin preferably has an aromatic ring structure, and more preferably includes a structural unit having an aromatic ring structure.

Examples of a monomer forming the structural unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer).

As a monomer forming the structural unit having an aromatic ring structure, a monomer having an aralkyl group or styrene is preferable.

Examples of the aralkyl group include a substituted or unsubstituted phenylalkyl group and a substituted or unsubstituted benzyl group; and a substituted or unsubstituted benzyl group is preferable.

Examples of a monomer having the phenylalkyl group include phenylethyl (meth)acrylate.

Examples of a monomer having the benzyl group include (meth)acrylates having a benzyl group [such as benzyl (meth)acrylate and chlorobenzyl (meth)acrylate] and vinyl monomers having a benzyl group [such as vinylbenzyl chloride and vinylbenzyl alcohol]; and benzyl (meth)acrylate is preferable.

From the viewpoint that the effects of the present disclosure are more excellent, the alkali-soluble resin more preferably includes a structural unit represented by Formula(S) (that is, a structural unit derived from styrene).

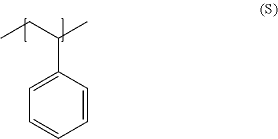

In a case where the alkali-soluble resin includes a structural unit having an aromatic ring structure, from the viewpoint that the effects of the present disclosure are more excellent, a content of the structural unit having an aromatic ring structure in the alkali-soluble resin is preferably 5% by mass to 90% by mass, more preferably 10% by mass to 70% by mass, and still more preferably 20% by mass to 60% by mass with respect to all structural units of the alkali-soluble resin.

From the viewpoint that the effects of the present disclosure are more excellent, the content of the structural unit having an aromatic ring structure in the alkali-soluble resin is preferably 5 mol % to 70 mol %, more preferably 10 mol % to 60 mol %, and still more preferably 20 mol % to 60 mol % with respect to all structural units of the alkali-soluble resin.

From the viewpoint that the effects of the present disclosure are more excellent, a content of the structural unit represented by Formula(S) in the alkali-soluble resin is preferably 5 mol % to 70 mol %, more preferably 10 mol % to 60 mol %, still more preferably 20 mol % to 60 mol %, and particularly preferably 20 mol % to 50 mol % with respect to all structural units of the alkali-soluble resin.

In the present disclosure, in a case where a content of “structural unit” is defined by a molar ratio, the “structural unit” is synonymous with “monomer unit”. In addition, in the present disclosure, the “monomer unit” may be modified after polymerization by a polymer reaction or the like. The same applies to the following.

From the viewpoint that the effects of the present disclosure are more excellent, the alkali-soluble resin preferably includes a structural unit having an aliphatic hydrocarbon ring structure. The aliphatic hydrocarbon ring structure may be monocyclic or polycyclic. The alkali-soluble resin may include a structural unit having a ring structure in which two or more aliphatic hydrocarbon rings are fused.

Examples of the aliphatic hydrocarbon ring include a tricyclodecane ring, a cyclohexane ring, a cyclopentane ring, a norbornane ring, and an isophorone ring.

Examples of a monomer forming the structural unit having an aliphatic hydrocarbon ring structure include dicyclopentanyl (meth)acrylate, cyclohexyl (meth)acrylate, and isobornyl (meth)acrylate.

In addition, from the viewpoint that the effects of the present disclosure are more excellent, the alkali-soluble resin more preferably includes a structural unit represented by Formula (Cy), and still more preferably includes the structural unit represented by Formula(S) and a structural unit represented by Formula (Cy).

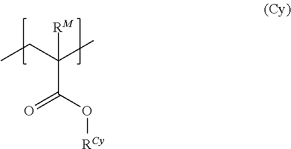

In Formula (Cy), R^{M} represents a hydrogen atom or a methyl group, and R^{Cy} represents a monovalent group having an aliphatic hydrocarbon ring structure.

R^{M} in Formula (Cy) is preferably a methyl group.

From the viewpoint that the effects of the present disclosure are more excellent, R^{Cy} in Formula (Cy) is preferably a monovalent group having an aliphatic hydrocarbon ring structure having 5 to 20 carbon atoms, more preferably a monovalent group having an aliphatic hydrocarbon ring structure having 6 to 16 carbon atoms, and still more preferably a monovalent group having an aliphatic hydrocarbon ring structure having 8 to 14 carbon atoms.

From the viewpoint that the effects of the present disclosure are more excellent, the aliphatic hydrocarbon ring structure in R^{Cy} of Formula (Cy) is preferably a cyclopentane ring structure, a cyclohexane ring structure, a tetrahydrodicyclopentadiene ring structure, a norbornane ring structure, or an isophorone ring structure, more preferably a cyclohexane ring structure or a tetrahydrodicyclopentadiene ring structure, and still more preferably a tetrahydrodicyclopentadiene ring structure.

In addition, from the viewpoint that the effects of the present disclosure are more excellent, the aliphatic hydrocarbon ring structure in Rey of Formula (Cy) is preferably a ring structure in which two or more aliphatic hydrocarbon rings are fused, and more preferably a ring in which two to four aliphatic hydrocarbon rings are fused.

In addition, from the viewpoint that the effects of the present disclosure are more excellent, R^{Cy} in Formula (Cy) is preferably a group in which the oxygen atom in —C(═O)O— of Formula (Cy) and the aliphatic hydrocarbon ring structure are directly bonded, that is, an aliphatic hydrocarbon ring group, more preferably a cyclohexyl group or a dicyclopentanyl group, and still more preferably a dicyclopentanyl group.

The alkali-soluble resin may include only one kind of the structural unit having an aliphatic hydrocarbon ring structure, or may include two or more kinds thereof.

In a case where the alkali-soluble resin includes a structural unit having an aliphatic hydrocarbon ring structure, from the viewpoint that the effects of the present disclosure are more excellent, a content of the structural unit having an aliphatic hydrocarbon ring structure in the alkali-soluble resin is preferably 5% by mass to 90% by mass, more preferably 10% by mass to 80% by mass, and still more preferably 20% by mass to 70% by mass with respect to all structural units of the alkali-soluble resin.

In addition, from the viewpoint that the effects of the present disclosure are more excellent, the content of the structural unit having an aliphatic hydrocarbon ring structure in the alkali-soluble resin is preferably 5 mol % to 70 mol %, more preferably 10 mol % to 60 mol %, and still more preferably 20 mol % to 50 mol % with respect to all structural units of the alkali-soluble resin.

From the viewpoint that the effects of the present disclosure are more excellent, a content of the structural unit represented by Formula (Cy) in the alkali-soluble resin is preferably 5 mol % to 70 mol %, more preferably 10 mol % to 60 mol %, and still more preferably 20 mol % to 50 mol % with respect to all structural units of the alkali-soluble resin.

In a case where the alkali-soluble resin includes the structural unit having an aromatic ring structure and the structural unit having an aliphatic hydrocarbon ring structure, from the viewpoint that the effects of the present disclosure are more excellent, the total content of the structural unit having an aromatic ring structure and the structural unit having an aliphatic hydrocarbon ring structure in the alkali-soluble resin is preferably 10% by mass to 90% by mass, more preferably 20% by mass to 80% by mass, and still more preferably 40% by mass to 75% by mass with respect to all structural units of the alkali-soluble resin.

From the viewpoint that the effects of the present disclosure are more excellent, the total content of the structural unit having an aromatic ring structure and the structural unit having an aliphatic hydrocarbon ring structure in the alkali-soluble resin is preferably 10 mol % to 80 mol %, more preferably 20 mol % to 70 mol %, and still more preferably 40 mol % to 60 mol % with respect to all structural units of the alkali-soluble resin.

From the viewpoint that the effects of the present disclosure are more excellent, the total content of the structural unit represented by Formula(S) and the structural unit represented by Formula (Cy) in the alkali-soluble resin is preferably 10 mol % to 80 mol %, more preferably 20 mol % to 70 mol %, and still more preferably 40 mol % to 60 mol % with respect to all structural units of the alkali-soluble resin.

From the viewpoint that the effects of the present disclosure are more excellent, a molar amount nS of the structural unit represented by Formula(S) and a molar amount nCy of the structural unit represented by Formula (Cy) in the alkali-soluble resin preferably satisfy a relationship shown in the following expression (SCy), more preferably satisfy a relationship shown in the following expression (SCy-1), and still more preferably satisfy a relationship shown in the following expression (SCy-2).

$$0.2 \leq nS / ( nS + nCy ) \leq 0 \text{.80} \qquad Expression ( SCy )$$

$$0.3 \leq nS / ( nS + nCy ) \leq 0 \text{.75} \qquad Expression ( SCy - 1 )$$

$$0.4 \leq nS / ( nS + nCy ) \leq 0 \text{.70} \qquad Expression ( SCy - 2 )$$

From the viewpoint that the effects of the present disclosure are more excellent, the alkali-soluble resin preferably includes a structural unit having an acid group. Examples of the acid group include a carboxy group, a sulfo group, a phosphonic acid group, and a phosphoric acid group, and a carboxy group is preferable. As the structural unit having an acid group, structural units derived from (meth)acrylic acid, which are shown below, is preferable, and a structural unit derived from methacrylic acid is more preferable.

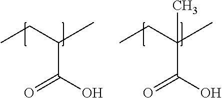

In a case where the alkali-soluble resin includes a structural unit having an acid group, the alkali-soluble resin may include only one kind of the structural unit having an acid group, or may include two or more kinds thereof.

In a case where the alkali-soluble resin includes a structural unit having an acid group, from the viewpoint that the effects of the present disclosure are more excellent, a content of the structural unit having an acid group in the alkali-soluble resin is preferably 5% by mass to 50% by mass, more preferably 5% by mass to 40% by mass, and still more preferably 10% by mass to 30% by mass with respect to all structural units of the alkali-soluble resin.

From the viewpoint that the effects of the present disclosure are more excellent, the content of the structural unit having an acid group in the alkali-soluble resin is preferably 5 mol % to 70 mol %, more preferably 10 mol % to 50 mol %, and still more preferably 20 mol % to 40 mol % with respect to all structural units of the alkali-soluble resin.

From the viewpoint that the effects of the present disclosure are more excellent, the content of the structural unit derived from (meth)acrylic acid in the alkali-soluble resin is preferably 5 mol % to 70 mol %, more preferably 10 mol % to 50 mol %, and still more preferably 20 mol % to 40 mol % with respect to all structural units of the alkali-soluble resin.

From the viewpoint that the effects of the present disclosure are more excellent, the alkali-soluble resin preferably has a reactive group, and more preferably includes a structural unit having a reactive group.

As the reactive group, a radically polymerizable group is preferable, and an ethylenically unsaturated group is more preferable. In addition, in a case where the alkali-soluble resin has an ethylenically unsaturated group, the alkali-soluble resin preferably includes a structural unit having an ethylenically unsaturated group in a side chain.

In the present disclosure, the “main chain” represents a relatively longest binding chain in a molecule of a polymer compound constituting a resin, and the “side chain” represents an atomic group branched from the main chain.

As the ethylenically unsaturated group, an allyl group or a (meth)acryloxy group is more preferable.

Examples of the structural unit having a reactive group include those shown below, but the structural unit having a reactive group is not limited thereto.

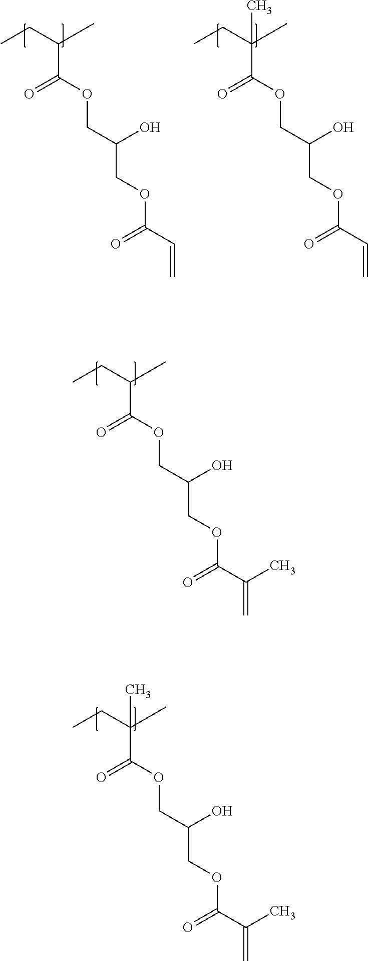

The alkali-soluble resin may include only one kind of the structural unit having a reactive group, or may include two or more kinds thereof.

In a case where the alkali-soluble resin includes a structural unit having a reactive group, from the viewpoint that the effects of the present disclosure are more excellent, a content of the structural unit having a reactive group in the alkali-soluble resin is preferably 5% by mass to 70% by mass, more preferably 10% by mass to 50% by mass, and still more preferably 20% by mass to 40% by mass with respect to all structural units of the alkali-soluble resin.

From the viewpoint that the effects of the present disclosure are more excellent, the content of the structural unit having a reactive group in the alkali-soluble resin is preferably 5 mol % to 70 mol %, more preferably 10 mol % to 60 mol %, and still more preferably 20 mol % to 50 mol % with respect to all structural units of the alkali-soluble resin.

Examples of a method for introducing the reactive group into the alkali-soluble resin include a method of reacting a compound such as an epoxy compound, a blocked isocyanate compound, an isocyanate compound, a vinyl sulfone compound, an aldehyde compound, a methylol compound, and a carboxylic acid anhydride with a functional group such as a hydroxy group, a carboxy group, a primary amino group, a secondary amino group, an acetoacetyl group, and a sulfo group.

Preferred examples of the method for introducing the reactive group into the alkali-soluble resin include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a alkali-soluble resin having a (meth)acryloxy group in the side chain can be obtained.

The polymerization reaction is preferably carried out under a temperature condition of 70° C. to 100° C., and more preferably carried out under a temperature condition of 80° C. to 90° C.

As a polymerization initiator used in the polymerization reaction, an azo-based initiator is preferable, and for example, V-601 (product name) or V-65 (product name) manufactured by FUJIFILM Wako Pure Chemical Corporation is more preferable.

The polymer reaction is preferably carried out under a temperature condition of 80° C. to 110° C.

In the polymer reaction, it is preferable to use a catalyst such as an ammonium salt.

As the alkali-soluble resin, from the viewpoint that the effects of the present disclosure are more excellent, polymers shown below are more preferable. Content ratios (a to d) and weight-average molecular weights Mw of each of the structural units shown below can be appropriately changed according to the purpose.

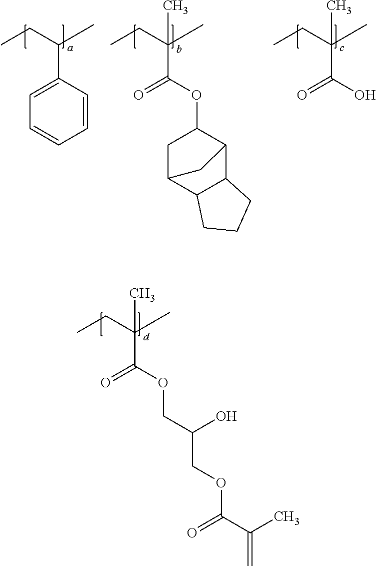

Preferred values for the content ratio of the above-described structural units are shown below.
a: 20% by mass to 60% by mass
b: 10% by mass to 50% by mass
c: 5% by mass to 25% by mass
d: 10% by mass to 50% by mass

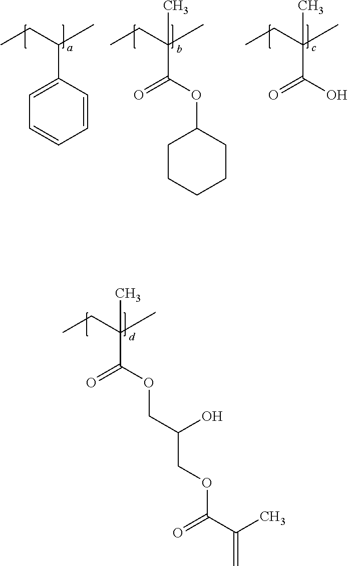

Preferred values for the content ratio of the above-described structural units are shown below.
a: 20% by mass to 60% by mass
b: 10% by mass to 50% by mass
c: 5% by mass to 25% by mass
d: 10% by mass to 50% by mass

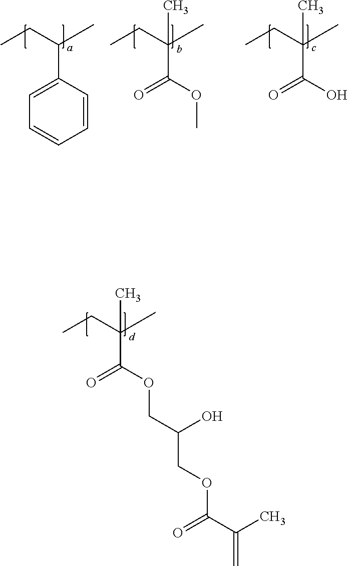

Preferred values for the content ratio of the above-described structural units are shown below.
a: 30% by mass to 65% by mass
b: 1% by mass to 20% by mass
c: 5% by mass to 25% by mass
d: 10% by mass to 50% by mass

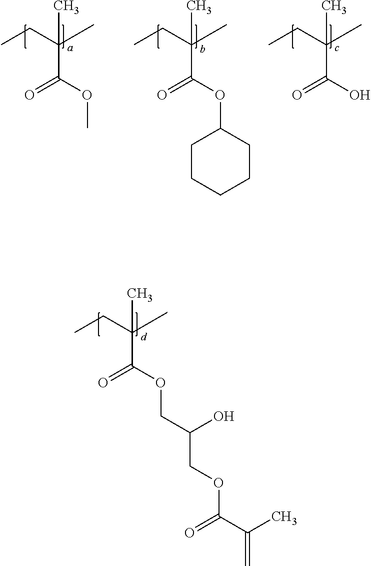

Preferred values for the content ratio of the above-described structural units are shown below.
a: 1% by mass to 20% by mass
b: 20% by mass to 60% by mass
c: 5% by mass to 25% by mass
d: 10% by mass to 50% by mass

The alkali-soluble resin may include a polymer (hereinafter, also referred to as a “polymer X”) including a structural unit having a carboxylic acid anhydride structure.

The carboxylic acid anhydride structure may be a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5- to 7-membered ring, more preferably a 5-membered ring or a 6-membered ring, and still more preferably a 5-membered ring.

The structural unit having a carboxylic acid anhydride structure is preferably a structural unit containing a divalent group obtained by removing two hydrogen atoms from a compound represented by Formula P-1 in a main chain, or a structural unit in which a monovalent group obtained by removing one hydrogen atom from a compound represented by Formula P-1 is bonded to the main chain directly or through a divalent linking group.

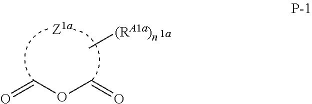

In Formula P-1, R^{A1a} represents a substituent, n^{1a} pieces of R^{A1a}'s may be the same or different, Z^{1a} represents a divalent group forming a ring including —C(═O)—O—C(—O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{A1a}'s may be the same or different. In addition, the plurality of R^{A1a}'s existing may be bonded to each other to form a ring, but it is preferable that they are not bonded to each other to form a ring.

As the structural unit having a carboxylic acid anhydride structure, a structural unit derived from an unsaturated carboxylic acid anhydride is preferable, a structural unit derived from an unsaturated cyclic carboxylic acid anhydride is more preferable, a structural unit derived from an unsaturated aliphatic carboxylic acid anhydride is still more preferable, a structural unit derived from maleic anhydride or itaconic anhydride is particularly preferable, and a structural unit derived from maleic acid anhydride is most preferable.

Hereinafter, specific examples of the structural unit having a carboxylic acid anhydride structure will be described, but the structural unit having a carboxylic acid anhydride structure is not limited to these specific examples.

In the following structural units, Rx represents a hydrogen atom, a methyl group, a CH₂OH group, or a CF₃ group, and Me represents a methyl group.

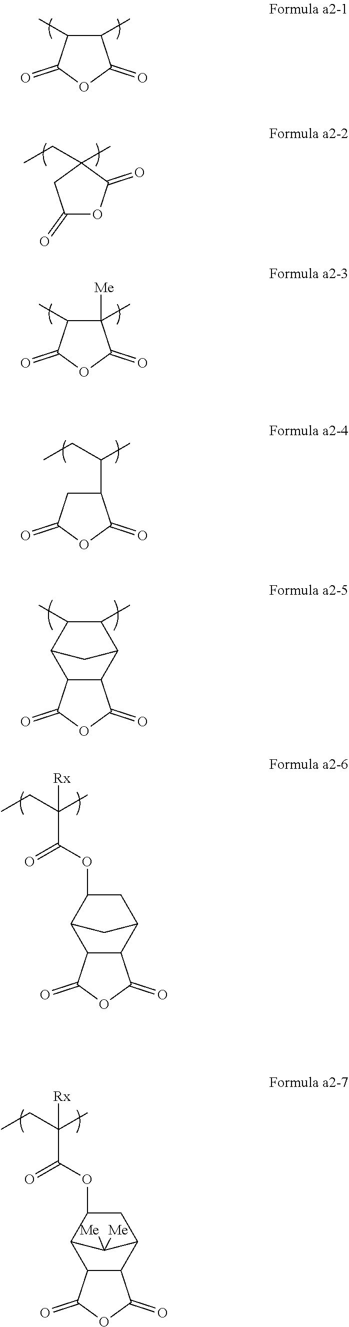

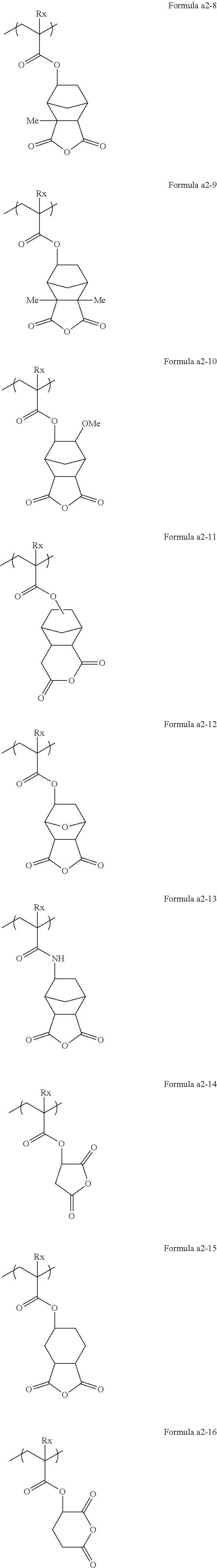

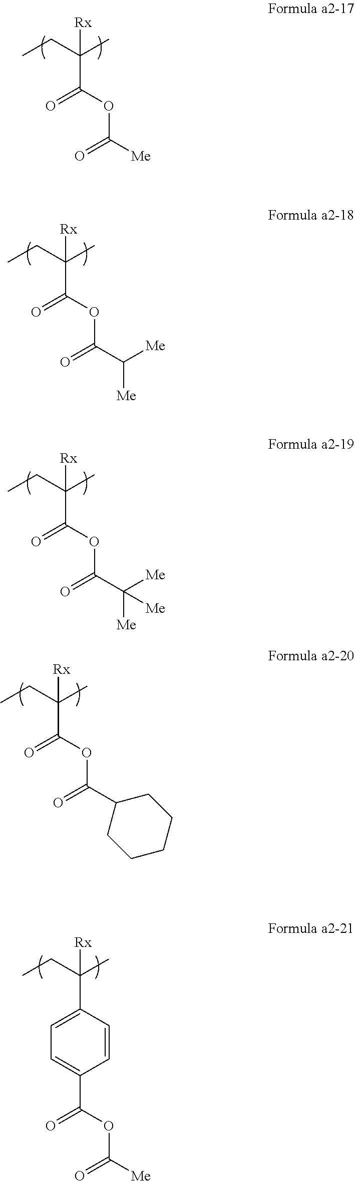

The polymer X may include only one kind of the structural unit having a carboxylic acid anhydride structure, or may include two or more kinds thereof.

The total content of the structural unit having a carboxylic acid anhydride structure in the polymer X is preferably 0 mol % to 60 mol %, more preferably 5 mol % to 40 mol %, and still more preferably 10 mol % to 35 mol % with respect to all structural units of the polymer X.

In a case where the photosensitive composition contains the polymer X, the photosensitive composition may contain only one kind of the polymer X, or may contain two or more kinds thereof.

In a case where the photosensitive composition contains the polymer X, from the viewpoint that the effects of the present disclosure are more excellent, a content of the polymer X in the photosensitive composition is preferably 0.1% by mass to 30% by mass, more preferably 0.2% by mass to 20% by mass, still more preferably 0.5% by mass to 20% by mass, and even more preferably 1% by mass to 20% by mass with respect to the total solid content of the photosensitive composition.

From the viewpoint that the effects of the present disclosure are more excellent, a weight-average molecular weight (Mw) of the alkali-soluble resin is preferably 5,000 or more, more preferably 10,000 or more, still more preferably 10,000 to 50,000, and particularly preferably 15,000 to 30,000.

An acid value of the alkali-soluble resin is preferably 10 mgKOH/g to 200 mgKOH/g, more preferably 60 mgKOH/g to 200 mgKOH/g, still more preferably 60 mgKOH/g to 150 mgKOH/g, and particularly preferably 70 mgKOH/g to 130 mgKOH/g.

The acid value of the alkali-soluble resin is a value measured according to the method described in JIS K 0070:1992.

From the viewpoint of developability, a dispersity of the alkali-soluble resin is preferably 1.0 to 6.0, more preferably 1.0 to 5.0, still more preferably 1.0 to 4.0, and particularly preferably 1.0 to 3.0.

In a case where the photosensitive composition according to the present disclosure contains an alkali-soluble resin, the photosensitive composition according to the present disclosure may contain only one kind of the alkali-soluble resin, or may contain two or more kinds thereof.

In a case where the photosensitive composition according to the present disclosure contains an alkali-soluble resin, from the viewpoint that the effects of the present disclosure are more excellent, a content of the alkali-soluble resin in the photosensitive composition is preferably 10% by mass to 90% by mass, more preferably 20% by mass to 80% by mass, and still more preferably 30% by mass to 70% by mass with respect to the total solid content of the photosensitive composition.

### (Polymerizable Monomer)

The photosensitive composition according to the present disclosure may contain a polymerizable monomer.

The polymerizable monomer is a monomer having a polymerizable group.

Examples of the polymerizable group include a radically polymerizable group and a cationically polymerizable group, and a radically polymerizable group is preferable.

The polymerizable monomer preferably includes a radically polymerizable monomer having an ethylenically unsaturated group.

As the ethylenically unsaturated group, a (meth)acryloxy group is preferable.

Examples of one suitable aspect of the polymerizable monomer include a compound represented by Formula (M) (simply referred to as “compound M”).

Q²-R¹-Q¹ Formula (M)

In Formula (M), Q¹ and Q² each independently represent a (meth)acryloyloxy group, and R¹ represents a divalent linking group having a chain structure.

From the viewpoint of easiness of synthesis, Q¹ and Q² in Formula (M) are preferably the same group.

In addition, from the viewpoint of reactivity, Q¹ and Q² in Formula (M) are preferably acryloyloxy groups.

From the viewpoint that the effects of the present disclosure are more excellent, R¹ in Formula (M) is preferably an alkylene group, an alkyleneoxyalkylene group (-L¹-O-L¹-), or a polyalkyleneoxyalkylene group (-(L¹-O) p-L¹-); more preferably a hydrocarbon group having 2 to 20 carbon atoms or a polyalkyleneoxyalkylene group; still more preferably an alkylene group having 4 to 20 carbon atoms; and particularly preferably a linear alkylene group having 6 to 18 carbon atoms.

It is sufficient that the hydrocarbon group has a chain structure at least in part, and a portion other than the chain structure is not particularly limited. For example, the portion may be a branched chain, a cyclic or a linear alkylene group having 1 to 5 carbon atoms, an arylene group, an ether bond, or a combination thereof, and an alkylene group or a group in which two or more alkylene groups and one or more arylene groups are combined is preferable, an alkylene group is more preferable, and a linear alkylene group is still more preferable.

L¹'s each independently represent an alkylene group; and an ethylene group, a propylene group, or a butylene group is preferable and an ethylene group or a 1,2-propylene group is more preferable.

p represents an integer of 2 or more, preferably an integer of 2 to 10.

From the viewpoint that the effects of the present disclosure are more excellent, the number of atoms in the shortest linking chain which links Q¹ and Q² in Formula (M) is preferably 3 to 50, more preferably 4 to 40, still more preferably 6 to 20, and particularly preferably 8 to 12.

In the present disclosure, the “number of atoms in the shortest linking chain which links Q¹ and Q²” is the shortest number of atoms linking from an atom in R¹ linked to Q¹ to an atom in R¹ linked to Q².

Specific examples of the compound M include 1,3-butanediol di(meth)acrylate, tetramethylene glycol di(meth)acrylate, neopentyl glycol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, hydrogenated bisphenol A di(meth)acrylate, hydrogenated bisphenol F di(meth)acrylate, polyethylene glycol di(meth)acrylate, polypropylene glycol di(meth)acrylate, poly (ethylene glycol/propylene glycol) di(meth)acrylate, and polybutylene glycol di(meth)acrylate. The above-described ester monomers can also be used as a mixture.

As the compound M, from the viewpoint that the effects of the present disclosure are more excellent, at least one compound selected from the group consisting of 1,6-hexanediol di(meth)acrylate, 1,9-nonanediol di(meth)acrylate, 1,10-decanediol di(meth)acrylate, and neopentyl glycol di(meth)acrylate is preferable; at least one compound selected from the group consisting of 1,6-hexanediol di(meth)acrylate, 1,9-nonanediol di(meth)acrylate, and 1,10-decanediol di(meth)acrylate is more preferable; and at least one compound selected from the group consisting of 1,9-nonanediol di(meth)acrylate and 1,10-decanediol di(meth)acrylate is still more preferable.

Examples of one suitable aspect of the polymerizable monomer include a bi- or higher functional ethylenically unsaturated compound.

In the present disclosure, the “bi- or higher functional ethylenically unsaturated compound” means a compound having two or more ethylenically unsaturated groups in one molecule.

As the ethylenically unsaturated group in the ethylenically unsaturated compound, a (meth)acryloyl group is preferable.

As the ethylenically unsaturated compound, a (meth)acrylate compound is preferable.

The bifunctional ethylenically unsaturated compound is not particularly limited and can be appropriately selected from a known compound.

Examples of the bifunctional ethylenically unsaturated compound other than the above-described compound M include tricyclodecane dimethanol di(meth)acrylate, dioxane glycol di(meth)acrylate, and 1,4-cyclohexanediol di(meth)acrylate.

Examples of a commercially available product of the bifunctional ethylenically unsaturated compound include tricyclodecane dimethanol diacrylate [product name: NK ESTER A-DCP, manufactured by Shin-Nakamura Chemical Co., Ltd.], tricyclodecane dimethanol dimethacrylate [product name: NK ESTER DCP, manufactured by Shin-Nakamura Chemical Co., Ltd.], 1,9-nonanediol diacrylate [product name: NK ESTER A-NOD-N, manufactured by Shin-Nakamura Chemical Co., Ltd.], 1,6-hexanediol diacrylate [product name: NK ESTER A-HD-N, manufactured by Shin-Nakamura Chemical Co., Ltd.], and dioxane glycol diacrylate [product name: KAYARAD (registered trademark) R-604, manufactured by Nippon Kayaku Co., Ltd.].

The tri- or higher functional ethylenically unsaturated compound is not particularly limited and can be appropriately selected from a known compound.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

In the present disclosure, the “(tri/tetra/penta/hexa) (meth)acrylate” has a concept including tri(meth)acrylate, tetra(meth)acrylate, penta (meth)acrylate, and hexa (meth)acrylate, and the “(tri/tetra) (meth)acrylate” has a concept including tri(meth)acrylate and tetra(meth)acrylate.

Examples of the polymerizable monomer also include a caprolactone-modified compound of a (meth)acrylate compound [KAYARAD (registered trademark) DPCA-20 manufactured by Nippon Kayaku Co., Ltd., A-9300-1CL manufactured by Shin-Nakamura Chemical Co., Ltd., or the like], an alkylene oxide-modified compound of a (meth)acrylate compound [KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like], and ethoxylated glycerin triacrylate [NK ESTER A-GLY-9E manufactured by Shin-Nakamura Chemical Co., Ltd., or the like].

Examples of the polymerizable monomer also include a urethane (meth)acrylate compound.

Examples of urethane (meth)acrylate include urethane di(meth)acrylate. Examples of the urethane di(meth)acrylate include propylene oxide-modified urethane di(meth)acrylate and ethylene oxide- and propylene oxide-modified urethane di(meth)acrylate.

In addition, examples of the urethane (meth)acrylate also include tri- or higher functional urethane (meth)acrylate. The lower limit of the number of functional groups is more preferably 6 or more and still more preferably 8 or more. The upper limit of the number of functional groups is preferably 20 or less.

Examples of the tri- or higher functional urethane (meth)acrylate include 8UX-015A (product name) manufactured by Taisei Fine Chemical Co., Ltd.; UA-32P (product name), U-15HA (product name), and UA-1100H (product name) manufactured by Shin-Nakamura Chemical Co., Ltd.; AH-600 (product name) manufactured by KYOEISHA CHEMICAL Co., LTD; and UA-306H (product name), UA-306T (product name), UA-306I (product name), UA-510H (product name), and UX-5000 (product name) manufactured by Nippon Kayaku Co., Ltd.

Examples of one suitable aspect of the polymerizable monomer include an ethylenically unsaturated compound having an acid group.

Examples of the acid group include a phosphoric acid group, a sulfo group, and a carboxy group.

The acid group is preferably a carboxy group.

Examples of the ethylenically unsaturated compound having an acid group include a tri- or tetra-functional ethylenically unsaturated compound having an acid group [a compound obtained by introducing a carboxy group to pentaerythritol tri- and tetra-acrylate (PETA) skeleton (acid value: 80 mgKOH/g to 120 mgKOH/g)], and a penta- or hexa-functional ethylenically unsaturated compound having an acid group [a compound obtained by introducing a carboxy group to dipentaerythritol penta- and hexa-acrylate (DPHA) skeleton (acid value: 25 mgKOH/g to 70 mgKOH/g)].

The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable.

In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced.

The bi- or higher functional ethylenically unsaturated compound having a carboxy group is not particularly limited and can be appropriately selected from a known compound.

Examples of the bi- or higher functional ethylenically unsaturated compound having a carboxy group include ARONIX (registered trademark) TO-2349 [manufactured by Toagosei Co., Ltd.], ARONIX (registered trademark) M-520 [manufactured by Toagosei Co., Ltd.], and ARONIX (registered trademark) M-510 [manufactured by Toagosei Co., Ltd.].

As the ethylenically unsaturated compound having an acid group, polymerizable compounds having an acid group, which are described in paragraphs [0025] to [0030] of JP2004-239942A, are preferable, and the contents described in this publication are incorporated herein by reference.

Examples of the polymerizable monomer also include a compound obtained by reacting a polyhydric alcohol with an α,β-unsaturated carboxylic acid, a compound obtained by reacting a glycidyl group-containing compound with an α,β-unsaturated carboxylic acid, urethane monomer such as a (meth)acrylate compound having a urethane bond, phthalate compounds such as γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate, and (meth)acrylic acid alkyl esters.

These compounds are used alone or in combination of two or more kinds thereof.

Examples of the compound obtained by reacting a polyhydric alcohol with an α,β-unsaturated carboxylic acid include bisphenol A-based (meth)acrylate compounds such as 2,2-bis(4-((meth)acryloxypolyethoxy)phenyl) propane, 2,2-bis(4-((meth)acryloxypolypropoxy)phenyl) propane, and 2,2-bis(4-((meth)acryloxypolyethoxypolypropoxy)phenyl) propane, polyethylene glycol di(meth)acrylate having 2 to 14 ethylene oxide groups, polypropylene glycol di(meth)acrylate having 2 to 14 propylene oxide groups, polyethylene polypropylene glycol di(meth)acrylate having 2 to 14 ethylene oxide groups and 2 to 14 propylene oxide groups, trimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylolpropane pentaethoxy tri(meth)acrylate, di(trimethylolpropane) tetraacrylate, tetramethylolmethane tri(meth)acrylate, tetramethylolmethane tetra(meth)acrylate, dipentaerythritol tetra(meth)acrylate, dipentaerythritol penta (meth)acrylate, and dipentaerythritol hexa (meth)acrylate.

As the compound obtained by reacting a polyhydric alcohol with an α,β-unsaturated carboxylic acid, an ethylenically unsaturated compound having a tetramethylolmethane structure or a trimethylolpropane structure is preferable; and tetramethylolmethane tri(meth)acrylate, tetramethylolmethane tetra(meth)acrylate, trimethylolpropane tri(meth)acrylate, or di(trimethylolpropane) tetraacrylate is more preferable.

Examples of the polymerizable monomer also include a caprolactone-modified compound of ethylenically unsaturated compound [for example, KAYARAD (registered trademark) DPCA-20 manufactured by Nippon Kayaku Co., Ltd., A-9300-1CL manufactured by Shin-Nakamura Chemical Co., Ltd., and the like], an alkylene oxide-modified compound of ethylenically unsaturated compound [for example, KAYARAD (registered trademark) RP-1040 manufactured by Nippon Kayaku Co., Ltd., ATM-35E and A-9300 manufactured by Shin-Nakamura Chemical Co., Ltd., and EBECRYL (registered trademark) 135 manufactured by Daicel-Allnex Ltd.], and ethoxylated glycerin triacrylate [for example, A-GLY-9E manufactured by Shin-Nakamura Chemical Co., Ltd.].

As the polymerizable monomer, from the viewpoint of excellent developability of the photosensitive composition layer formed of the photosensitive composition, a polymerizable monomer including an ester bond (particularly, an ethylenically unsaturated compound) is also preferable.

The ethylenically unsaturated compound including an ester bond is not particularly limited as long as it includes an ester bond in the molecule; but from the viewpoint that the effects of the present disclosure are excellent, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

As the ethylenically unsaturated compound, from the viewpoint of imparting reliability, it is preferable to include an ethylenically unsaturated compound having an aliphatic group having 6 to 20 carbon atoms and the ethylenically unsaturated compound having a tetramethylolmethane structure or a trimethylolpropane structure.

Examples of the ethylenically unsaturated compound having an aliphatic structure having 6 or more carbon atoms include 1,9-nonanediol di(meth)acrylate, 1,10-decanediol di(meth)acrylate, and tricyclodecane dimethanol di(meth)acrylate.

Examples of one suitable aspect of the polymerizable monomer include a polymerizable compound (preferably, a bifunctional ethylenically unsaturated compound) having an aliphatic hydrocarbon ring structure.

As the above-described polymerizable monomer, a polymerizable compound having a ring structure in which two or more aliphatic hydrocarbon rings are fused (preferably, a structure selected from the group consisting of a tricyclodecane structure and a tricyclodecene structure) is preferable, a bifunctional ethylenically unsaturated compound having a ring structure in which two or more aliphatic hydrocarbon rings are fused is more preferable, and tricyclodecane dimethanol di(meth)acrylate is still more preferable.

As the aliphatic hydrocarbon ring structure, from the viewpoint that the effects of the present disclosure are more excellent, a cyclopentane structure, a cyclohexane structure, a tricyclodecane structure, a tricyclodecene structure, a norbornane structure, or an isophorone structure is preferable.

A molecular weight of the polymerizable monomer is not particularly limited, but is preferably 200 to 3,000, more preferably 250 to 2,600, still more preferably 280 to 2,200, and particularly preferably 300 to 2,200.

A proportion of the content of the polymerizable monomer having a molecular weight of 300 or less in the polymerizable monomers contained in the photosensitive composition is preferably 30% by mass or less, more preferably 25% by mass or less, and still more preferably 20% by mass or less with respect to the content of all the polymerizable monomers contained in the photosensitive composition.

As one suitable aspect of the photosensitive composition, the photosensitive composition preferably contains the bi- or higher functional ethylenically unsaturated compound, more preferably contains the tri- or higher functional ethylenically unsaturated compound, and still more preferably contains a tri- or tetrafunctional ethylenically unsaturated compound as the polymerizable monomer.

In addition, as one suitable aspect of the photosensitive composition, the photosensitive composition preferably contains the bifunctional ethylenically unsaturated compound having an aliphatic hydrocarbon ring structure as the polymerizable monomer, and the resin having a structural unit having an aliphatic hydrocarbon ring as the alkali-soluble resin.

In addition, as one suitable aspect of the photosensitive composition, the photosensitive composition preferably contains the compound M and the ethylenically unsaturated compound having an acid group as the polymerizable monomer; more preferably contains 1,9-nonanediol diacrylate, tricyclodecane dimethanol diacrylate, and a polyfunctional ethylenically unsaturated compound having a carboxylic acid group as the polymerizable monomer; and still more preferably contains 1,9-nonanediol diacrylate, tricyclodecane dimethanol diacrylate, and a succinic acid-modified form of dipentaerythritol pentaacrylate as the polymerizable monomer.

In addition, as one suitable aspect of the photosensitive composition, the photosensitive composition preferably contains the compound M and the ethylenically unsaturated compound having an acid group as the polymerizable monomer, and a thermal crosslinking compound described later; and more preferably contains the compound M and the ethylenically unsaturated compound having an acid group as the polymerizable monomer, and a blocked isocyanate compound described later.

In addition, as one suitable aspect of the photosensitive composition, from the viewpoint of development residue inhibitory property and rust preventive property, the photosensitive composition preferably contains the bifunctional ethylenically unsaturated compound [preferably, a bifunctional (meth)acrylate compound] and the tri- or higher functional ethylenically unsaturated compound [preferably, a tri- or higher functional (meth)acrylate compound].

A mass ratio of a content of the bifunctional ethylenically unsaturated compound and a content of the tri- or higher functional ethylenically unsaturated compound is preferably 10:90 to 90:10 and more preferably 30:70 to 70:30.

A proportion of the content of the bifunctional ethylenically unsaturated compound to the total amount of all ethylenically unsaturated compounds is preferably 20% by mass to 80% by mass and more preferably 30% by mass to 70% by mass.

The content of the bifunctional ethylenically unsaturated compound in the photosensitive composition is preferably 10% by mass to 60% by mass and more preferably 15% by mass to 40% by mass with respect to the total solid content of the photosensitive composition.

In addition, as one suitable aspect of the photosensitive composition, from the viewpoint of rust preventive property, the photosensitive composition preferably contains the compound M and the bifunctional ethylenically unsaturated compound having an aliphatic hydrocarbon ring structure.

In addition, as one suitable aspect of the photosensitive composition, from the viewpoint of substrate adhesiveness, development residue inhibitory property, and rust preventive property, the photosensitive composition preferably contains the compound M and the ethylenically unsaturated compound having an acid group; more preferably contains the compound M, the bifunctional ethylenically unsaturated compound having an aliphatic hydrocarbon ring structure, and the ethylenically unsaturated compound having an acid group; still more preferably contains the compound M, the bifunctional ethylenically unsaturated compound having an aliphatic hydrocarbon ring structure, the tri- or higher functional ethylenically unsaturated compound, and the ethylenically unsaturated compound having an acid group; and particularly preferably contains the compound M, the bifunctional ethylenically unsaturated compound having an aliphatic hydrocarbon ring structure, the tri- or higher functional ethylenically unsaturated compound, the ethylenically unsaturated compound having an acid group, and the urethane (meth)acrylate compound.

In addition, as one suitable aspect of the photosensitive composition, from the viewpoint of substrate adhesiveness, development residue inhibitory property, and rust preventive property, the photosensitive composition preferably contains 1,9-nonanediol diacrylate and the polyfunctional ethylenically unsaturated compound having a carboxylic acid group; more preferably contains 1,9-nonanediol diacrylate, tricyclodecane dimethanol diacrylate, and the polyfunctional ethylenically unsaturated compound having a carboxylic acid group; still more preferably contains 1,9-nonanediol diacrylate, tricyclodecane dimethanol diacrylate, dipentaerythritol hexaacrylate, and an ethylenically unsaturated compound having a carboxylic acid group; and particularly preferably contains 1,9-nonanediol diacrylate, tricyclodecane dimethanol diacrylate, an ethylenically unsaturated compound having a carboxylic acid group, and a urethane acrylate compound.

The photosensitive composition may contain a monofunctional ethylenically unsaturated compound as the ethylenically unsaturated compound.

A content of the bi- or higher functional ethylenically unsaturated compound in the ethylenically unsaturated compound is preferably 60% by mass to 100% by mass, more preferably 80% by mass to 100% by mass, and still more preferably 90% by mass to 100% by mass with respect to the total content of all ethylenically unsaturated compounds contained in the photosensitive composition.

In a case where the photosensitive composition according to the present disclosure contains a polymerizable monomer, the photosensitive composition according to the present disclosure may contain only one kind of the polymerizable monomer (particularly, the ethylenically unsaturated compound), or may contain two or more kinds thereof.

In a case where the photosensitive composition according to the present disclosure contains a polymerizable monomer, a content of the polymerizable monomer (particularly, the ethylenically unsaturated compound) in the photosensitive composition is preferably 1% by mass to 70% by mass, more preferably 5% by mass to 70% by mass, still more preferably 5% by mass to 60% by mass, and particularly preferably 5% by mass to 50% by mass with respect to the total solid content of the photosensitive composition.

### (Photopolymerization Initiator)

The photosensitive composition according to the present disclosure may contain a photopolymerization initiator.

The photopolymerization initiator is not particularly limited and a known photopolymerization initiator can be used.

The photopolymerization initiator may be a photoradical polymerization initiator.

Examples of the photopolymerization initiator include a photopolymerization initiator having an oxime ester structure (hereinafter also referred to as an “oxime-based photopolymerization initiator”), a photopolymerization initiator having an a-aminoalkylphenone structure (hereinafter also referred to as an “a-aminoalkylphenone-based photopolymerization initiator”), a photopolymerization initiator having an a-hydroxyalkylphenone structure (hereinafter also referred to as an “a-hydroxyalkylphenone-based photopolymerization initiator”), a photopolymerization initiator having an acylphosphine oxide structure (hereinafter also referred to as an “acylphosphine oxide-based photopolymerization initiator”), and a photopolymerization initiator having an N-phenylglycine structure (hereinafter also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators described in paragraphs [0031] to [0042] of JP2011-95716A and paragraphs [0064] to [0081] of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], IRGACURE (registered trademark) OXE03 (manufactured by BASF SE), IRGACURE (registered trademark) OXE04 (manufactured by BASF SE), 2-(dimethylamino)-2-[(4-methylphenyl)methyl]-1-[4-(4-morpholinyl)phenyl]-1-butanone [product name: Omnirad (registered trademark) 379EG, manufactured by IGM Resins B.V.], 2-methyl-1-(4-methylthiophenyl)-2-morpholinopropan-1-one [product name: Omnirad (registered trademark) 907, manufactured by IGM Resins B.V.], 2-hydroxy-1-{4-[4-(2-hydroxy-2-methylpropionyl) benzyl]phenyl}-2-methylpropan-1-one [product name: Omnirad (registered trademark) 127, manufactured by IGM Resins B.V.], 2-benzyl-2-dimethylamino-1-(4-morpholinophenyl) butanone-1 [product name: Omnirad (registered trademark) 369, manufactured by IGM Resins B.V.], 2-hydroxy-2-methyl-1-phenylpropan-1-one [product name: Omnirad (registered trademark) 1173, manufactured by IGM Resins B.V.], 1-hydroxy cyclohexyl phenyl ketone [product name: Omnirad (registered trademark) 184, manufactured by IGM Resins B.V.], 2,2-dimethoxy-1,2-diphenylethan-1-one (product name: Omnirad (registered trademark) 651, manufactured by IGM Resins B.V.], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by TRONLY), 3-cyclohexyl-1-(6-(2-(benzoyloxyimino) hexanoyl)-9-ethyl-9H-carbazole-3-yl)-propan-1,2-dione-2-(O-benzoyloxime) (product name: TR-PBG-391, manufactured by TRONLY), and 1-(biphenyl-4-yl)-2-methyl-2-morpholinopropan-1-one (product name: APi-307, manufactured by Shenzhen UV-Chem Tech Co., Ltd.).

In a case where the photosensitive composition according to the present disclosure contains a photopolymerization initiator, the photosensitive composition according to the present disclosure may contain only one kind of the photopolymerization initiator, or may contain two or more kinds thereof.

In a case where the photosensitive composition according to the present disclosure contains two or more kinds of the photopolymerization initiators, it is preferable that the photosensitive composition contains the oxime-based photopolymerization initiator and at least one selected from the group consisting of the α-aminoalkylphenone-based photopolymerization initiator and the α-hydroxyalkylphenone-based polymerization initiator.

In a case where the photosensitive composition according to the present disclosure contains a photopolymerization initiator, a content of the photopolymerization initiator in the photosensitive composition is preferably 0.1% by mass or more, more preferably 0.5% by mass or more, and still more preferably 1.0% by mass or more with respect to the total solid content of the photosensitive composition. The upper limit of the content of the photopolymerization initiator in the photosensitive composition according to the present disclosure is preferably 10% by mass or less, and more preferably 5% by mass or less with respect to the total solid content of the photosensitive composition.

### (Acid Generator)

In a case where the photosensitive composition according to the present disclosure contains a coloring material precursor which colors black by acid, the photosensitive composition may contain an acid generator.

The acid generator may be a photoacid generator or a thermal acid generator, but is preferably a photoacid generator.

The photoacid generator is a compound capable of generating an acid by irradiation with radiation such as ultraviolet rays, far ultraviolet rays, X-rays, and charged particle rays.

The photoacid generator is preferably a compound which is sensitive to actinic rays having a wavelength of 300 nm or more, preferably 300 to 450 nm, and generates an acid. A photo-acid generator which is not directly sensitive to actinic rays having a wavelength of 300 nm or more can also be preferably used in combination with a sensitizer as long as it is a compound which is sensitive to actinic rays having a wavelength of 300 nm or more and generates an acid by being used in combination with the sensitizer.

The photo-acid generator is preferably a photo-acid generator which generates an acid with a pKa of 4 or less, more preferably a photo-acid generator which generates an acid with a pKa of 3 or less, and even more preferably a photo-acid generator which generates an acid with a pKa of 2 or less. The lower limit of pKa is not particularly limited, but is, for example, preferably-10 or more.

Examples of the photoacid generator include an ionic photoacid generator and a nonionic photoacid generator.

Examples of the ionic photoacid generator include an onium salt compound and a quaternary ammonium salt compound. Examples of the onium salt compound include a diaryliodonium salt compound and a triarylsulfonium salt compound.

The ionic photoacid generator is preferably an onium salt compound, and more preferably at least one selected from the group consisting of a diaryliodonium salt compound and a triarylsulfonium salt compound.

As the ionic photoacid generator, for example, ionic photoacid generators described in paragraphs [0114] to [0133] of JP2014-85643A can also be preferably used.

Examples of the nonionic photoacid generator include a trichloromethyl-s-triazine compound, a diazomethane compound, an imide sulfonate compound, and an oxime sulfonate compound.

Specific examples of the trichloromethyl-s-triazine compound, the diazomethane compound, and the imide sulfonate compound include compounds described in paragraphs [0083] to [0088] of JP2011-221494A.

Specific examples of the oxime sulfonate compound include compounds described in paragraphs [0084] to [0088] of WO2018/179640A.

From the viewpoint of sensitivity, the photoacid generator is, for example, preferably at least one compound selected from the group consisting of an onium salt compound and an oxime sulfonate compound, and more preferably an oxime sulfonate compound.

In a case where the photosensitive composition according to the present disclosure contains an acid generator, the photosensitive composition according to the present disclosure may contain only one kind of the acid generator, or may contain two or more kinds thereof.

In a case where the photosensitive composition according to the present disclosure contains an acid generator, from the viewpoint of color developability of the coloring material precursor which colors black by acid, a content of the acid generator is preferably 0.2% by mass to 5.0% by mass and more preferably 0.5% by mass to 3.0% by mass with respect to the total solid content of the photosensitive composition.

### (Sensitizer)

The photosensitive composition according to the present disclosure may contain a sensitizer.

The sensitizer has a function of further improving sensitivity of the photopolymerization initiator to actinic ray, suppressing inhibition of polymerization of the polymerizable compound by oxygen, or the like.

Examples of the sensitizer include triethanolamine, p-dimethylaminobenzoic acid ethyl ester, p-formyldimethylaniline, p-methylthiodimethylaniline, N-phenylglycine, tributyl tin acetate, and trithiane.

In a case where the photosensitive composition according to the present disclosure contains a sensitizer, the photosensitive composition according to the present disclosure may contain only one kind of the sensitizer, or may contain two or more kinds thereof.

In a case where the photosensitive composition according to the present disclosure contains a sensitizing agent, a content of the sensitizing agent in the photosensitive composition is preferably 0.01% by mass to 1% by mass, and more preferably 0.02% by mass to 0.5% by mass with respect to the total solid content of the photosensitive composition.

### (Heterocyclic Compound)

The photosensitive composition according to the present disclosure may contain a heterocyclic compound.

A heterocyclic ring included in the heterocyclic compound may be a monocyclic or polycyclic heterocyclic ring.

Examples of a heteroatom included in the heterocyclic compound include an oxygen atom, a nitrogen atom, and a sulfur atom.

The heterocyclic compound preferably includes at least one atom selected from the group consisting of a nitrogen atom, an oxygen atom, and a sulfur atom, and more preferably includes a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound.

The heterocyclic compound is preferably at least one compound selected from the group consisting of a triazole compound, a benzotriazole compound, a tetrazole compound, a thiadiazole compound, a triazine compound, a rhodanine compound, a thiazole compound, a benzothiazole compound, a benzimidazole compound, and a benzoxazole compound; and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below.

Examples of the triazole compound and the benzotriazole compound include the following compounds.

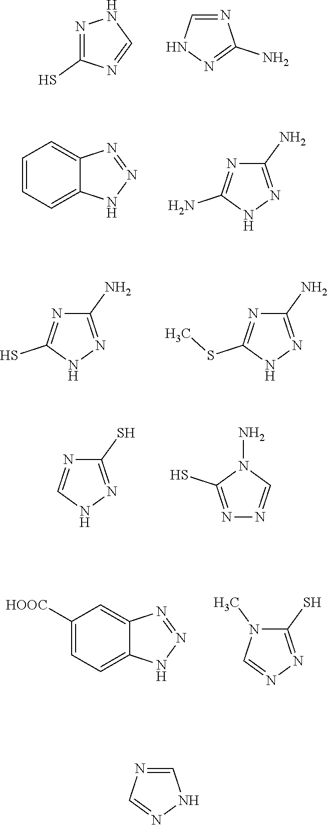

Examples of the tetrazole compound include the following compounds.

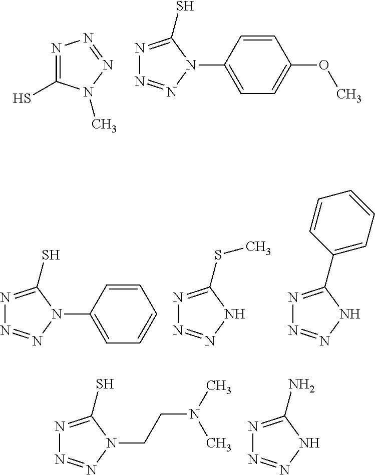

Examples of the thiadiazole compound include the following compounds.

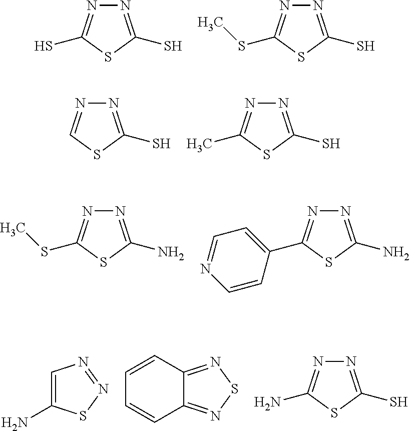

Examples of the triazine compound include the following compounds.

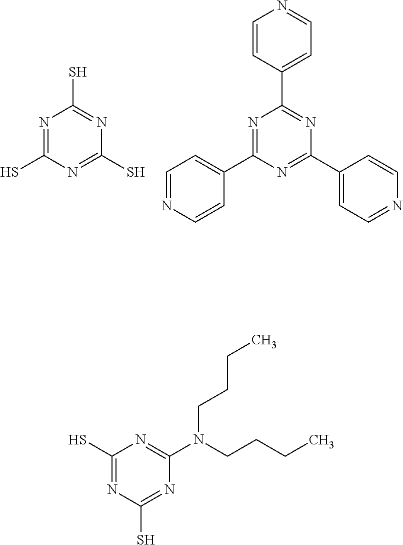

Examples of the rhodanine compound include the following compounds.

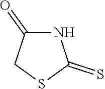

Examples of the thiazole compound include the following compounds.

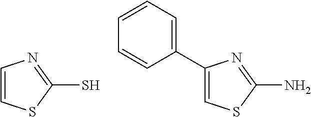 [SMILES: Sc1nccs1 ; Nc1nc(-c2ccccc2)cs1]

Examples of the benzothiazole compound include the following compounds.

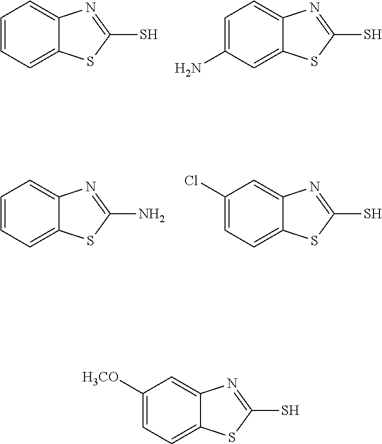 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

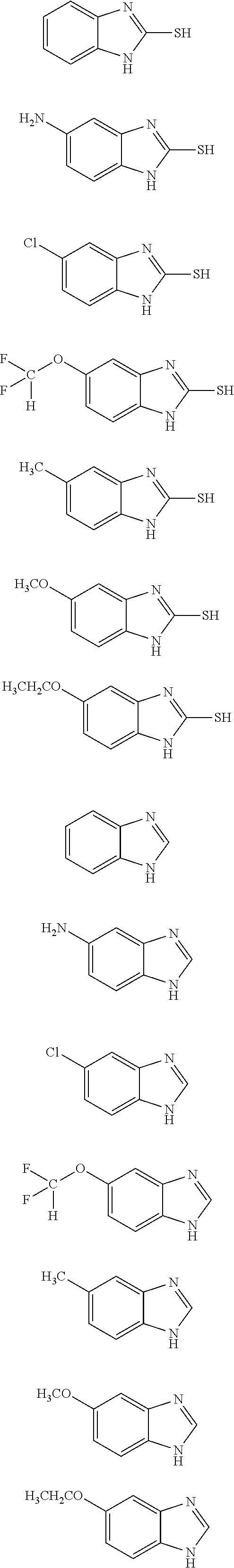

Examples of the benzoxazole compound include the following compounds.

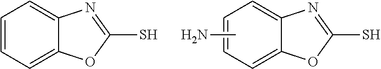

In a case where the photosensitive composition according to the present disclosure contains a heterocyclic compound, the photosensitive composition according to the present disclosure may contain only one kind of the heterocyclic compound, or may contain two or more kinds thereof.

In a case where the photosensitive composition according to the present disclosure contains a heterocyclic compound, a content of the heterocyclic compound in the photosensitive composition is preferably 0.01% by mass to 20.0% by mass, more preferably 0.10% by mass to 10.0% by mass, still more preferably 0.30% by mass to 8.0% by mass, and particularly preferably 0.50% by mass to 5.0% by mass with respect to the total solid content of the photosensitive composition.

### (Aliphatic Thiol Compound)

The photosensitive composition according to the present disclosure may contain an aliphatic thiol compound.

In a case where the photosensitive composition contains an aliphatic thiol compound, the aliphatic thiol compound undergoes an ene-thiol reaction with a radically polymerizable compound having an ethylenically unsaturated group, so that a film to be obtained is suppressed from being cured and shrunk, and the stress of the film is relieved.

As the aliphatic thiol compound, a monofunctional aliphatic thiol compound or a polyfunctional aliphatic thiol compound (that is, a bi- or higher functional aliphatic thiol compound) is preferable.

As the aliphatic thiol compound, from the viewpoint of adhesiveness of a pattern to be formed (particularly, adhesiveness after exposure), a polyfunctional aliphatic thiol compound is preferable.

In the present disclosure, the “polyfunctional aliphatic thiol compound” refers to an aliphatic compound having two or more thiol groups (also referred to as “mercapto groups”) in a molecule.

As the polyfunctional aliphatic thiol compound, a low-molecular-weight compound having a molecular weight of 100 or more is preferable. Specifically, the molecular weight of the polyfunctional aliphatic thiol compound is more preferably 100 to 1,500 and still more preferably 150 to 1,000.

From the viewpoint of adhesiveness of the formed pattern, for example, the number of functional groups in the polyfunctional aliphatic thiol compound is preferably 2 to 10, more preferably 2 to 8, and still more preferably 2 to 6.

Examples of the polyfunctional aliphatic thiol compound include trimethylolpropane tris(3-mercaptobutyrate), 1,4-bis(3-mercaptobutyryloxy) butane, pentaerythritol tetrakis(3-mercaptobutyrate), 1,3,5-tris(3-mercaptobutyryloxyethyl)-1,3,5-triazine-2,4,6 (1H,3H,5H)-trione, trimethylolethane tris(3-mercaptobutyrate), tris [(3-mercaptopropionyloxy) ethyl]isocyanurate, trimethylolpropane tris(3-mercaptopropionate), pentaerythritol tetrakis(3-mercaptopropionate), tetraethylene glycol bis (3-mercaptopropionate), dipentaerythritol hexakis(3-mercaptopropionate), ethylene glycol bisthiopropionate, 1,4-bis(3-mercaptobutyryloxy) butane, 1,2-ethanedithiol, 1,3-propanedithiol, 1,6-hexamethylenedithiol, 2,2′-(ethylenedithio) diethanethiol, meso-2,3-dimercaptosuccinic acid, and di(mercaptoethyl) ether.

Among the above, the polyfunctional aliphatic thiol compound is preferably at least one compound selected from the group consisting of trimethylolpropane tris(3-mercaptobutyrate), 1,4-bis(3-mercaptobutyryloxy) butane, and 1,3,5-tris(3-mercaptobutyryloxyethyl)-1,3,5-triazine-2,4,6 (1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

In a case where the photosensitive composition according to the present disclosure contains an aliphatic thiol compound, the photosensitive composition according to the present disclosure may contain only one kind of the aliphatic thiol compound, or may contain two or more kinds thereof.

In a case where the photosensitive composition according to the present disclosure contains an aliphatic thiol compound, a content of the aliphatic thiol compound in the photosensitive composition is preferably 5% by mass or more, more preferably 5% by mass to 50% by mass, still more preferably 5% by mass to 30% by mass, and particularly preferably 8% by mass to 20% by mass with respect to the total solid content of the photosensitive composition.

### (Thermal Crosslinking Compound)

From the viewpoint of hardness of a cured film to be obtained and pressure-sensitive adhesiveness of an uncured film to be obtained, the photosensitive composition according to the present disclosure preferably contains a thermal crosslinking compound.

In the present disclosure, a thermal crosslinking compound having an ethylenically unsaturated group, which will be described later, is not treated as the ethylenically unsaturated compound, but is treated as the thermal crosslinking compound.

Examples of the thermal crosslinking compound include an epoxy compound, an oxetane compound, a methylol compound, and a blocked isocyanate compound.

As the thermal crosslinking compound, from the viewpoint of hardness of a cured film to be obtained and pressure-sensitive adhesiveness of an uncured film to be obtained, a blocked isocyanate compound is preferable.

Since the blocked isocyanate compound reacts with a hydroxy group and a carboxy group, for example, in a case where at least one of the alkali-soluble resin or the radically polymerizable compound having an ethylenically unsaturated group has at least one of a hydroxy group or a carboxy group, hydrophilicity of the formed film tends to decrease, and the function as a protective film tends to be strengthened. The blocked isocyanate compound refers to “compound having a structure in which the isocyanate group of isocyanate is protected (so-called masked) with a blocking agent”.

A dissociation temperature of the blocked isocyanate compound is not particularly limited, but for example, it is preferably 90° C. to 160° C. and more preferably 100° C. to 150° C.

The dissociation temperature of blocked isocyanate means “temperature at an endothermic peak accompanied with a deprotection reaction of blocked isocyanate in a case where the measurement is performed by differential scanning calorimetry (DSC) analysis using a differential scanning calorimeter”.

As the differential scanning calorimeter, for example, a differential scanning calorimeter (model number: DSC6200) manufactured by Seiko Instruments Inc. can be suitably used. However, the differential scanning calorimeter is not limited thereto.

Examples of the blocking agent having a dissociation temperature of 100° C. to 160° C. include active methylene compounds [diester malonates (dimethyl malonate, diethyl malonate, di-n-butyl malonate, di-2-ethylhexyl malonate, and the like)], and oxime compounds (compound having a structure represented by —C(═N—OH)— in a molecule, such as formaldoxime, acetoaldoxime, acetoxime, methyl ethyl ketoxime, and cyclohexanone oxime).

Among these, from the viewpoint of storage stability, the blocking agent having a dissociation temperature of 90° C. to 160° C. is preferably, for example, at least one compound selected from the group consisting of an oxime compound and a pyrazole compound.

From the viewpoint of improving brittleness of the film and improving the adhesion to an object to be transferred, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group.

The polymerizable group is not particularly limited, and a known polymerizable group can be used, and a radically polymerizable group is preferable.

Examples of the polymerizable group include a (meth)acryloxy group, a (meth)acrylamide group, an ethylenically unsaturated group such as styryl group, and an epoxy group such as a glycidyl group.

Among the above, as the polymerizable group, an ethylenically unsaturated group is preferable, a (meth)acryloxy group is more preferable, and an acryloxy group still more preferable.

As the blocked isocyanate compound, a commercially available product can be used.

Examples of the commercially available product of the blocked isocyanate compound include Karenz (registered trademark) AOI-BM, Karenz (registered trademark) MOI-BM, and Karenz (registered trademark) MOI-BP [all of which are manufactured by SHOWA DENKO K.K.]; and block-type DURANATE series [for example, DURANATE (registered trademark) TPA-B80E, DURANATE (registered trademark) SBN-70D, and DURANATE (registered trademark) WT32-B75P].

From the viewpoint that the effects of the present disclosure are more excellent, it is preferable that the photosensitive composition contains a blocked isocyanate compound having an NCO value of 4.5 mmol/g or more (hereinafter, referred to as “first blocked isocyanate compound”).

The NCO value of the first blocked isocyanate compound is preferably 5.0 mmol/g or more, and more preferably 5.3 mmol/g or more. In addition, from the viewpoint that the effects of the present disclosure are more excellent, the upper limit of the NCO value of the first blocked isocyanate compound is preferably 8.0 mmol/g or less, more preferably 6.0 mmol/g or less, still more preferably 5.8 mmol/g or less, and particularly preferably 5.7 mmol/g or less.

The NCO value of blocked isocyanate compound in the present disclosure means the number of moles of isocyanate groups included in 1 g of the blocked isocyanate compound, and is a value calculated from a structural formula of the blocked isocyanate compound.

From the viewpoint that the effects of the present disclosure are more excellent, the first blocked isocyanate compound preferably has a ring structure.

Examples of the ring structure include an aliphatic hydrocarbon ring, an aromatic hydrocarbon ring, and a heterocyclic ring, and from the viewpoint that the effects of the present disclosure are more excellent, an aliphatic hydrocarbon ring or an aromatic hydrocarbon ring is preferable, and an aliphatic hydrocarbon ring is more preferable.

Specific examples of the aliphatic hydrocarbon ring include a cyclopentane ring and a cyclohexane ring, and among these, a cyclohexane ring is preferable.

Specific examples of the aromatic hydrocarbon ring include a benzene ring and a naphthalene ring, and among these, a benzene ring is preferable.

Specific examples of the heterocyclic ring include an isocyanurate ring.

In a case where the first blocked isocyanate compound has a ring structure, from the viewpoint that the effects of the present disclosure are more excellent, the number of rings is preferably 1 or 2 and more preferably 1.

In a case where the first blocked isocyanate compound includes a fused ring, the number of rings constituting the fused ring is counted, for example, the number of rings in the naphthalene ring is counted as 2.

From the viewpoint that the strength of the formed pattern is excellent and the effects of the present disclosure are more excellent, the number of blocked isocyanate groups in the first blocked isocyanate compound is preferably 2 to 5, more preferably 2 or 3, and still more preferably 2.

From the viewpoint that the effects of the present disclosure are more excellent, the first blocked isocyanate compound is preferably a blocked isocyanate compound represented by Formula Q.

B¹-A¹-L¹-A²-B² Formula Q

In Formula Q, B¹ and B² each independently represent a blocked isocyanate group.

The blocked isocyanate group is not particularly limited; but from the viewpoint that the effects of the present disclosure are more excellent, a group in which an isocyanate group is blocked with an oxime compound is preferable, and a group in which an isocyanate group is blocked with methyl ethyl ketooxime (specifically, a group represented by *—NH—C(═O)—O—N═C (CH₃)—C₂H₅; * represents a bonding position with A¹ or A²) is more preferable.

B¹ and B² are preferably the same group.

In Formula Q, A¹ and A² each independently represent a single bond or an alkylene group having 1 to 10 carbon atoms, and an alkylene group having 1 to 10 carbon atoms is preferable.

The alkylene group may be linear, branched, or cyclic, and is preferably linear.

The number of carbon atoms in the alkylene group is 1 to 10, and from the viewpoint that the effects of the present disclosure are more excellent, it is preferably 1 to 5, more preferably 1 to 3, and still more preferably 1.

A¹ and A² are preferably the same group.

In Formula Q, L¹ represents a divalent linking group.

Specific examples of the divalent linking group include a divalent hydrocarbon group.

Specific examples of the divalent hydrocarbon group include a divalent saturated hydrocarbon group, a divalent aromatic hydrocarbon group, and a group formed by linking two or more of these groups.

The divalent saturated hydrocarbon group may be linear, branched, or cyclic, and from the viewpoint that the effects of the present disclosure are more excellent, it is preferably cyclic.

From the viewpoint that the effects of the present disclosure are more excellent, the number of carbon atoms in the divalent saturated hydrocarbon group is preferably 4 to 15, more preferably 5 to 10, and still more preferably 5 to 8.

The divalent aromatic hydrocarbon group preferably has 5 to 20 carbon atoms, and examples thereof include a phenylene group. The divalent aromatic hydrocarbon group may have a substituent (for example, an alkyl group).

As the divalent linking group, a linear, branched, or cyclic divalent saturated hydrocarbon group having 5 to 10 carbon atoms, a group in which a cyclic saturated hydrocarbon group having 5 to 10 carbon atoms is linked to a linear alkylene group having 1 to 3 carbon atoms, a divalent aromatic hydrocarbon group which may have a substituent, or a group in which a divalent aromatic hydrocarbon group is linked to a linear alkylene group having 1 to 3 carbon atoms is preferable, a cyclic divalent saturated hydrocarbon group having 5 to 10 carbon atoms or a phenylene group which may have a substituent is more preferable, a cyclohexylene group or a phenylene group which may have a substituent is still more preferable, and a cyclohexylene group is particularly preferable.

From the viewpoint that the effects of the present disclosure are more excellent, the blocked isocyanate compound represented by Formula Q is particularly preferably a blocked isocyanate compound represented by Formula QA.

B^{1a}-A^{1a}-L^{1a}-A^{2a}-B^{2a} Formula QA

In Formula QA, B^{1a} and B^{2a} each independently represent a blocked isocyanate group.

Suitable aspects of B^{1a} and B^{2a} are the same as those of B¹ and B² in Formula Q.

In Formula QA, A^{1a} and A^{2a} each independently represent a divalent linking group.

A suitable aspect of the divalent linking group in A^{1a} and A^{2a} is the same as that of A¹ and A² in Formula Q.

In Formula QA, L^{1a} represents a cyclic divalent saturated hydrocarbon group or a divalent aromatic hydrocarbon group.

The number of carbon atoms in the cyclic divalent saturated hydrocarbon group in L^{1a} is preferably 5 to 10, more preferably 5 to 8, still more preferably 5 or 6, and particularly preferably 6.

A suitable aspect of the divalent aromatic hydrocarbon group in L^{1a} is the same as that of L¹ in Formula Q.

L^{1a} is preferably a cyclic divalent saturated hydrocarbon group, more preferably a cyclic divalent saturated hydrocarbon group having 5 to 10 carbon atoms, still more preferably a cyclic divalent saturated hydrocarbon group having 5 to 10 carbon atoms, particularly preferably a cyclic divalent saturated hydrocarbon group having 5 or 6 carbon atoms, and most preferably a cyclohexylene group.

In a case where L^{1a} is a cyclohexylene group, the blocked isocyanate compound represented by Formula QA may be an isomer mixture of a cis form and a trans form.

A mass ratio of the cis form to the trans form is preferably cis form/trans form=10/90 to 90/10, and more preferably cis form/trans form=40/60 to 60/40.

Specific examples of the first blocked isocyanate compound are shown below. However, the first blocked isocyanate compound is not limited thereto.

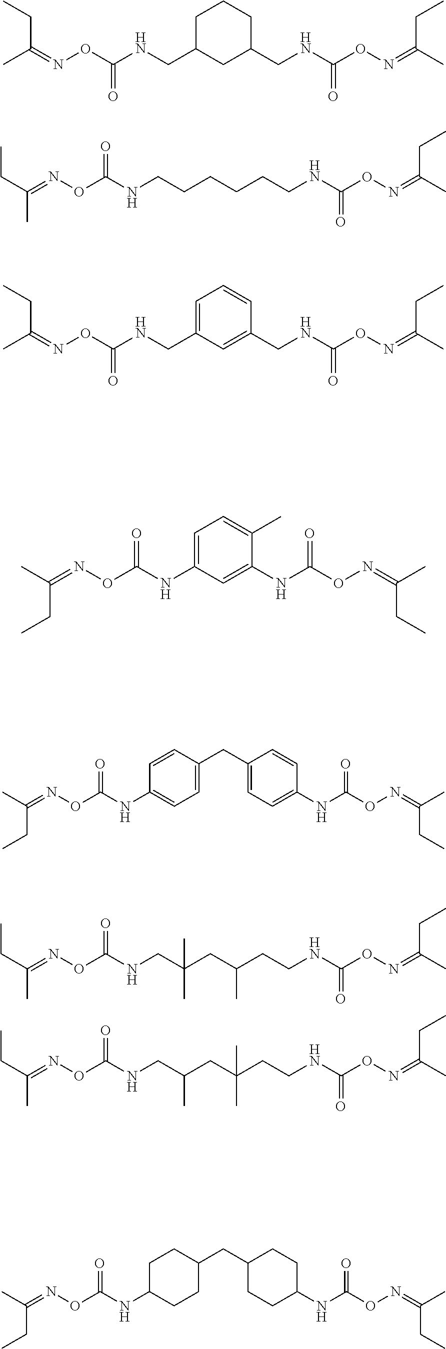

In a case where the photosensitive composition according to the present disclosure contains a thermal crosslinking compound, the photosensitive composition according to the present disclosure may contain only one kind of the thermal crosslinking compound, or may contain two or more kinds thereof.

In a case where the photosensitive composition according to the present disclosure contains a thermal crosslinking compound, a content of the thermal crosslinking compound in the photosensitive composition is preferably 1% by mass to 50% by mass, and more preferably 5% by mass to 30% by mass with respect to the total solid content of the photosensitive composition.

### (Surfactant)

The photosensitive composition according to the present disclosure may contain a surfactant.

Examples of the surfactant include surfactants described in paragraph [0017] of JP4502784B and paragraphs [0060] to [0071] of JP2009-237362A.

Examples of the surfactant include a hydrocarbon-based surfactant, a fluorine-based surfactant, and a silicone-based surfactant.

From the viewpoint of improving environmental suitability, it is preferable that the surfactant does not contain a fluorine atom.

As the surfactant, a hydrocarbon-based surfactant or a silicone-based surfactant is preferable.

Examples of a commercially available product of the fluorine-based surfactant include: MEGAFACE (registered trademark) F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP.MFS-330, EXP.MFS-578, EXP.MFS-578-2, EXP.MFS-579, EXP.MFS-586, EXP.MFS-587, EXP.MFS-628, EXP.MFS-631, EXP.MFS-603, R-41, R-41-LM, R-01, R-40, R-40-LM, RS-43, TF-1956, RS-90, R-94, RS-72-K, and DS-21 [all of which are manufactured by DIC Corporation]; FLUORAD (registered trademark) FC430, FC431, and FC171 [all of which are manufactured by Sumitomo 3M Ltd.]; SURFLON (registered trademark) S-382, SC-101, SC-103, SC-104, SC-105, SC-1068, SC-381, SC-383, S-393, and KH-40 [all of which are manufactured by Asahi Glass Co., Ltd.]; POLYFOX (registered trademark) PF636, PF656, PF6320, PF6520, and PF7002 [all of which are manufactured by OMNOVA Solutions Inc.]; FTERGENT (registered trademark) 710FL, 710FM, 610FM, 601AD, 601ADH2, 602A, 215M, 245F, 251, 212M, 250, 209F, 222F, 208G, 710LA, 710FS, 730 LM, 650AC, 681, and 683 [all of which are manufactured by NEOS COMPANY LIMITED]; and U-120E [manufactured by Uni-chem Co., Ltd.].

In addition, as the fluorine-based surfactant, it is also suitable to use an acrylic compound which has a molecular structure having a functional group containing a fluorine atom, in which, by applying heat to the molecular structure, the functional group containing a fluorine atom is broken to volatilize a fluorine atom. Examples of such a fluorine-based surfactant include MEGAFACE DS series manufactured by DIC Corporation [The Chemical Daily (Feb. 22, 2016) and Nikkei Business Daily (Feb. 23, 2016)], for example, MEGAFACE (registered trademark) DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can also be preferably used.

In addition, as the fluorine-based surfactant, a block polymer can also be used.

In addition, as the fluorine-based surfactant, a fluorine-containing polymer compound including a structural unit derived from a (meth)acrylate compound having a fluorine atom and a structural unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactan, a fluorine-containing polymer having an ethylenically unsaturated bond-containing group in the side chain can also be used. Examples of such a fluorine-based surfactant include MEGAFACE (registered trademark) RS-101, RS-102, RS-718K, and RS-72-K [all of which are manufactured by DIC Corporation].

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the hydrocarbon-based surfactant include glycerol, trimethylolpropane, trimethylolethane, and ethoxylate and propoxylate thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester.

Examples of a commercially available product of the hydrocarbon-based surfactant include PLURONIC (registered trademark) L10, L31, L61, L62, 10R5, 17R2, and 25R2, TETRONIC (registered trademark) 304, 701, 704, 901, 904, and 150R1, and HYDROPALAT (registered trademark) WE 3323 [all manufactured by BASF SE]; Solsperse (registered trademark) 20000 [manufactured by Nippon Lubrizol Corporation]; NCW-101, NCW-1001, and NCW-1002 [all manufactured by FUJIFILM Wako Pure Chemical Corporation]; Pionin (registered trademark) D-1105, D-6112, D-6112-W, and D-6315 [all manufactured by TAKEMOTO OIL & FAT Co., Ltd.]; and OLFINE (registered trademark) E1010, and SURFYNOL (registered trademark) 104, 400, and 440 [all manufactured by Nissin Chemical Co., Ltd.].

Examples of the silicone-based surfactant include a linear polymer including a siloxane bond, a modified siloxane polymer in which an organic group is introduced into a side chain or a terminal, and a polymer having a structural unit having a hydrophilic group in a side chain and a structural unit having a siloxane bond-containing group in a side chain. Among these, as the silicone-based surfactant, the polymer having a structural unit having a hydrophilic group in a side chain and a structural unit having a siloxane bond-containing group in a side chain is preferable.

The polymer may be a random copolymer or a block copolymer.

Examples of the structural unit having a hydrophilic group in a side chain include a structural unit derived from a monomer represented by the following formula.

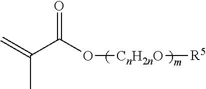

In the formula, R⁴ represents a hydrogen atom or a methyl group; R⁵ represents a hydrogen atom or a methyl group; n represents an integer of 1 to 4; and m represents an integer of 1 to 100.

Examples of the structural unit having a siloxane bond-containing group in a side chain include a structural unit derived from a monomer represented by the following formula.

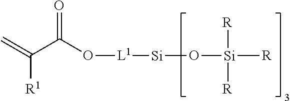

In the formula, R's each independently represent an alkyl group having 1 to 3 carbon atoms; R¹ represents a hydrogen atom or a methyl group; and L¹ represents a divalent organic group or a single bond.

In addition, examples of the structural unit having a siloxane bond-containing group in a side chain also include a structural unit derived from a monomer represented by the following formula.

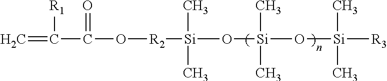

In the formula, R₁ represents a hydrogen atom or a methyl group; R₂ represents an alkylene group having 1 to 10 carbon atoms; R₃ represents an alkyl group having 1 to 4 carbon atoms; and n represents an integer of 5 to 50.

Examples of a commercially available product of the silicone-based surfactant include EXP.S-309-2, EXP.S-315, EXP.S-503-2, and EXP.S-505-2 [all of which are manufactured by DIC Corporation]; DOWSIL (registered trademark) 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 [all of which are manufactured by Dow Corning Toray Co., Ltd.]; X-22-4952, X-22-4272, X-22-6266, KF-351A, K354L, KF-355A, KF-945, KF-640, KF-642, KF-643, X-22-6191, X-22-4515, KF-6004, KF-6001, KF-6002, KP-101, KP-103, KP-104, KP-105, KP-106, KP-109, KP-112, KP-120, KP-121, KP-124, KP-125, KP-301, KP-306, KP-310, KP-322, KP-323, KP-327, KP-341, KP-368, KP-369, KP-611, KP-620, KP-621, KP-626, and KP-652 [all of which are manufactured by Shin-Etsu Chemical Co., Ltd.]; F-4440, TSF-4300, TSF-4445, TSF-4460, and TSF-4452 [all of which are manufactured by Momentive Performance Materials Co., Ltd.]; and BYK300, BYK306, BYK307, BYK310, BYK320, BYK325, BYK330, BYK313, BYK315N, BYK331, BYK333, BYK345, BYK347, BYK348, BYK349, BYK370, BYK377, BYK378, and BYK323 [all of which are manufactured by BYK Chemie].

In addition, as the surfactant, a nonionic surfactant is preferable.

In a case where the photosensitive composition according to the present disclosure contains a surfactant, the photosensitive composition according to the present disclosure may contain only one kind of the surfactant, or may contain two or more kinds thereof.

In a case where the photosensitive composition according to the present disclosure contains a surfactant, a content of the surfactant in the photosensitive composition is preferably 0.01% by mass to 3.0% by mass, more preferably 0.01% by mass to 1.0% by mass, and still more preferably 0.05% by mass to 0.80% by mass with respect to the total solid content of the photosensitive composition.

### (Polymerization Inhibitor)

The photosensitive composition according to the present disclosure may contain a polymerization inhibitor.

The polymerization inhibitor means a compound having a function of delaying or prohibiting a polymerization reaction.

The polymerization inhibitor is not particularly limited, and for example, a known compound used as a polymerization inhibitor can be used.

Examples of the polymerization inhibitor include phenothiazine compounds such as phenothiazine, bis-(1-dimethylbenzyl) phenothiazine, and 3,7-dioctylphenothiazine; hindered phenolic compounds such as bis[3-(3-tert-butyl-4-hydroxy-5-methylphenyl) propionic acid][ethylene bis(oxyethylene)], 2,4-bis[(laurylthio) methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, and pentaerythritol tetrakis[3-(3,5-di-tert-butyl-4-hydroxyphenyl) propionate]; nitroso compounds or a salt thereof, such as 4-nitrosophenol, N-nitrosodiphenylamine, N-nitrosocyclohexylhydroxylamine, and N-nitrosophenylhydroxylamine; quinone compounds such as methylhydroquinone, t-butylhydroquinone, 2,5-di-t-butylhydroquinone, and 4-benzoquinone; phenolic compounds such as 4-methoxyphenol, 4-methoxy-1-naphthol, and t-butylcatechol; and metal salt compounds such as copper dibutyldithiocarbamate, copper diethyldithiocarbamate, manganese diethyldithiocarbamate, and manganese diphenyldithiocarbamate.

Among these, as the polymerization inhibitor, from the viewpoint that the effects of the present disclosure are more excellent, at least one selected from the group consisting of a phenothiazine compound, a nitroso compound or a salt thereof, and a hindered phenolic compound is preferable; and at least one selected from the group consisting of phenothiazine, bis[3-(3-tert-butyl-4-hydroxy-5-methylphenyl) propionic acid][ethylene bis(oxyethylene)], 2,4-bis[(laurylthio) methyl]-o-cresol, 1,3,5-tris(3,5-di-t-butyl-4-hydroxybenzyl), p-methoxyphenol, and an aluminum salt of N-nitrosophenylhydroxylamine is more preferable.

In a case where the photosensitive composition according to the present disclosure contains a polymerization inhibitor, the photosensitive composition according to the present disclosure may contain only one kind of the polymerization inhibitor, or may contain two or more kinds thereof.

In a case where the photosensitive composition according to the present disclosure contains a polymerization inhibitor, a content of the polymerization inhibitor in the photosensitive composition is preferably 0.001% by mass to 5.0% by mass, more preferably 0.01% by mass to 3.0% by mass, and still more preferably 0.02% by mass to 2.0% by mass with respect to the total solid content of the photosensitive composition.

In addition, in a case where the photosensitive composition according to the present disclosure contains a polymerization inhibitor, the content of the polymerization inhibitor in the photosensitive composition is preferably 0.005% by mass to 5.0% by mass, more preferably 0.01% by mass to 3.0% by mass, and still more preferably 0.01% by mass to 1.0% by mass with respect to the total mass of the polymerizable monomer.

### (Hydrogen Donating Compound)

The photosensitive composition according to the present disclosure may contain a hydrogen donating compound.

The hydrogen donating compound has a function of further improving sensitivity of the photopolymerization initiator to actinic ray, suppressing inhibition of polymerization of the polymerizable compound by oxygen, or the like.

Examples of the hydrogen donating compound include amines and an amino acid compound.

Examples of the amines include compounds described in M. R. Sander et al., “Journal of Polymer Society” Vol. 10, page 3173 (1972), JP1969-020189B (JP-S44-020189B), JP1976-082102A (JP-S51-082102A), JP1977-134692A (JP-S52-134692A), JP1984-138205A (JP-S59-138205A), JP1985-084305A (JP-S60-084305A), JP1987-018537A (JP-S62-018537A), JP1989-033104A (JP-S64-033104A), and Research Disclosure 33825.

More specific examples of the amines include 4,4′-bis(diethylamino) benzophenone, tris(4-dimethylaminophenyl) methane (another name: Leucocrystal Violet), triethanolamine, p-dimethylaminobenzoic acid ethyl ester, p-formyldimethylaniline, and p-methylthiodimethylaniline.

As the amines, from the viewpoint that the effects of the present disclosure are more excellent, at least one selected from the group consisting of 4,4′-bis(diethylamino) benzophenone and tris(4-dimethylaminophenyl) methane is preferable.

Examples of the amino acid compound include N-phenylglycine, N-methyl-N-phenylglycine, and N-ethyl-N-phenylglycine.

As the amino acid compound, from the viewpoint that the effects of the present disclosure are more excellent, N-phenylglycine is preferable.

In addition, examples of the hydrogen donating compound also include an organic metal compound described in JP1973-042965B (JP-S48-042965B) (for example, tributyl tin acetate), a hydrogen donor described in JP1980-034414B (JP-S55-034414B), and a sulfur compound described in JP1994-308727A (JP-H6-308727A) (for example, trithiane).

In a case where the photosensitive composition according to the present disclosure contains a hydrogen donating compound, the photosensitive composition according to the present disclosure may contain only one kind of the hydrogen donating compound, or may contain two or more kinds thereof.

In a case where the photosensitive composition according to the present disclosure contains a hydrogen donating compound, for example, from the viewpoint of improving a curing rate by balancing the polymerization growth rate and chain transfer, a content of the hydrogen donating compound in the photosensitive composition is preferably 0.01% by mass to 10.0% by mass, more preferably 0.01% by mass to 8.0% by mass, and still more preferably 0.03% by mass to 5.0% by mass with respect to the total solid content of the photosensitive composition.

### (Solvent)

The photosensitive composition according to the present disclosure may contain a solvent.

The solvent may be water or an organic solvent, but an organic solvent is preferable.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

The solvent may be an organic solvent (so-called high-boiling-point solvent) having a boiling point of 180° C. to 250° C.

In a case where the photosensitive composition according to the present disclosure contains a solvent, the photosensitive composition according to the present disclosure may contain only one kind of the solvent, or may contain two or more kinds thereof.

In a case where the photosensitive composition according to the present disclosure contains a solvent, a content of the solvent in the photosensitive composition is preferably 20% by mass to 95% by mass, more preferably 60% by mass to 95% by mass, and still more preferably 70% by mass to 95% by mass with respect to the total mass of the photosensitive composition.

### (Other Components)

The photosensitive composition according to the present disclosure may contain a component other than the above-described components (also referred to as “other components”).

Examples of the other components include a colorant (for example, a pigment and a dye), an antioxidant, and particles (for example, metal oxide particles).

In addition, examples of the other components also include other additives described in paragraphs [0058] to [0071] of JP2000-310706A.

### —Colorant—

The photosensitive composition according to the present disclosure may contain a colorant (pigment, dye, and the like), but for example, from the viewpoint of transparency, it is preferable that the photosensitive composition according to the present disclosure does not substantially contain the colorant.

In a case where the photosensitive composition according to the present disclosure contains a colorant, a content of the colorant in the photosensitive composition is preferably less than 1% by mass, and more preferably less than 0.1% by mass with respect to the total solid content of the photosensitive composition.

### —Antioxidant—

The photosensitive composition according to the present disclosure may contain an antioxidant.

Examples of the antioxidant include 3-pyrazolidones such as 1-phenyl-3-pyrazolidone (another name: phenidone), 1-phenyl-4,4-dimethyl-3-pyrazolidone, and 1-phenyl-4-methyl-4-hydroxymethyl-3-pyrazolidone; polyhydroxybenzenes such as hydroquinone, catechol, pyrogallol, methylhydroquinone, and chlorohydroquinone; paramethylaminophenol, paraaminophenol, parahydroxyphenylglycine, and paraphenylenediamine.

Among these, as the antioxidant, from the viewpoint that the effects of the present disclosure are more excellent, 3-pyrazolidones are preferable, and 1-phenyl-3-pyrazolidone is more preferable.

In a case where the photosensitive composition according to the present disclosure contains an antioxidant, a content of the antioxidant in the photosensitive composition is preferably 0.001% by mass or more, more preferably 0.005% by mass or more, and still more preferably 0.01% by mass or more with respect to the total solid content of the photosensitive composition. The upper limit thereof is not particularly limited, but is, for example, preferably 1% by mass or less.

### —Particles—

The photosensitive composition according to the present disclosure may contain particles.

As the particles, metal oxide particles are preferable.

The metal of the metal oxide particles also includes semimetal such as B, Si, Ge, As, Sb, and Te.

From the viewpoint of transparency of the cured film, for example, an average primary particle diameter of the particles is preferably 1 nm to 200 nm and more preferably 3 nm to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the photosensitive composition according to the present disclosure contains particles, the photosensitive composition according to the present disclosure may contain only one kind of particles having different metal types, sizes, and the like, or may contain two or more kinds thereof.

It is preferable that the photosensitive composition according to the present disclosure does not content particles, or in a case of containing particles, a content of the particles is more than 0% by mass and 35% by mass or less with respect to the total solid content of the photosensitive composition; it is more preferable that the photosensitive composition according to the present disclosure does not contain particles, or a content of the particles is more than 0% by mass and 10% by mass or less with respect to the total solid content of the photosensitive resin composition; it is still more preferable that the photosensitive composition according to the present disclosure does not contain particles, or a content of the particles is more than 0% by mass and 5% by mass or less with respect to the total solid content of the photosensitive resin composition; it is even more preferable that the photosensitive composition according to the present disclosure does not contain particles, or a content of the particles is more than 0% by mass and 1% by mass or less with respect to the total solid content of the photosensitive resin composition; and it is particularly preferably that the photosensitive composition according to the present disclosure does not contain particles.

In a case where a film having a film thickness of 1 μm is formed of the photosensitive composition according to the present disclosure, from the viewpoint of patterning properties, an absorbance of the film at a wavelength of 365 nm (hereinafter, also referred to as “absorbance A1”) is preferably 0.1 or less, more preferably 0.08 or less, still more preferably 0.06 or less, and particularly preferably 0.04 or less. The upper limit thereof is not particularly limited, and examples thereof include 0.001 or more.

The fact that the absorbance of the above-described film at a wavelength of 365 nm is 0.1 or less means that the film in a state in which the specific coloring material precursor colors black by a stimulus has excellent transmittance of light at a wavelength of 365 nm. In a case where the absorbance of the above-described film at a wavelength of 365 nm is 0.1 or less, during exposure, incidence ray is gradually attenuated toward a film thickness direction of the film formed of the photosensitive composition (that is, the photosensitive composition layer), and for example, in a case of a negative tone, a phenomenon in which polymerization curing is insufficient is unlikely to occur, and a pattern having a favorable shape tends to be easily obtained.

In a case where a black film having a film thickness of 1 μm is formed by coloring the specific coloring material precursor in black by a stimulus using the photosensitive composition according to the present disclosure, an absorbance of the film at a wavelength of 365 nm (hereinafter, also referred to as “absorbance A2”) is preferably 0.14 or more, more preferably 0.16 or more, still more preferably 0.18 or more, and particularly preferably 0.2 or more. The upper limit thereof is not particularly limited, and examples thereof include 4.0 or less.

A ratio of the absorbance A² to the absorbance A1 (Absorbance A2/Absorbance A1) is preferably 5.0 or more, and more preferably 7.0 or more.

In a case where a black film having a film thickness of 1 μm is formed by coloring the specific coloring material precursor in black by a stimulus using the photosensitive composition according to the present disclosure, an average absorbance of the film in a wavelength of 400 nm to 700 nm is preferably 0.14 or more, more preferably 0.16 or more, still more preferably 0.18 or more, and particularly preferably 0.2 or more. The upper limit thereof is not particularly limited, and examples thereof include 4.0 or less.

The fact that both the absorbance of the above-described film at a wavelength of 365 nm and the average absorbance of the above-described film in a wavelength of 400 nm to 700 nm are 0.14 or more means that the film in a state in which the specific coloring material precursor colors black by a stimulus has excellent light shielding properties against light having a wavelength from the visible range to the ultraviolet range.

In the present disclosure, the “absorbance” is a value measured using a spectrophotometer.

As the spectrophotometer, for example, an ultraviolet-visible spectrophotometer (model number: UV-1800) manufactured by Shimadzu Corporation can be used. However, the spectrophotometer is not limited thereto.

A preferred aspect of the photosensitive composition according to the present disclosure is a photosensitive composition containing a coloring material precursor which colors black by at least one stimulus selected from the group consisting of heat, light, acid, base, and radical, an alkali-soluble resin, a polymerizable monomer; and a photopolymerization initiator, in which all of the following (1) to (3) are satisfied.

(1) In a case where a film having a film thickness of 1 μm is formed of the photosensitive composition, an absorbance of the film at a wavelength of 365 nm is 0.1 or less.

(2) In a case where a black film having a film thickness of 1 μm is formed of the photosensitive composition by coloring the coloring material precursor by the stimulus in black, an absorbance of the film at a wavelength of 365 nm is 0.2 or more.

(3) In a case where a black film having a film thickness of 1 μm is formed of the photosensitive composition by coloring the coloring material precursor by the stimulus in black, an average absorbance of the film in a wavelength of 400 nm to 700 nm is 0.2 or more.

### <<Viscosity of Photosensitive Composition>>

For example, from the viewpoint of coatability, a viscosity of the photosensitive composition according to the present disclosure at 25° C. is preferably 1 mPa·s to 50 mPa·s, more preferably 2 mPa·s to 40 mPa·s, and still more preferably 3 mPa·s to 30 mPa·s.

The viscosity of the photosensitive composition according to the present disclosure is measured using a viscometer.

As the viscometer, for example, a viscometer (product name: VISCOMETER TV-22) manufactured by Toki Sangyo Co. Ltd. can be suitably used. However, the viscometer is not limited to the above-described viscometer.

### <<Surface Tension of Photosensitive Composition>>

For example, from the viewpoint of coatability, a surface tension of the photosensitive composition according to the present disclosure at 25° C. is preferably 5 mN/m to 100 mN/m, more preferably 10 mN/m to 80 mN/m, and still more preferably 15 mN/m to 40 mN/m.

The surface tension of the photosensitive composition according to the present disclosure is measured using a tensiometer.

As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

### <<Application of Photosensitive Composition>

The photosensitive composition according to the present disclosure can be applied to various applications.

Since the photosensitive composition according to the present disclosure can form a film having excellent light shielding properties and has excellent patterning properties, the photosensitive composition according to the present disclosure can be applied to, for example, a black matrix (so-called black partition wall) or the like.

[Transfer film]

The transfer film according to the present disclosure includes a temporary support and a photosensitive composition layer containing the photosensitive composition according to the present disclosure described above.

The transfer film according to the present disclosure may include a composition layer other than the photosensitive composition layer (so-called other composition layers).

The transfer film according to the present disclosure may have a configuration, for example, in which a protective film is provided on the photosensitive composition layer or the other composition layers.

Each of the photosensitive composition layer, the other composition layers, and the protective film may be a single layer or a multilayer of two or more layers.

The configuration of the transfer film according to the present disclosure is preferably temporary support/photosensitive composition layer/protective film.

In the transfer film according to the present disclosure, in a case of a configuration in which the other composition layers are further provided on a side of the photosensitive composition layer opposite to the temporary support side, the total thickness of the other composition layers provided on the side of the photosensitive composition layer opposite to the temporary support side is preferably 0.1% to 30% and more preferably 0.1% to 20% with respect to a thickness (film thickness) of the photosensitive composition layer.

From the viewpoint of suppressing generation of air bubbles in a bonding step described later, the maximum width of undulation of the transfer film according to the present disclosure is preferably 300 μm or less, more preferably 200 μm or less, and still more preferably 60 μm or less. The lower limit of the maximum width of the undulation is 0 μm or more, preferably 0.1 μm or more, and more preferably 1 μm or more.

The maximum width of the undulation of the transfer film is a value measured by the following procedure.

First, the transfer film is cut in a direction perpendicular to the main surface so as to have a size of 20 cm in length×20 cm in width to produce a test sample. In a case where the transfer film has a protective film, the protective film is peeled off. Next, the above-described test sample is placed on a stage having a smooth and horizontal surface so that the surface of the temporary support faces the stage. After placing, for a range of 10 cm square in the center of the test sample, the surface of the test sample is scanned with a laser microscope [for example, VK-9700SP manufactured by Keyence Corporation] to obtain a three-dimensional surface image, and the minimum concave height is subtracted from the maximum convex height observed in the obtained three-dimensional surface image. The above-described operation is performed on 10 test samples, and the arithmetic mean value thereof is defined as the “maximum width of the undulation of the transfer film”.

Hereinafter, the configuration of the transfer film according to the present disclosure will be described in detail.

### <Temporary Support>

The transfer film according to the present disclosure includes a temporary support.

The temporary support is a member which supports the photosensitive composition layer, and is finally removed by a peeling treatment.

The temporary support may be a monolayer structure or a multilayer structure.

The temporary support is preferably a film and more preferably a resin film. As the temporary support, a film which has flexibility and does not generate significant deformation, contraction, or stretching under pressure or under pressure and heating is preferable.

Examples of such a film include a polyethylene terephthalate film (for example, a biaxial stretching polyethylene terephthalate film), a polymethylmethacrylate film, a cellulose triacetate film, a polystyrene film, a polyimide film, and a polycarbonate film.

Among these, as the temporary support, a polyethylene terephthalate film is preferable. In addition, it is preferable that the film used as the temporary support does not have deformation such as wrinkles or scratches.

From the viewpoint that pattern exposure can be performed through the temporary support, the temporary support preferably has high transparency; and a transmittance at a wavelength of 313 nm, a wavelength of 365 nm, a wavelength of 405 nm, and a wavelength of 436 nm is preferably 60% or more, more preferably 70% or more, still more preferably 80% or more, and particularly preferably 90% or more.

Examples of a preferred value of the transmittance include 87%, 92%, and 98%.

The transmittance is calculated as a proportion of the amount of light emitted from the temporary support to the amount of light incident at each wavelength (=Amount of emitted light/Amount of incidence ray×100; %).

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of the pattern forming properties during the pattern exposure through the temporary support and the transparency of the temporary support, it is preferable that the number of fine particles, foreign substances, and defects included in the temporary support is small.

The number of fine particles, foreign substances, and defects having a diameter of 1 μm or more, contained in the temporary support, is preferably 50 pieces/10 mm² or less, more preferably 10 pieces/10 mm² or less, still more preferably 3 pieces/10 mm² or less, and particularly preferably 0 pieces/10 mm².

In order to improve adhesiveness between the temporary support and the photosensitive composition layer, a surface of the temporary support on a side in contact with the photosensitive composition layer may be surface-modified by ultraviolet (UV) irradiation, corona discharge, plasma, or the like.

In a case of performing surface modification by ultraviolet irradiation, an exposure amount of ultraviolet rays is not particularly limited, but is, for example, preferably 10 mJ/cm² to 2,000 mJ/cm² and more preferably 50 mJ/cm² to 1,000 mJ/cm².

Examples of a light source for the ultraviolet irradiation include a light source such as a low pressure mercury lamp, a high pressure mercury lamp, a ultra-high pressure mercury lamp, a carbon arc lamp, a metal halide lamp, a xenon lamp, a chemical lamp, an electrodeless discharge lamp, and a light emitting diode (LED), all of which emit light in a wavelength range of 150 nm to 450 nm. The lamp output and the illuminance are not particularly limited and can be appropriately set, for example, according to a desired exposure amount.

In order to impart handleability, a layer (also referred to as “lubricant layer”) containing fine particles may be provided on the surface of the temporary support.

The lubricant layer may be provided on one surface of the temporary support or on both surfaces thereof.

A diameter of the particles contained in the lubricant layer is not particularly limited, but is, for example, preferably 0.05 μm to 0.8 μm. In addition, a film thickness of the lubricant layer is not particularly limited, but is, for example, preferably 0.05 μm to 1.0 μm.

A thickness of the temporary support is not particularly limited, but for example, is preferably 5 μm to 200 μm; and from the viewpoint of handleability and general-purpose properties, it is more preferably 5 μm to 150 μm, still more preferably 5 μm to 50 μm, and particularly preferably 5 μm to 25 μm.

The thickness of the temporary support is calculated as an average value of any five points measured by a cross-sectional observation with a scanning electron microscope (SEM). A commercially available product can be used as the temporary support.

Examples of the commercially available product of the temporary support include LUMIRROR (registered trademark) 16KS40, LUMIRROR (registered trademark) 16FB40, LUMIRROR (registered trademark) #38-U48, LUMIRROR (registered trademark) #75-U34, and LUMIRROR (registered trademark) #25T60 [all of which are manufactured by Toray Industries, Inc.]; and COSMOSHINE (registered trademark) A4100, COSMOSHINE (registered trademark) A4160, COSMOSHINE (registered trademark) A4300, COSMOSHINE (registered trademark) A4360, and COSMOSHINE (registered trademark) A8300 [all of which are manufactured by TOYOBO Co., Ltd.].

The temporary support may be a recycled product. Examples of the recycled product include films obtained by washing used films and the like into chips and using the chips as a material. Specific examples of the recycled product include Ecouse series manufactured by Toray Industries, Inc.

Examples of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 9 μm.

For example, preferred aspects of the temporary support are described in paragraphs [0017] and [0018] of JP2014-085643A, paragraphs [0019] to [0026] of JP2016-027363A, paragraphs [0041] to [0057] of WO2012/081680A, and paragraphs [0029] to [0040] of WO2018/179370A, the contents of which are incorporated herein by reference.

### <Photosensitive Composition Layer>

The transfer film according to the present disclosure includes a photosensitive composition layer containing the photosensitive composition according to the present disclosure. According to the transfer film according to the present disclosure, a pattern can be formed on an object to be transferred by transferring the photosensitive composition layer onto the object to be transferred, and then performing exposure and development.

It is sufficient that the photosensitive composition layer is a layer containing the photosensitive composition according to the present disclosure, but the photosensitive composition layer is preferably a layer consisting of the photosensitive composition according to the present disclosure or a layer consisting of the solid contents of the photosensitive composition according to the present disclosure.

The photosensitive composition layer may be a positive tone photosensitive composition layer or a negative tone photosensitive composition layer, but is preferably a negative tone photosensitive composition layer.

The negative photosensitive composition layer is a photosensitive composition layer in which solubility of an exposed portion in a developer is reduced by exposure. In a case where the photosensitive composition layer is a negative-tone photosensitive composition layer, the formed pattern corresponds to a cured layer.

The photosensitive composition layer may contain a predetermined amount of impurities.

Examples of the impurities include sodium, potassium, magnesium, calcium, iron, manganese, copper, aluminum, titanium, chromium, cobalt, nickel, zinc, tin, halogen, and ions of these. Among these, halide ion (for example, chloride ion, bromide ion, and iodide ion), sodium ion, and potassium ion are easily mixed as impurities, so that the following content is preferable.

A content of the impurities in the photosensitive composition layer is preferably 80 ppm or less, more preferably 10 ppm or less, and still more preferably 2 ppm or less on a mass basis. In addition, the content of the impurities in the photosensitive composition layer may be 1 ppb or more or 0.1 ppm or more on a mass basis.

Specific examples of the content of the impurities in the photosensitive composition layer include an aspect in which all the above-described impurities are 0.6 ppm on a mass basis.

Examples of a method of setting the content of impurities in the photosensitive composition layer within the above-described range include selecting a material having a low content of the impurities as a raw material of the photosensitive composition, preventing the impurities from being mixed during the formation of the photosensitive composition layer, and washing and removing the photosensitive composition layer. By such a method, the content of the impurities in the photosensitive composition layer can be set to be within the above-described range.

The impurities can be quantified by a known method such as inductively coupled plasma (ICP) emission spectroscopy, atomic absorption spectroscopy, and ion chromatography.

The photosensitive composition layer may contain a residual monomer of each structural unit of the alkali-soluble resin described above (hereinafter, also simply referred to as “residual monomer”).

From the viewpoint of patterning properties and reliability, a content of the residual monomer in the photosensitive composition layer is preferably 5,000 ppm by mass or less, more preferably 2,000 ppm by mass or less, and still more preferably 500 ppm by mass or less with respect to the total mass of the alkali-soluble resin. The lower limit thereof is not particularly limited, but may be, for example, 1 ppm by mass or more or 10 ppm by mass or more.

From the viewpoint of patterning properties and reliability, the content of the residual monomer in the photosensitive composition layer is preferably 3,000 ppm by mass or less, more preferably 600 ppm by mass or less, and still more preferably 100 ppm by mass or less with respect to the total solid content of the photosensitive composition. The lower limit thereof is not particularly limited, but may be, for example, 0.1 ppm by mass or more or 1 ppm by mass or more.

It is preferable that the amount of residual monomer of the monomer in a case of synthesizing the alkali-soluble resin by the polymer reaction is also within the above-described range. For example, in a case where glycidyl acrylate is reacted with a carboxylic acid side chain to synthesize the alkali-soluble resin, the content of glycidyl acrylate is preferably within the above-described range.

The amount of the residual monomer in the photosensitive composition layer can be measured by a known method such as liquid chromatography and gas chromatography.

It is preferable that a content of compounds such as benzene, formaldehyde, trichloroethylene, 1,3-butadiene, carbon tetrachloride, chloroform, N,N-dimethylformamide, N,N-dimethylacetamide, and hexane is low in the photosensitive composition layer.

The content of these compounds in the photosensitive composition layer is preferably 100 ppm or less, more preferably 20 ppm or less, and still more preferably 4 ppm or less on a mass basis. The lower limit thereof may be 10 ppb or more or 100 ppb or more on a mass basis.

The content of these compounds can be reduced, for example, by selecting a material having a low content of these compounds as a raw material of the photosensitive composition, and preventing these compounds from being mixed during the formation of the photosensitive composition layer.

The content of these compounds can be quantified by a known measurement method.

From the viewpoint of reliability and laminating property, a content of water in the photosensitive composition layer is preferably 0.01% by mass to 1.0% by mass and more preferably 0.05% by mass to 0.5% by mass.

### <<Thickness of Photosensitive Composition Layer>>

A thickness (also referred to as “film thickness”) of the photosensitive composition layer is not particularly limited.

In a case where the photosensitive composition layer is used as a partition wall of a micro LED display, for example, from the viewpoint of further suppressing color mixing between adjacent pixels, the film thickness of the photosensitive composition layer is, for example, preferably 5 μm or more, and more preferably 10 μm or more.

In addition, the film thickness of the photosensitive composition layer is, for example, preferably 20 μm or less and more preferably 15 μm or less, from the viewpoint of handleability.

The film thickness of the photosensitive composition layer is calculated as an average value of any five points measured by a cross-sectional observation with a scanning electron microscope (SEM).

### <<Refractive Index of Photosensitive Composition Layer>>

A refractive index of the photosensitive composition layer is not particularly limited, but is, for example, preferably 1.41 to 1.59 and more preferably 1.47 to 1.56.

The refractive index of the photosensitive composition layer is a value at a wavelength of 550 nm measured using an ellipsometer in an environment of an atmosphere temperature of 25° C.

### <<Color of Photosensitive Composition Layer>>

The photosensitive composition layer is preferably achromatic.

Specifically, in CIE1976 (L*, a*, b*) color space of the total reflection [incidence angle: 8°, light source: D-65 (visual field: 2°)], the L* value is preferably 10 to 90, the a* value is preferably −1.0 to 1.0, and the b* value is preferably −1.0 to 1.0.

### <<Dissolution Rate of Photosensitive Composition Layer>>

From the viewpoint of suppressing residues during development, a dissolution rate of the photosensitive composition layer in a 1.0% by mass sodium carbonate aqueous solution is preferably 0.01 μm/sec or more, more preferably 0.10 μm/sec or more, and still more preferably 0.20 μm/sec or more.

In addition, from the viewpoint of edge shape of the pattern, the dissolution rate of the photosensitive composition layer in a 1.0% by mass sodium carbonate aqueous solution is preferably 5.0 μm/sec or less, more preferably 4.0 μm/sec or less, and still more preferably 3.0 μm/sec or less.

Examples of a specific preferred numerical value thereof include 1.8 μm/sec, 1.0 μm/sec, and 0.7 μm/sec.

The dissolution rate of the photosensitive composition layer in a 1.0% by mass sodium carbonate aqueous solution per unit time is measured as follows.

The photosensitive composition layer (having a film thickness range of 1.0 μm to 10 μm) formed on a glass substrate, from which the solvent has been sufficiently removed, is subjected to a shower development with a 1.0% by mass sodium carbonate aqueous solution at a liquid temperature of 25° C. until the photosensitive composition layer is dissolved completely (however, the maximum time is set to 2 minutes). The dissolution rate of the photosensitive composition layer is obtained by dividing the film thickness of the photosensitive composition layer by the time required for the photosensitive composition layer to dissolve completely. In a case where the photosensitive composition layer is not dissolved completely in 2 minutes, the dissolution rate of the photosensitive composition layer is calculated in the same manner as above, from the amount of change in film thickness up to 2 minutes. For development, a shower nozzle (model number: 1/4 MINJJX030PP) manufactured by H.IKEUCHI Co., Ltd. is used, and a spraying pressure of the shower is set to 0.08 MPa. Under the above-described conditions, a shower flow rate per unit time is set to 1,800 mL/min.

### <<Dissolution Rate of Cured Film of Photosensitive Composition Layer>>

A dissolution rate of a cured film (having a film thickness range of 1.0 μm to 10 μm) of the photosensitive composition layer in a 1.0% by mass sodium carbonate aqueous solution is preferably 3.0 μm/sec or less, more preferably 2.0 μm/sec or less, still more preferably 1.0 μm/sec or less, and particularly preferably 0.2 μm/sec or less. The cured film of the photosensitive composition layer is a film obtained by exposing the photosensitive composition layer with i-rays (wavelength: 365 nm) at an exposure amount of 300 mJ/cm².

Examples of a specific preferred numerical value thereof include 0.8 μm/sec, 0.2 μm/sec, and 0.001 μm/sec.

The dissolution rate of the cured film (having a film thickness range of 1.0 μm to 10 μm) of the photosensitive composition layer in a 1.0% by mass sodium carbonate aqueous solution is measured by the same method as the dissolution rate of the photosensitive composition layer in a 1.0% by mass sodium carbonate aqueous solution per unit time.

### <<Swelling Ratio of Photosensitive Composition Layer>>

From the viewpoint of improving pattern formability, a swelling ratio of the photosensitive composition layer after exposure in a 1.0% by mass sodium carbonate aqueous solution is preferably 100% or less, more preferably 50% or less, and still more preferably 30% or less.

The swelling ratio of the photosensitive composition layer after exposure in a 1.0% by mass sodium carbonate aqueous solution is measured as follows.

The photosensitive composition layer (having a film thickness range of 1.0 μm to 10 μm) formed on a glass substrate, from which the solvent has been sufficiently removed, is exposed with i-rays (wavelength: 365 nm) at an exposure amount of 500 mJ/cm² using an ultra-high pressure mercury lamp. The glass substrate is immersed in a 1.0% by mass sodium carbonate aqueous solution at a liquid temperature of 25° C., and the film thickness is measured after 30 seconds. Next, an increased proportion of the film thickness after immersion to the film thickness before immersion is calculated.

Examples of a specific preferred numerical value thereof include 4%, 13%, and 25%.

### <<Foreign Substance in Photosensitive Composition Layer>>

From the viewpoint of pattern forming properties, the number of foreign substances having a diameter of 1.0 μm or more in the photosensitive composition layer is preferably 10 pieces/mm² or less, and more preferably 5 pieces/mm² or less.

The number of foreign substances in the photosensitive composition layer is measured as follows.

Five regions (1 mm×1 mm) at any positions on the surface of the photosensitive composition layer are visually observed from a normal direction of the surface of the photosensitive composition layer using an optical microscope. The number of foreign substances having a diameter of 1.0 μm or more in each region is measured, and the arithmetic mean thereof is calculated as the number of foreign substances.

Examples of a specific preferred numerical value thereof include 0 pieces/mm², 1 pieces/mm², 4 pieces/mm², and 8 pieces/mm².

### <<Haze of Dissolved Substance in Photosensitive Composition Layer>>

From the viewpoint of suppressing generation of aggregates during development, a haze of a solution obtained by dissolving 1.0 cm³ of the photosensitive composition layer in 1.0 liter (L) of a 1.0% by mass sodium carbonate aqueous solution at a liquid temperature of 30° C. is preferably 60% or less, more preferably 30% or less, still more preferably 10% or less, and particularly preferably 1% or less.

The above-described haze is measured as follows.

First, a 1.0% by mass sodium carbonate aqueous solution is prepared, and a liquid temperature is adjusted to 30° C. Next, 1.0 cm³ of the photosensitive composition layer is added to 1.0 L of the 1.0% by mass sodium carbonate aqueous solution at a liquid temperature of 30° C. The solution is stirred at 30° C. for 4 hours, being careful not to mix air bubbles. After stirring, a haze of the solution in which the photosensitive composition layer has been dissolved is measured. The haze is measured using a haze meter as a measuring device, and using a liquid measuring unit and a liquid measuring cell having an optical path length of 20 mm.

As the haze meter, for example, a haze meter (model number: NDH4000) manufactured by NIPPON DENSHOKU INDUSTRIES Co., Ltd. can be suitably used. However, the haze meter is not limited to the above.

Examples of a specific preferred numerical value thereof include 0.4%, 1.0%, 9%, and 24%.

### <Protective Film>

The transfer film according to the present disclosure may include a protective film.

Examples of the protective film include a resin film having heat resistance and solvent resistance.

Examples of the protective film include polyolefin films such as a polypropylene film and a polyethylene film, polyester films such as a polyethylene terephthalate film, polycarbonate films, and polystyrene films.

In addition, a resin film composed of the same material as the above-described temporary support may be used as the protective film.

As the protective film, a polyolefin film is preferable, a polypropylene film or a polyethylene film is more preferable, and a polyethylene film is still more preferable.

A thickness of the protective film is preferably 1 μm to 100 μm, more preferably 5 μm to 50 μm, still more preferably 5 μm to 40 μm, and particularly preferably 15 μm to 30 μm.

A thickness of the protective film is preferably 1 μm or more from the viewpoint of excellent mechanical hardness, and is preferably 100 μm or less from the viewpoint of relatively low cost.

The number of fisheyes with a diameter of 80 μm or more in the protective film is preferably 5 pieces/1 m² or less.

The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles contained in the protective film being transferred to the photosensitive composition layer.

From the viewpoint of imparting take-up property, an arithmetic average roughness Ra on a surface of the protective film opposite to the surface in contact with the photosensitive composition layer is preferably 0.01 μm or more, more preferably 0.02 μm or more, and still more preferably 0.03 μm or more. On the other hand, the arithmetic average roughness Ra on the surface of the protective film opposite to the surface in contact with the photosensitive composition layer is preferably less than 0.50 μm, more preferably 0.40 μm or less, and still more preferably 0.30 μm or less.

From the viewpoint of suppressing defects during transfer, a surface roughness Ra on the surface of the protective film in contact with the photosensitive composition layer is preferably 0.01 μm or more, more preferably 0.02 μm or more, and still more preferably 0.03 μm or more. On the other hand, the surface roughness Ra on the surface of the protective film in contact with the photosensitive composition layer is preferably less than 0.50 μm, more preferably 0.40 μm or less, and still more preferably 0.30 μm or less.

The protective film may be a recycled product. Examples of the recycled product include films obtained by washing used films and the like into chips and using the chips as a material. Specific examples of the recycled product include Ecouse series manufactured by Toray Industries, Inc.

### <<Relationship Between Temporary Support, Photosensitive Composition Layer, and Protective Film>>

In the transfer film according to the present disclosure, it is preferable that a breaking elongation of a cured film obtained by curing the photosensitive composition layer at 120° C. is 15% or more, an arithmetic average roughness Ra of the surface of the temporary support on the photosensitive composition layer side is 50 nm or less, and an arithmetic average roughness Ra of the surface of the protective film on the photosensitive composition layer side is 150 nm or less.

The transfer film according to the present disclosure preferably satisfies the following expression (T1).

X×Y<1500 Expression (T1)

In the expression (T1), X represents a value (%) of the breaking elongation of the cured film obtained by curing the photosensitive composition layer at 120° C., and Y represents a value (nm) of the arithmetic average roughness Ra of the surface of the temporary support on the photosensitive composition layer side.

X×Y is more preferably 750 or less.

Examples of a specific numerical value of X include 18%, 25%, 30%, and 35%.

Examples of a specific numerical value of Y include 4 nm, 8 nm, 15 nm, and 30 nm.

Examples of a specific numerical value of X x Y include 150, 200, 300, 360, and 900.

In the transfer film according to the present disclosure, it is preferable that the breaking elongation of the cured film obtained by curing the photosensitive composition layer at 120° C. is 2 times or more a breaking elongation of a cured film obtained by curing the photosensitive composition layer at 23° C.

The breaking elongation is measured by a tensile test with, as a test sample, a cured film which is obtained by exposing the photosensitive composition layer having a thickness of 20 μm at an exposure amount of 120 mJ/cm² using an ultra-high pressure mercury lamp to be cured, further exposing at an exposure amount of 400 mJ/cm² using a high pressure mercury lamp, and heating at 145° C. for 30 minutes.

The transfer film according to the present disclosure preferably satisfies the following expression (T2).

Y≤Z Expression (T2)

In the expression (T2), Y represents the value (nm) of the arithmetic average roughness Ra of the surface of the temporary support on the photosensitive composition layer side, and Z represents a value (nm) of the arithmetic average roughness Ra of the surface of the protective film on the photosensitive composition layer side.

### <<Application of Transfer Film>>

The transfer film according to the present disclosure can be applied to various applications.

The transfer film according to the present disclosure can be applied to, for example, a black matrix (so-called black partition wall).

### <Manufacturing Method of Transfer Film>

A manufacturing method of the transfer film according to the present disclosure is not particularly limited, and a known method can be used.

Examples of the manufacturing method of the transfer film according to the present disclosure include a method including a step of applying the photosensitive composition onto a surface of the temporary support to form a coating film and a step of drying the formed coating film to form the photosensitive composition layer, from the viewpoint of excellent productivity.

Examples of a method of applying the photosensitive composition include a printing method, a spray coating method, a roll coating method, a bar coating method, a curtain coating method, a spin coating method, and a die coating method (that is, a slit coating method).

Examples of a method of drying the coating film include natural drying, heat drying, and drying under reduced pressure; and these drying methods can be adopted alone or in combination of a plurality of drying methods.

As the method of drying the coating film, heating and drying and/or drying under reduced pressure is preferable.

In the present disclosure, the “drying” means removing at least part of the solvent included in the composition.

The drying temperature is preferably 80° C. or higher and more preferably 90° C. or higher. The upper limit of the drying temperature is preferably 130° C. or lower and more preferably 120° C. or lower. The drying may be carried out while continuously changing the temperature.

The drying time is preferably 20 seconds or more, more preferably 40 seconds or more, and still more preferably 60 seconds or more. The upper limit of the drying time is not particularly limited, but is, for example, preferably 600 seconds or less and more preferably 300 seconds or less.

In a case where the transfer film according to the present disclosure includes the protective film on the surface of the photosensitive composition layer opposite to the temporary support, for example, the transfer film having a configuration of temporary support/photosensitive composition layer/protective film can be manufactured by pressure-bonding and bonding the protective film to the photosensitive composition layer formed as described above.

A method of bonding the protective film and the photosensitive composition layer is not particularly limited, and a known method can be used.

For the bonding of the protective film and the photosensitive composition layer, for example, a known laminator such as a vacuum laminator and an auto laminator can be used.

It is preferable that the laminator is equipped with any heatable roller such as a rubber roller, and can perform pressing and heating.

The transfer film manufactured as described above may be wound to produce a roll-shaped transfer film, which may be stored. The roll-shaped transfer film is provided as it is in a bonding step with the base material in a roll-to-roll method.

### [Manufacturing Method of Laminate]

The manufacturing method of a laminate according to the present disclosure (hereinafter, also simply referred to as “manufacturing method according to the present disclosure”) is a manufacturing method of a laminate having a black pattern, the manufacturing method including, in the following order, a step of forming a photosensitive composition layer containing the photosensitive composition according to the present disclosure described above on a base material (hereinafter, also referred to as “formation step”); a step of performing pattern exposure on the photosensitive composition layer (hereinafter, also referred to as “exposure step”); and a step of developing the photosensitive composition layer (hereinafter, also referred to as “development step”), in which the manufacturing method further includes, after the pattern exposure step, a step of coloring the specific coloring material precursor in black (hereinafter, also referred to as “coloring step”).

Hereinafter, the procedure of the above-described steps will be described in detail.

### <Formation Step>

The formation step is a step of forming a photosensitive composition layer containing the photosensitive composition according to the present disclosure described above on a base material.

It is sufficient that the formation step is a step of forming the photosensitive composition layer containing the photosensitive composition according to the present disclosure on a base material; and for example, the formation step may be a step of forming a coating film of the photosensitive composition according to the present disclosure on a base material and drying the formed coating film to form the photosensitive composition layer, or a step of, using the transfer film according to the present disclosure described above, bonding a surface of the transfer film opposite to the temporary support to a base material to form a photosensitive composition layer on the base material (hereinafter, also referred to as “bonding step”), in which it is preferable that the bonding step is provided.

In the bonding step, the photosensitive composition layer of the transfer film according to the present disclosure is bonded to the base material by bringing the surface of the photosensitive composition layer on a side opposite to the temporary support into contact with the base material, thereby forming the photosensitive composition layer on the base material. In a case where the transfer film according to the present disclosure includes the protective film on the surface of the photosensitive composition layer opposite to the temporary support, the bonding step is performed after the protective film is peeled off.

A method of bonding the photosensitive composition layer and the base material is not particularly limited, and a known method can be used.

For the bonding of the photosensitive composition layer and the base material, for example, a known laminator such as a vacuum laminator and an auto laminator can be used.

It is preferable that the laminator is equipped with any heatable roller such as a rubber roller, and can perform pressing and heating.

The laminating temperature is preferably, for example, 70° C. to 130° C. As the base material, a glass base material or a resin base material is preferable.

The base material is preferably a transparent base material, and more preferably a transparent resin base material.

A refractive index of the base material is preferably 1.50 to 1.52.

Examples of the glass base material include tempered glass such as GORILLA GLASS (registered trademark) manufactured by Corning Incorporated.

A thickness of the glass base material is preferably 0.01 mm to 1.1 mm, and more preferably 0.1 mm to 0.7 mm.

Examples of the resin base material include a base material consisting of a resin such as polyethylene terephthalate (PET), polyethylene naphthalate (PEN), polycarbonate (PC), triacetyl cellulose (TAC), polyimide (PI), polybenzoxazole (PBO), and cycloolefin polymer (COP).

A thickness of the resin base material is preferably 5 μm to 200 μm, and more preferably 10 μm to 100 μm.

As the material of the base material, for example, materials described in JP2010-86684A, JP2010-152809A, and JP2010-257492A are preferably used.

### <Exposure Step>

The exposure step is a step of performing pattern exposure on the photosensitive composition layer.

The “pattern exposure” refers to exposure in a form of performing the exposure in a patterned manner, that is, a form in which an exposed portion and a non-exposed portion are present. A positional relationship between the exposed region and the non-exposed region in the pattern exposure is not particularly limited and is appropriately adjusted.

For example, in a case where the photosensitive composition layer is a negative tone, the exposed portion in the pattern exposure of the photosensitive composition layer on the base material is cured to finally form a cured film. Meanwhile, the unexposed portion in the pattern exposure of the photosensitive composition layer on the base material is not cured, and is dissolved and removed with a developer in the development step described later. With the unexposed portion, the opening portion of the cured film can be formed after the development step.

As a light source of the pattern exposure, a light source can be appropriately selected as long as it can emit light at a wavelength region (for example, 365 nm or 405 nm) at which the photosensitive composition layer can be cured. Among these, a main wavelength of the exposure light for the pattern exposure is preferably 365 nm. The main wavelength means a wavelength having the highest intensity.

Examples of the light source include various lasers, a light emitting diode (LED), an ultra-high pressure mercury lamp, a high pressure mercury lamp, and a metal halide lamp.

An exposure amount is preferably 5 mJ/cm² to 200 mJ/cm² and more preferably 10 mJ/cm² to 200 mJ/cm².

In a case where the photosensitive composition layer is formed on the base material using the transfer film, the pattern exposure may be performed after peeling off the temporary support, or the temporary support may be peeled off after performing the pattern exposure through the temporary support, before peeling off the temporary support.

From the viewpoint of preventing mask contamination due to contact with the photosensitive composition layer and viewpoint of avoiding an influence of foreign substance adhering to the mask on the exposure, it is preferable to perform the pattern exposure without peeling off the temporary support.

From the viewpoint of improving resolution by suppressing scattering of exposure light by the temporary support and suppressing diffraction of light transmitted through the mask, it is preferable to perform the pattern exposure after peeling off the temporary support.

The pattern exposure may be an exposure through a mask or may be a digital exposure using a laser or the like.

Examples of a base material of the mask in a case of exposure through the mask include a quartz mask, a soda-lime glass mask, and a film mask.

Among these, from the viewpoint of excellent dimensional accuracy, a quartz mask is preferable, and from the viewpoint that it is easy to increase the size, a film mask is preferable.

As the base material of the film mask, a polyester film is preferable, and a polyethylene terephthalate film is more preferable.

Specific examples of the base material of the film mask include XPR-7S SG [manufactured by Fujifilm Global Graphic Systems].

Preferred aspects of the light source, the exposure amount, and the exposing method used for the exposure are described in, for example, paragraphs [0146] and [0147] of WO2018/155193A, the contents of which are incorporated herein by reference.

### <Development Step>

The development step is a step of developing the photosensitive composition layer after the pattern exposure.

By developing the photosensitive composition layer after the pattern exposure, a pattern is formed.

The development of the photosensitive composition layer after the pattern exposure can be carried out using a developer.

As the developer, an alkali aqueous solution is preferable.

Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

A pH of the alkali aqueous solution at 25° C. is preferably 8 to 13, more preferably 9 to 12, and still more preferably 10 to 12.

A content of the alkali compound in the alkali aqueous solution is preferably 0.1% by mass to 5% by mass and more preferably 0.1% by mass to 3% by mass with respect to the total mass of the alkali aqueous solution.

Examples of the developer which is suitably used in the present disclosure include developers described in paragraph [0194] of WO2015/093271A.

Examples of a development method include methods such as puddle development, shower development, shower and spin development, and dip development.

Examples of the development method which is suitably used in the present disclosure include development methods described in paragraph [0195] of WO2015/093271A.

The development step may include a stage of performing the development, and a stage of performing the heating treatment (also referred to as “post baking”) with respect to the pattern obtained by the development.

A post-baking temperature is preferably 80° C. to 260° C. and more preferably 90° C. to 160° C. A post-baking time is preferably 1 minute to 180 minutes and more preferably 10 minutes to 60 minutes.

### <Coloring Step>

The manufacturing method according to the present disclosure includes a step of coloring the specific coloring material precursor contained in the photosensitive composition layer in black (that is, a coloring step), after the pattern exposure step (that is, the exposure step).

It is sufficient that the coloring step is performed after the exposure step, and for example, the coloring step may be performed during or after the development step. In addition, “after the exposure step” means “after the exposure for curing the photosensitive composition layer”.

In the coloring step, the specific coloring material precursor colors black by applying a stimulus to the photosensitive composition layer and/or the specific coloring material precursor contained in the photosensitive composition layer.

A method of coloring the specific coloring material precursor in black varies depending on the stimulus for causing the specific coloring material precursor to color black.

For example, in a case where the stimulus is heat, examples thereof include a method of heating the photosensitive composition layer after the exposure step. The method of heating the photosensitive composition layer after the exposure step is not particularly limited, and a known heating method can be adopted.

Examples of a heating unit include an oven, a hot plate, and a heat roll.

A heating temperature is not particularly limited as long as the specific coloring material precursor colors black at the heating temperature, and can be appropriately set according to a black coloring temperature of the specific coloring material precursor. For example, in a case where the specific coloring material precursor is the compound represented by Formula (1), the heating temperature is preferably 80° C. to 260° C.

A heating time is not particularly limited and can be appropriately set depending on the degree of coloring. In a case where the photosensitive composition layer contains a thermoplastic resin, it is preferable to appropriately adjust the heating time, such as shortening the heating time, in consideration of retention of the shape of the pattern.

As a method of coloring the specific coloring material precursor in black by heat, a method of coloring the specific coloring material precursor contained in the photosensitive composition layer in black by post-baking in the development step is preferable. For example, in a case where the specific coloring material precursor is the compound represented by Formula (1), the pattern containing the specific coloring material precursor, obtained by the development, is heated during post-baking to react the compound represented by Formula (1) with oxygen in the air to form an oxidant, thereby coloring black.

For example, in a case where the stimulus is acid, a method of generating the acid in the photosensitive composition layer after the exposure step using an acid generator or the like can be mentioned.

Examples of the method of generating the acid in the photosensitive composition layer after the exposure step using an acid generator or the like include a method of utilizing a difference in reaction rate between a curing reaction by photoradical polymerization of a polymerizable monomer or the like and a coloring reaction of the specific coloring material precursor by an acid generated from a photoacid generator.

For example, in a case where the specific coloring material precursor is the leuco dye, the curing reaction by photoradical polymerization of a polymerizable monomer or the like precedes the coloring reaction of the leuco dye by an acid generated from a photoacid generator, and thus the curing reaction is less affected by the coloring reaction.

Although the curing step of the curing reaction and the coloring step of the coloring reaction are not clearly distinguished from each other, the coloring step is not included in the exposure step in the manufacturing method according to the present disclosure because the coloring step is not a step of exposing the photosensitive composition for curing.

In addition, examples of the method of generating the acid in the photosensitive composition layer after the exposure step using an acid generator or the like also include a method of utilizing a difference between an absorption spectrum of a photoradical polymerization initiator and an absorption spectrum of a photoacid generator.

For example, in a case where the curing reaction of a polymerizable monomer or the like is performed by photoradical polymerization, as coloring the specific coloring material precursor with light having a wavelength which is absorbed by the photoradical polymerization initiator and not absorbed by the photoacid generator, by irradiating with light having a wavelength which is not absorbed by the photoacid generator, the curing reaction can be made less susceptible to the influence of the coloring reaction.

In addition, for example, in a case where the stimulus is acid, a method of bringing the photosensitive composition layer after the exposure step into contact with an acidic solution can also be mentioned.

Examples of the method of bringing the photosensitive composition layer after the exposure step into contact with an acidic solution include immersion in the acidic solution, spraying of the acidic solution, and application of the acidic solution.

Examples of the acidic solution include a hydrochloric acid aqueous solution, a sulfuric acid aqueous solution, and a nitric acid aqueous solution.

Among these, a hydrochloric acid aqueous solution is preferable as the acidic solution.

A concentration of the hydrochloric acid aqueous solution is, for example, preferably 5% by mass to 15% by mass.

In addition, for example, in a case where the stimulus for coloring the specific coloring material precursor in black is light, examples of a method of coloring the specific coloring material precursor in black include a method of irradiating the photosensitive composition layer after the exposure step with light; for example, in a case where the stimulus for coloring the specific coloring material precursor in black is base, examples of a method of coloring the specific coloring material precursor in black include a method of generating a base in the photosensitive composition layer after the exposure step using a base generator or the like; and for example, in a case where the stimulus for coloring the specific coloring material precursor in black is radical, examples of a method of coloring the specific coloring material precursor in black include a method of generating a radical in the photosensitive composition layer after the exposure step using a radical generator or the like. It is preferable to appropriately adjust any of the methods as long as the adjustment does not interfere with the exposure step.

A film thickness of the black pattern of the laminate manufactured by the manufacturing method according to the present disclosure is, for example, preferably 5 μm or more, and more preferably 10 μm or more. The upper limit thereof is, for example, preferably 20 μm or less, and more preferably 15 μm or less, from the viewpoint of handleability.

In a case where the film to be exposed is black, the light of exposure is absorbed, and thus polymerization curing is insufficient, making it difficult to form a thick film pattern. On the other hand, in the manufacturing method according to the present disclosure, by exposing the photosensitive composition layer before the specific coloring material precursor colors black, that is, exposing the photosensitive composition layer which does not exhibit black, the light of the exposure is not likely to be absorbed, and sufficient polymerization curing is performed. Therefore, it is possible to achieve the formation of a black pattern having a thickness of 5 μm or more.

### [Laminate Manufactured by Manufacturing Method According to Present Disclosure]

A laminate manufactured by the manufacturing method according to the present disclosure has a black pattern.

The black pattern of the laminate manufactured by the manufacturing method according to the present disclosure has excellent light shielding properties and exhibits a high aspect ratio.

A film thickness of the black pattern of the laminate manufactured by the manufacturing method according to the present disclosure is preferably 5 μm or more, and more preferably 10 μm or more.

In a case where the film thickness of the black pattern is 5 μm or more, for example, when the black pattern is used as a partition wall, color mixing between respective pixels tends to be further suppressed.

From the viewpoint of handleability, the upper limit of the film thickness of the black pattern is preferably 20 μm or less and more preferably 15 μm or less.

An absorbance of the black pattern of the laminate manufactured by the manufacturing method according to the present disclosure at a wavelength of 365 nm is preferably 2.0 or more, and more preferably 3.0 or more. The upper limit thereof is not particularly limited, and examples thereof include 5.0 or less.

An average absorbance of the black pattern of the laminate manufactured by the manufacturing method according to the present disclosure in a wavelength of 400 nm to 700 nm is preferably 2.0 or more, and more preferably 3.0 or more. The upper limit thereof is not particularly limited, and examples thereof include 5.0 or less.

In the black pattern of the laminate manufactured by the manufacturing method according to the present disclosure, an aspect ratio which is a ratio of the film thickness to a line width of a bottom portion is preferably 1.0 or more, and more preferably 2.0 or more. The upper limit thereof is not particularly limited, and examples thereof include 10.0 or less and 5.0 or less.

In the present disclosure, the aspect ratio which is a ratio of the film thickness to the line width of the bottom portion is determined by observing a cross section of the black pattern using a scanning electron microscope (SEM), measuring the film thickness of the black pattern and the line width of the bottom portion, and using the following expression.

“Aspect ratio”=“Film thickness”/“Line width of bottom portion”

### [Laminate]

The laminate according to the present disclosure includes a base material and a black pattern, in which a film thickness of the black pattern is 5 μm or more, an aspect ratio of the black pattern, which is a ratio of a film thickness to a line width of a bottom portion, is 1.0 or more, and an average absorbance in a wavelength of 400 nm to 700 nm is 2.0 or more.

The laminate according to the present disclosure has excellent light shielding properties and has a high aspect pattern of a thick film.

### <Base Material>

The laminate according to the present disclosure has a base material.

The base material included in the laminate according to the present disclosure has the same meaning as the base material in the manufacturing method according to the present disclosure; and the same applies to the preferred aspect thereof, and thus the description thereof will be omitted here.

### <Black Pattern>

The laminate according to the present disclosure has a black pattern.

A film thickness of the black pattern included in the laminate according to the present disclosure is 5 μm or more, and preferably 10 μm or more. The upper limit thereof is not particularly limited, but is, for example, preferably 20 μm or less and more preferably 15 μm or less.

In the black pattern included in the laminate according to the present disclosure, the aspect ratio which is a ratio of the film thickness to the line width of the bottom portion is 1.0 or more, preferably 2.0 or more. The upper limit thereof is not particularly limited, and examples thereof include 10.0 or less and 5.0 or less.

The average absorbance of the black pattern included in the laminate according to the present disclosure at a wavelength of 400 nm to 700 nm is 2.0 or more, preferably 3.0 or more. The upper limit thereof is not particularly limited, and examples thereof include 5.0 or less.

In the black pattern included in the laminate according to the present disclosure, a ratio of a line width of the uppermost portion to the line width of the bottom portion (Line width of uppermost portion/Line width of bottom portion) is preferably 0.8 to 1.2 and more preferably 0.9 to 1.1. The fact that the ratio of the line width of the uppermost portion to the line width of the bottom portion is 0.8 to 1.2 means that the black pattern has excellent rectangularity.

In the present disclosure, the ratio of the line width of the uppermost portion to the line width of the bottom portion (Line width of uppermost portion/Line width of bottom portion) is determined by observing a cross section of the black pattern using a scanning electron microscope (SEM), and measuring the line width of the bottom portion and the line width of the uppermost portion in the black pattern.

The black pattern included in the laminate according to the present disclosure preferably contains a coloring material represented by Formula (I).

The coloring material represented by Formula (I) is an oxidant of the compound represented by Formula (1) described above, and is a compound formed by the compound represented by Formula (1) being stimulated by heat to react with oxygen in the air.

In a case where tautomers and/or geometric isomers exist with regard to the compound represented by Formula (I), the existing tautomers and/or geometric isomers are included in the compound represented by Formula (I).

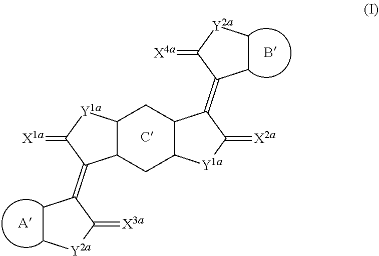

In Formula (I), X^{1a}, X^{2a}, X^{3a}, X^{4a}, Y^{1a}, and Y^{2a} each independently represent an oxygen atom, a sulfur atom, or N-L¹a, L^{1a} represents a hydrogen atom, an alkyl group, an acyl group, an alkoxycarbonyl group, or an aminocarbonyl group, and A′, B′, and C′ each independently represent an aromatic ring.

X^{1a}, X^{2a}, X^{3a}, X^{4a}, Y^{1a}, and Y^{2a} in Formula (I) have the same meanings as X¹, X², X³, X⁴, Y¹, and Y² in Formula (1) described above, and preferred aspects thereof are also the same, and thus the description thereof will be omitted here.

A′, B′, and C′ in Formula (I) have the same meanings as A, B, and C in Formula (1) described above, and preferred aspects thereof are also the same, and thus the description thereof will be omitted here.

In a case where the black pattern included the laminate according to the present disclosure contains the coloring material represented by Formula (I), the black pattern may contain only one kind of the coloring material, or may contain two or more kinds thereof.

In a case where the black pattern included in the laminate according to the present disclosure contains the coloring material represented by Formula (I), a content of the coloring material represented by Formula (I) in the black pattern is not particularly limited, but for example, it is preferably 5% by mass to 25% by mass, and more preferably 10% by mass to 20% by mass with respect to the total mass of the black pattern.

### [Micro LED Display]

The micro LED display according to the present disclosure includes the laminate according to the present disclosure described above.

The micro LED display according to the present disclosure includes the laminate according to the present disclosure, that is, includes the base material and the black pattern having a film thickness of 5 μm, in which the aspect ratio which is a ratio of the film thickness to the line width of the bottom portion is 1.0 or more, and the average absorbance in a wavelength of 400 nm to 700 nm is 2.0 or more. The above-described black pattern can function as a partition wall.

Examples of an aspect of the micro LED display according to the present disclosure include an aspect in which a micro LED array substrate including a plurality of micro LEDs, a partition wall provided between the plurality of micro LEDs, and a substrate facing the micro LED array substrate are provided, the partition wall is the black pattern in the laminate according to the present disclosure, and the substrate facing the micro LED array substrate is the base material in the laminate according to the present disclosure. In the micro LED display of such an aspect, since light leakage from the micro LED and each pixel light emitting portion, and color mixing between the respective pixels are suppressed by having the partition wall having excellent light shielding properties and a high aspect ratio, a contrast can be improved.

In the micro LED display according to the present disclosure, from the viewpoint of pattern processability, a width of the black pattern which can function as the partition wall is preferably 3 μm or more. In addition, from the viewpoint of securing a large light emission region of the micro LED and further increasing the brightness, the width of the black pattern is preferably 100 μm or less.

### EXAMPLES

Hereinafter, the present disclosure will be further described in detail according to Examples. The materials, the used amounts, the proportions, the treatment contents, the treatment procedures, and the like described in the following examples can be appropriately changed without departing from the gist of the present disclosure. Therefore, the scope of the present disclosure should not be construed as being limited to Examples.

Unless specified otherwise, “part(s)” and “%” represent “part(s) by mass” and “% by mass”.

In addition, in Examples, a weight-average molecular weight of a resin is a weight-average molecular weight obtained by performing polystyrene conversion of a value measured by gel permeation chromatography (GPC).

### [Synthesis of Binder Polymer P-1]

After charging 82.4 g of propylene glycol monomethyl ether [manufactured by FUJIFILM Wako Pure Chemical Corporation] into a flask having a capacity of 1,000 mL, the flask was heated to 90° C. in a nitrogen stream. A solution obtained by dissolving 38.4 g of styrene [manufactured by FUJIFILM Wako Pure Chemical Corporation], 30.1 g of dicyclopentanyl methacrylate [product name: FANCRYL (registered trademark) FA-513M, manufactured by Hitachi Chemical Co., Ltd.], and 34.0 g of methacrylic acid [manufactured by FUJIFILM Wako Pure Chemical Corporation] in 20 g of propylene glycol monomethyl ether, and a solution obtained by dissolving 5.4 g of dimethyl 2,2′-azobis (2-methylpropionate) [product name: V-601, manufactured by FUJIFILM Wako Pure Chemical Corporation] as a polymerization initiator in 43.6 g of propylene glycol monomethyl ether acetate [manufactured by FUJIFILM Wako Pure Chemical Corporation] were added dropwise thereto over 3 hours.

After completion of the dropwise addition, 0.75 g of the polymerization initiator (V-601) was added to the solution after completion of the dropwise addition every hour three times. Next, the solution after the addition was further reacted for 3 hours.

Next, the obtained solution was diluted with 58.4 g of propylene glycol monomethyl ether acetate and 11.7 g of propylene glycol monomethyl ether.

Next, the diluted solution was heated to 100° C. in an air stream.

Next, 0.53 g of tetraethylammonium bromide [manufactured by FUJIFILM Wako Pure Chemical Corporation] and 0.26 g of p-methoxyphenol [manufactured by FUJIFILM Wako Pure Chemical Corporation] were added to the heated solution.

Next, 25.5 g of glycidyl methacrylate [product name: BLEMMER (registered trademark) GH, manufactured by NOF Corporation] was added dropwise to the obtained solution over 20 minutes.

Next, the obtained solution was reacted at 100° C. for 7 hours to obtain 350.6 g of a solution of a binder polymer P-1.

A concentration of solid contents of the obtained solution was 36.3% by mass.

The obtained binder polymer P-1 included each structural unit shown in Table 1, had a weight-average molecular weight (Mw) of 17,000, a dispersity (Mw/Mn) of 2.4, and an acid value of 94.5 mgKOH/g.

The weight-average molecular weight (Mw) and the number-average molecular weight (Mn) are values in terms of standard polystyrene measured by gel permeation chromatography (GPC). The same method was used for a binder polymer P-2 described later.

The acid value was measured according to the method described in JIS K 0070:1992. The same method was performed for the binder polymer P-2 described later.

For any monomer, a residual monomer amount measured by gas chromatography (GC) was less than 0.1% by mass with respect to the solid content of the binder polymer P-1.

The “solid content” means all components excluding a solvent in the solution of the binder polymer P-1, and even in a case where a property of a component was in a liquid state, the component is included in the solid content. The same applies to the binder polymer P-2 described later.

### [Synthesis of Binder Polymer P-2]

60 g of propylene glycol monomethyl ether acetate [product name: PGM-Ac, manufactured by SANWA KAGAKU SANGYO Co., Ltd.] and 240 g of propylene glycol monomethyl ether [product name: PGM, manufactured by SANWA KAGAKU SANGYO Co., Ltd.] were charged into a flask having a capacity of 2,000 mL. Next, the liquid in the flask was heated to 90° C. while stirring at a stirring speed of 250 revolutions per minute (rpm).

Next, 107.1 g of methacrylic acid [product name: ACRYL ESTER (registered trademark) M, manufactured by Mitsubishi Chemical Corporation], 5.46 g of methyl methacrylate [product name: MMA, manufactured by Mitsubishi Gas Chemical Company, Inc.], and 231.42 g of cyclohexyl methacrylate [product name: CHMA, manufactured by Mitsubishi Gas Chemical Company, Inc.] were mixed with each other, and diluted with 60 g of propylene glycol monomethyl ether acetate to prepare a dropping liquid (1).

Next, 9.637 g of dimethyl 2,2′-azobis (2-methylpropionate) [product name: V-601, manufactured by FUJIFILM Wako Pure Chemical Corporation] as a polymerization initiator was dissolved in 136.56 g of propylene glycol monomethyl ether acetate to prepare a dropping liquid (2).

The dropping liquid (1) and the dropping liquid (2) prepared as described above were simultaneously added dropwise to the flask having a capacity of 2,000 mL, containing the liquid heated to 90° C. described above, over 3 hours. Subsequently, the container containing the dropping liquid (1) was washed with 12 g of propylene glycol monomethyl ether acetate, and the obtained washing solution was added dropwise to the flask having a capacity of 2,000 mL. Subsequently, the container containing the dropping liquid (2) was washed with 6 g of propylene glycol monomethyl ether acetate, and the obtained washing solution was added dropwise to the above-described flask having a capacity of 2,000 mL. During the dropwise addition of these washing solutions, the reaction solution in the above-described flask having a capacity of 2,000 mL was kept at a liquid temperature of 90° C. and stirred at a stirring speed of 250 rpm. After the dropwise addition, as a post-reaction, the reaction solution in the flask was kept at a liquid temperature of 90° C. and stirred at a stirring speed of 250 rpm for 1 hour.

Next, 2.401 g of V-601 was added to the reaction solution after the post-reaction as a first additional addition of the polymerization initiator. Subsequently, the container containing V-601 was washed with 6 g of propylene glycol monomethyl ether acetate, the obtained washing solution was further added to the reaction solution, and then the mixture was stirred at 90° C. for 1 hour.

Next, 2.401 g of V-601 was added to the obtained reaction solution as a second additional addition of the polymerization initiator. Subsequently, the container containing V-601 was washed with 6 g of propylene glycol monomethyl ether acetate, the obtained washing solution was further added to the reaction solution, and then the mixture was stirred at 90° C. for 1 hour.

Next, 2.401 g of V-601 was added to the obtained reaction solution as a third additional addition of the polymerization initiator. Subsequently, the container containing V-601 was washed with 6 g of propylene glycol monomethyl ether acetate, the obtained washing solution was further added to the reaction solution, and then the mixture was stirred at 90° C. for 3 hours.

Next, 178.66 g of propylene glycol monomethyl ether acetate was added to the obtained reaction solution. Next, 1.8 g of tetraethylammonium bromide [manufactured by FUJIFILM Wako Pure Chemical Corporation] and 0.8 g of hydroquinone monomethyl ether [manufactured by FUJIFILM Wako Pure Chemical Corporation] were added to the obtained reaction solution. Next, each of the container containing tetraethylammonium bromide and the container containing hydroquinone monomethyl ether was washed with 6 g of propylene glycol monomethyl ether acetate, and the obtained washing solutions were further added to the reaction solution.

Next, the temperature of the obtained reaction solution was raised to 100° C.

Next, 76.03 g of glycidyl methacrylate [product name: BLEMMER (registered trademark) G, manufactured by NOF Corporation] was added dropwise to the reaction solution after the temperature was raised, over 1 hour. Subsequently, the container containing BLEMMER G was washed with 6 g of propylene glycol monomethyl ether acetate, the obtained washing solution was further added to the reaction solution, and then the mixture was stirred at 100° C. for 6 hours for an addition reaction.

Next, the obtained reaction solution was cooled and then filtered using a mesh filter for removing dust (mesh size: 100 mesh), thereby obtaining 1,158 g of a solution of a binder polymer P-2.

A concentration of solid contents of the obtained solution was 36.3% by mass.

The obtained binder polymer P-2 included each structural unit shown in Table 1, had a weight-average molecular weight (Mw) of 27,000, a dispersity (Mw/Mn) of 1.8, and an acid value of 95.0 mgKOH/g.

For any monomer, a residual monomer amount measured by gas chromatography (GC) was less than 0.1% by mass with respect to the solid content of the binder polymer P-2.

TABLE 1

| | | Binder polymer | |
|---|---|---|---|
| | | P-1 | P-2 |
| Proportion | St | 30.0 | — |
| of structural | CHMA | — | 51.5 |
| unit | MAA-GMA | 32.0 | 20.0 |
| [% by mass] | MAA | 14.5 | 26.5 |
| | MMA | — | 2.0 |
| | DCPMA | 23.5 | — |

| | | |
|---|---|---|
| Weight-average molecular | 17000 | 27000 |
| weight (Mw) | | |
| Dispersity (Mw/Mn) | 2.4 | 1.8 |
| Acid value [mgKOH/g] | 94.5 | 95.0 |

In Table 1, structural units other than a structural unit having a (meth)acryloyl group are shown by abbreviations of monomers for forming each structural unit.

The structural unit having a (meth)acryloyl group is shown in a form of an addition structure of monomers. For example, MAA-GMA means a structural unit in which glycidyl methacrylate (GMA) is added to a structural unit derived from methacrylic acid (MAA).

The following abbreviations respectively indicate the following monomers.
“St”: styrene
“CHMA”: cyclohexyl methacrylate
“MAA”: methacrylic acid
“MMA” methyl methacrylate
“GMA”: glycidyl methacrylate
“DCPMA”: dicyclopentanyl methacrylate
   [Synthesis of Coloring Material Precursor which Colors Black by Stimulus]

The following compounds (1) and (3) were synthesized based on the following scheme. N—R in the scheme corresponds to Y² in Formula (1).

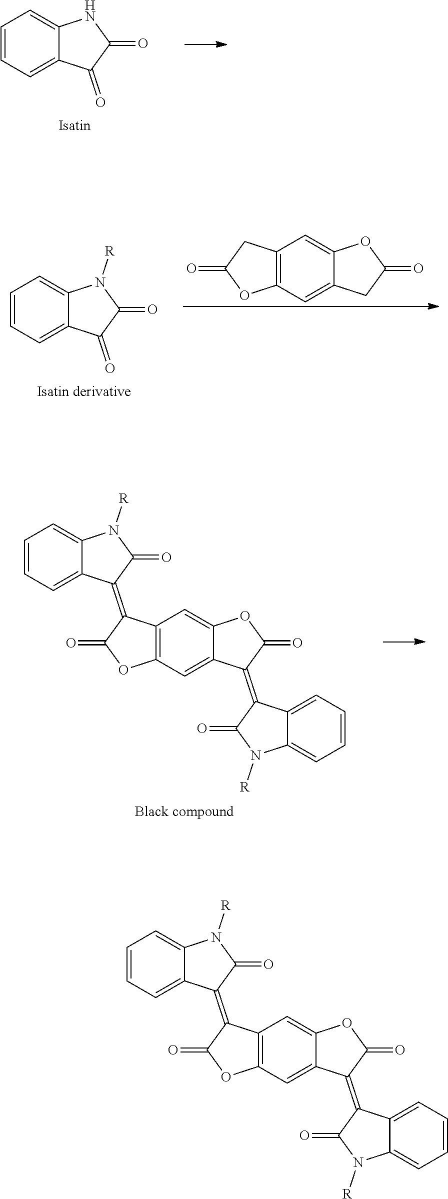

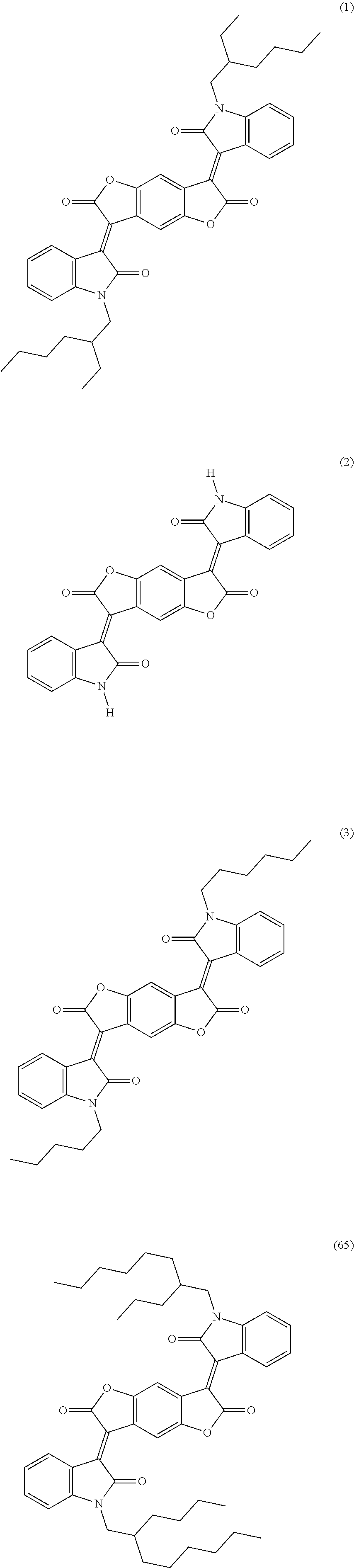

### [Synthesis of Compound (1)]

With reference to J. Am. Chem. Soc. 2015, 137, pp. 15947 to 15956, a compound [the following compound (100)] corresponding to the black compound in the above scheme was synthesized using isatin as a starting material. 150 mL of tetrahydrofuran (THF) [containing a stabilizer, Wako 1st grade, manufactured by FUJIFILM Wako Pure Chemical Corporation] was charged into a 300 mL three-neck flask, and then 10.0 g of the synthesized compound (100) and 4.9 g of zinc powder [Wako special grade, manufactured by FUJIFILM Wako Pure Chemical Corporation] were added thereto. The above-described three-neck flask was immersed in ice water to maintain the internal temperature at 5° C. or lower, and 15 mL of trifluoroacetic acid [Wako special grade, manufactured by FUJIFILM Wako Pure Chemical Corporation] was added dropwise thereto. After completion of the dropwise addition, the external equipment was removed, and the mixture was reacted in a water bath for 2 hours such that the internal temperature did not reach 40° C. or higher. The reaction solution was filtered through Celite, 10 mL of ultrapure water was added to the filtrate, and the solution was heated to 40° C. to distill off THF under reduced pressure. The precipitated gray solid was subjected to suction filtration and washed with 300 mL of ultrapure water. The resultant was dried for 12 hours using a blast dryer at a set temperature of 50° C., thereby obtaining 4.5 g of the compound (1) (yield: 46%).

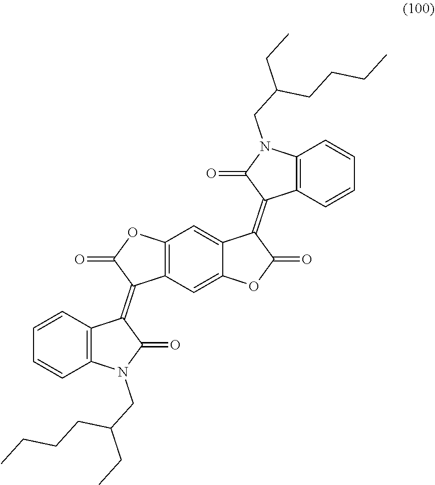 [SMILES: CCCCC(CC)CN1C(=O)/C(=C2/C(=O)Oc3cc4c(cc32)OC(=O)/C4=C2/C(=O)N(CC(CC)CCCC)c3ccccc32)c2ccccc21]

A structure of the obtained compound (1) was confirmed to be the structure of the above-described compound (1) by ¹H-NMR. The NMR data of the obtained compound (1) are shown below.

### <NMR Data of Compound (1)>

¹H-NMR (CDCl₃-d) δ=0.80 to 1.90 (m, 30H), 3.30 to 3.70 (m, 4H), 4.20 to 4.50 (s×3, 4H), 6.20 to 6.50 (m, 2H), 6.80 to 7.20 (m, 6H), 7.30 to 7.40 (m, 2H)

### [Synthesis of Compound (3)]

With reference to Journal of Medicinal Chemistry, 2008, 51, pp. 4932 to 4947, an isatin derivative was synthesized by reacting isatin with 1-bromohexane. Using the synthesized isatin derivative, the compound (3) was synthesized by the same method as that for the compound (1) described above.

A structure of the obtained compound (3) was confirmed to be the structure of the above-described compound (3) by ¹H-NMR. NMR data of the obtained compound (3) are shown below.

### <NMR Data of Compound (3)>

¹H-NMR (CDCl₃-d) δ=0.69 to 0.71 (t, 6H), 3.35 to 3.76 (m, 12H), 4.20 to 4.50 (s×3, 4H), 6.20 to 6.50 (m, 2H), 6.80 to 7.20 (m, 6H), 7.30 to 7.40 (m, 2H)

### [Synthesis of Compound (2)]

In the above scheme, a black compound [a compound (101) having the following structure] was directly synthesized from isatin without going through an isatin derivative. 100 mL of N,N-dimethylformamide (DMF) [Wako special grade, manufactured by FUJIFILM Wako Pure Chemical Corporation] was charged into a 300 mL three-neck flask, and then 10.0 g of a compound (101) and 1.0 g of Palladium 10% on Carbon [product name, manufactured by Tokyo Chemical Industry Co., Ltd.] were further added thereto. A balloon in which nitrogen was sealed was attached to the flask, the inside of the flask was degassed, and then the inside of the flask was purged with nitrogen. The mixture was reacted at room temperature for 2 hours in a nitrogen atmosphere. The reaction solution was filtered through Celite, and the Celite was washed with ethyl acetate. The filtrate was subjected to an evaporator in a water bath at 40° C. to distill off ethyl acetate, thereby obtaining a DMF solution containing a target substance. The DMF solution was purified by silica gel column chromatography, and a fraction containing the target substance was subjected to the evaporator again to obtain 10 mg (yield: 0.22%) of a precipitated gray compound (2).

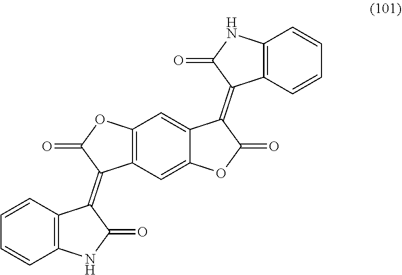 [SMILES: O=C1Nc2ccccc2/C1=C1\C(=O)Oc2cc3c(cc21)OC(=O)/C3=C1/C(=O)Nc2ccccc21]

A structure of the obtained compound (2) was confirmed to be the structure of the above-described compound (2) by ¹H-NMR. NMR data of the obtained compound (2) are shown below.

### <NMR Data of Compound (2)>

¹H-NMR (DMSO-d₆) δ=4.25 to 4.40 (m, 2H), 4.75 to 4.84 (m, 2H), 6.47 to 6.55 (m, 1H), 6.70 to 7.00 (m, 7H), 7.10 to 7.32 (m, 2H)

### [Synthesis of Compound (65)]

A compound (65) was obtained in the same manner as in the compound (1), except that in the synthesis of the compound (1), “5-(bromomethyl) undecane” was used instead of “2-ethylhexyl bromide”.

A structure of the obtained compound (65) was confirmed to be the structure of the above-described compound (65) by ¹H-NMR. NMR data of the obtained compound (65) are shown below.

### <NMR Data of Compound (65)>

¹H-NMR (CDCl₃) δ=0.83 to 0.89 (m, 12H), 0.90 to 1.50 (m, 32H), 1.60 to 1.78 (brs×2, 2H), 3.38 to 3.60 (m, 4H), 4.25 to 4.48 (m, 4H), 6.23 to 6.50 (m, 2H), 6.82 to 7.07 (m, 6H), 7.33 to 7.40 (m, 2H)

### [Color Evaluation of Coloring Material Precursor]

1.1 mg of the compound (1) was dissolved in 50 mL of tetrahydrofuran (THF) [containing a stabilizer, Wako 1st grade, manufactured by FUJIFILM Wako Pure Chemical Corporation] to prepare a THF solution of the compound (1). Next, the prepared THE solution of the compound (1) was placed in a 1 cm cell; and using a spectrophotometer [model number: UV-1800, manufactured by Shimadzu Corporation] as a measuring device, an absorption spectrum was measured, and a molar absorption coefficient at each wavelength was determined at intervals of 1 nm. An average molar absorption coefficient at any continuous 100 nm in a wavelength range of 400 nm to 700 nm was calculated, and color of the coloring material precursor was evaluated according to the following evaluation standard.

With regard to the compound (3), the compound (2), the compound (65), 2′-anilino-6′-(dibutylamino)-3′-methylfluoran [manufactured by Tokyo Chemical Industry Co., Ltd.], and BLACK 305 [manufactured by Fukui Yamada Chemical Co., Ltd.], an average molar absorption coefficient was calculated by the same procedure as in the compound (1) described above, and color of the coloring material precursor was evaluated according to the following evaluation standard.

The results of the color evaluation of the coloring material precursor are shown in Table 2.

The evaluation result is preferably “A”, “B”, or “C”.

### —Evaluation Standard—

A: average molar absorption coefficient was 100 L/(mol·cm) or less.
B: average molar absorption coefficient was in a range of more than 100 L/(mol·cm) and 200 L/(mol·cm) or less.
C: average molar absorption coefficient was in a range of more than 200 L/(mol·cm) and 400 L/(mol·cm) or less.
D: average molar absorption coefficient was more than 400 L/(mol·cm).

### [Black Coloring Development Evaluation of Coloring Material Precursor]

1.1 mg of the compound (1) was heated for 60 minutes in an environment of an atmosphere temperature of 230° C. to color black. The black color substance of the obtained compound (1) was dissolved in 50 mL of tetrahydrofuran (THF) [containing a stabilizer, Wako 1st grade, manufactured by FUJIFILM Wako Pure Chemical Corporation] to prepare a THF solution of the black color substance of the compound (1). Next, the prepared THE solution of the black color substance of the compound (1) was placed in a 1 cm cell; and using a spectrophotometer [model number: UV-1800, manufactured by Shimadzu Corporation] as a measuring device, an absorption spectrum was measured, and a molar absorption coefficient at each wavelength was determined. Thereafter, a maximal absorption wavelength and a molar absorption coefficient at the maximal absorption wavelength (here, in a case of two or more maximal absorption wavelengths, a molar absorption coefficient at a wavelength at which absorption is maximum) were obtained. In addition, a molar absorption coefficient at each wavelength was determined for every 1 nm, an average molar absorption coefficient at any continuous 100 nm in a wavelength range of 400 nm to 700 nm was calculated, and evaluation was performed according to the following evaluation standard.

With regard to the compound (3), the compound (2), and the compound (65), an absorption spectrum was measured by the same procedure as in the compound (1) described above, and a maximal absorption wavelength and a molar absorption coefficient at the maximal absorption wavelength (here, in a case of two or more maximal absorption wavelengths, a molar absorption coefficient at a wavelength at which absorption is maximum) were obtained. In addition, an average molar absorption coefficient at any continuous 100 nm in a wavelength range of 400 nm to 700 nm was calculated, and evaluation was performed according to the following evaluation standard.

In an environment of an atmosphere temperature of 25° C., 2 ml of a hydrochloric acid aqueous solution having a concentration of 10% by mass was added dropwise to 1.1 mg of 2′-anilino-6′-(dibutylamino)-3′-methylfluoran [manufactured by Tokyo Chemical Industry Co., Ltd.], and the mixture was allowed to stand for 10 minutes to color black. The obtained hydrochloric acid aqueous solution of the black color substance was heated for 15 minutes using a far-infrared heating furnace (so-called IR oven) heated to 150° C., and powder of the black color substance was isolated. The isolated powder of the black color substance was dissolved in 50 mL of tetrahydrofuran (THF) to prepare a THF solution of the black color substance of 2′-anilino-6′-(dibutylamino)-3′-methylfluoran. Using the THF solution of the black color substance of 2′-anilino-6′-(dibutylamino)-3′-methylfluoran, an absorption spectrum was measured by the same procedure as in the compound (1) described above, and a maximal absorption wavelength and a molar absorption coefficient at the maximal absorption wavelength (here, in a case of two or more maximal absorption wavelengths, a molar absorption coefficient at a wavelength at which absorption is maximum) were obtained. In addition, an average molar absorption coefficient at any continuous 100 nm in a wavelength range of 400 nm to 700 nm was calculated, and evaluation was performed according to the following evaluation standard.

With regard to BLACK 305 [manufactured by Fukui Yamada Chemical Co., Ltd.], an absorption spectrum was measured by the same procedure as in the 2′-anilino-6′-(dibutylamino)-3′-methylfluoran [manufactured by Tokyo Chemical Industry Co., Ltd.] described above, and a maximal absorption wavelength and a molar absorption coefficient at the maximal absorption wavelength (here, in a case of two or more maximal absorption wavelengths, a molar absorption coefficient at a wavelength at which absorption is maximum) were obtained. In addition, an average molar absorption coefficient at any continuous 100 nm in a wavelength range of 400 nm to 700 nm was calculated, and evaluation was performed according to the following evaluation standard.

The results of the black coloring development evaluation of the coloring material precursor are shown in Table 2.

As the value of the average molar absorption coefficient is higher, light shielding properties are more excellent.

The evaluation result is preferably “A” or “B”.

### —Evaluation Standard—

A: average molar absorption coefficient was 3,000 L/(mol·cm) or more.
B: average molar absorption coefficient was in a range of 2,000 L/(mol·cm) or more and less than 3,000 L/(mol·cm).
C: average molar absorption coefficient was less than 2,000 L/(mol·cm).

TABLE 2

| | Color | | | |
|---|---|---|---|---|
| | evaluation | | | |
| | of coloring | | | |
| | material | Black coloring development evaluation | | |
| | precursor | of coloring material precursor | | |
| | Average | | | Average |
| | molar | | Molar | molar |
| | absorption | | absorption | absorption |
| | coefficient | Maximal | coefficient | coefficient |
| | at any | absorption | at maximal | at any |
| | continuous | wavelength | absorption | continuous |
| | 100 nm | [nm] | wavelength | 100 nm |
| Compound (1) | B | 422,681 | 5900 | A |
| Compound (3) | A | 424,677 | 6200 | B |
| Compound (2) | A | 419,677 | 6300 | A |
| Compound (65) | A | 428,680 | 6000 | A |
| 2′-Anilino-6′-(dibutylamino)-3′- | A | 465,598 | 12000 | A |
| methylfluoran | | | | |
| [manufactured by Tokyo Chemical | | | | |
| Industry Co., Ltd.] | | | | |
| BLACK 305 | A | 453,588 | 12000 | B |
| [manufactured by Fukui Yamada | | | | |
| Chemical Co., Ltd.] | | | | |

### [Preparation of Photosensitive Composition]

### Examples 1a to 4A

The respective components were mixed so as to have the composition shown in Table 3. Zirconia beads (bead diameter: 0.1 mm) in an amount three times the mass of the mixture were added to the obtained mixture, and then the mixture was dispersed using a multi-stacked elements (MSE) mixer at a circumferential speed of 9 m/sec for 90 minutes. After the dispersion, the above-described zirconia beads were separated using a filter having a nominal filtration particle size of 73 μm to obtain photosensitive compositions X-1 to X-4 of Examples 1A to 4A.

### Examples 5A to 8A and Comparative Example 1A

The respective components were mixed so as to have the composition shown in Table 4. Zirconia beads (bead diameter: 0.1 mm) in an amount three times the mass of the mixture were added to the obtained mixture, and then the mixture was dispersed using a multi-stacked elements (MSE) mixer at a circumferential speed of 9 m/sec for 90 minutes. After the dispersion, the above-described zirconia beads were separated using a filter having a nominal filtration particle size of 73 μm to obtain photosensitive compositions X-5 to X-8, and Y-1 of Examples 5A to 8A, and Comparative Example 1A.

### Example 9A

The respective components were mixed so as to have the composition shown in Table 5. Zirconia beads (bead diameter: 0.1 mm) in an amount three times the mass of the mixture were added to the obtained mixture. Next, the mixture was dispersed using a multi-stacked elements (MSE) mixer at a circumferential speed of 9 m/sec for 70 minutes, and then at a circumferential speed of 6 m/sec for 40 minutes. After the dispersion, the above-described zirconia beads were separated using a filter having a nominal filtration particle size of 73 μm to obtain a photosensitive composition X-9 of Example 9A.

### Example 10A

The respective components were mixed so as to have the composition shown in Table 5, and the mixture was stirred for 20 minutes to obtain a photosensitive composition X-10 of Example 10A.

TABLE 3

| | | | Photosensitive composition | | | |
|---|---|---|---|---|---|---|
| | | | Example 1A | Example 2A | Example 3A | Example 4A |
| | | | (X-1) | (X-2) | (X-3) | (X-4) |
| Formulation | Radically | 1,9-Nonanediol diacrylate | 6.87 | 6.45 | — | 3.12 |
| (part by | polymerizable | [A-NOD-N, manufactured by Shin- | | | | |
| mass) | monomer | Nakamura Chemical Co., Ltd.] | | | | |
| | | Dipentaerythritol pentaacrylate | 3.21 | 3.02 | — | 2.87 |
| | | [KAYARAD DPHA, manufactured by | | | | |
| | | Nippon Kayaku Co., Ltd.] | | | | |
| | | ARONIX TO-2349 | 1.54 | 1.45 | 1.29 | 1.09 |
| | | [manufactured by Toagosei Co., Ltd.] | | | | |
| | | A-DCP | — | — | 6.17 | — |
| | | [manufactured by Shin-Nakamura | | | | |
| | | Chemical Co., Ltd.] | | | | |
| | | 8UX-015A | — | — | 3.09 | — |
| | | [manufactured by Taisei Fine | | | | |
| | | Chemical Co., Ltd.] | | | | |
| | | KAYARAD R-604 | — | — | — | 3.12 |
| | | [manufactured by Nippon Kayaku | | | | |
| | | Co., Ltd.] | | | | |
| | Alkali- | Binder polymer P-1 | 44.5 | 41.8 | — | — |
| | soluble | (solid content: 36.3% by mass, | | | | |
| | resin | binder solution) | | | | |
| | | Binder polymer P-2 | — | — | 47.2 | 45.8 |
| | | (solid content: 36.3% by mass, | | | | |
| | | binder solution) | | | | |
| | Photopoly- | Irgacure OXE-02 | — | — | 0.12 | — |
| | merization | [manufactured by BASF SE] | | | | |
| | initiator | Omnirad 379EG | — | — | — | 0.09 |
| | | [manufactured by IGM Resins B.V.] | | | | |
| | | 1-(Biphenyl-4-yl)-2-methyl-2- | — | — | 0.24 | 0.25 |
| | | morpholinopropan-1-one | | | | |
| | | [APi-307, manufactured by | | | | |
| | | Shenzhen UV-ChemTech Co., Ltd.] | | | | |
| | | 2,2′-Bis(2-chlorophenyl)-4,4′,5,5′- | 1.87 | 1.76 | — | — |
| | | tetraphenyl-1,2′-biimidazole | | | | |
| | | [manufactured by Tokyo Chemical | | | | |
| | | Industry Co., Ltd.] | | | | |
| | Sensitizer | SB-PI 701 | 0.02 | 0.02 | — | — |
| | | [manufactured by SANYO | | | | |
| | | TRADING CO., LTD.] | | | | |
| | Photoacid | Photoacid generator X | — | — | — | — |
| | generator | TPS-102 | — | — | — | — |
| | | [manufactured by Midori | | | | |
| | | Kagaku Co., Ltd.] | | | | |
| | Chain | N-Phenylcarbamoylmethyl-N- | 0.19 | 0.19 | — | — |
| | transfer | carboxymethylaniline | | | | |
| | agent | [manufactured by FUJIFILM | | | | |
| | | Wako Pure Chemical Corporation] | | | | |
| | | N-Phenylglycine | — | — | 0.04 | — |
| | | [manufactured by FUJIFILM | | | | |
| | | Wako Pure Chemical Corporation] | | | | |
| | Polymerization | TDP-G | 0.09 | 0.09 | — | — |
| | inhibitor | [manufactured by Kawaguchi | | | | |
| | | Chemical Industry Co., LTD.] | | | | |
| | Coloring | Compound (1) | 5.26 | 7.02 | 7.00 | — |
| | material | Compound (3) | — | — | — | 7.00 |
| | precursor | 2′-Anilino-6′-(dibutylamino)-3′- | — | — | — | — |
| | | methylfluoran | | | | |
| | | [manufactured by Tokyo Chemical | | | | |
| | | Industry Co., Ltd.] | | | | |
| | | BLACK 305 | — | — | — | — |
| | | [manufactured by Fukui Yamada | | | | |
| | | Chemical Co., Ltd.] | | | | |
| | Coloring | Irgaphor Black S 0100CF | — | — | — | — |
| | material | [manufactured by BASF SE] | | | | |
| | Additive | MEGAFACE F551A | 0.31 | 0.31 | 0.22 | 0.19 |
| | | [manufactured by DIC Corporation] | | | | |
| | | XIRAN EF-40 | — | — | — | 0.88 |
| | | [manufactured by TOMOE | | | | |
| | | Engineering Co., Ltd.] | | | | |
| | | Benzoimidazole | — | — | 0.11 | 0.11 |
| | | [manufactured by FUJIFILM | | | | |
| | | Wako Pure Chemical Corporation] | | | | |
| | Solvent | 1-Methoxy-2-propyl acetate (MMPGAC) | 11.6 | 12.1 | 20.2 | — |
| | | Methyl ethyl ketone (MEK) | 24.5 | 25.7 | 14.3 | 35.4 |

TABLE 4

| | | | Photosensitive composition | | | | |
|---|---|---|---|---|---|---|---|
| | | | Example | Example | Example | Example | Comparative |
| | | | 5A | 6A | 7A | 8A | Example 1A |
| | | | (X-5) | (X-6) | (X-7) | (X-8) | (Y-1) |
| Formulation | Radically | 1,9-Nonanediol diacrylate | 5.70 | 5.70 | 5.67 | 5.67 | 5.70 |
| (part by | polymerizable | [A-NOD-N, manufactured by Shin- | | | | | |
| mass) | monomer | Nakamura Chemical Co., Ltd.] | | | | | |
| | | Dipentaerythritol pentaacrylate | 2.67 | 2.67 | 2.65 | 2.65 | 2.67 |
| | | [KAYARAD DPHA, manufactured by | | | | | |
| | | Nippon Kayaku Co., Ltd.] | | | | | |
| | | ARONIX TO-2349 | 1.28 | 1.28 | 1.27 | 1.27 | 1.28 |
| | | [manufactured by Toagosei Co., Ltd.] | | | | | |
| | | A-DCP | — | — | — | — | — |
| | | [manufactured by Shin-Nakamura | | | | | |
| | | Chemical Co., Ltd.] | | | | | |
| | | 8UX-015A | — | — | — | — | — |
| | | [manufactured by Taisei Fine | | | | | |
| | | Chemical Co., Ltd.] | | | | | |
| | | KAYARAD R-604 | — | — | — | — | — |
| | | [manufactured by Nippon Kayaku | | | | | |
| | | Co., Ltd.] | | | | | |
| | Alkali- | Binder polymer P-1 | 37.0 | 37.0 | 36.8 | 36.8 | 37.0 |
| | soluble | (solid content: 36.3% by mass, | | | | | |
| | resin | binder solution) | | | | | |
| | | Binder polymer P-2 | — | — | — | — | — |
| | | (solid content: 36.3% by mass, | | | | | |
| | | binder solution) | | | | | |
| | Photopoly- | Irgacure OXE-02 | — | — | — | — | — |
| | merization | [manufactured by BASF SE] | | | | | |
| | initiator | Omnirad 379EG | — | — | — | — | — |
| | | [manufactured by IGM Resins B.V.] | | | | | |
| | | 1-(Biphenyl-4-yl)-2-methyl-2- | — | — | — | — | — |
| | | morpholinopropan-1-one | | | | | |
| | | [APi-307, manufactured by | | | | | |
| | | Shenzhen UV-ChemTech Co., Ltd.] | | | | | |
| | | 2,2′-Bis(2-chlorophenyl)-4,4′,5,5′- | 1.55 | 1.55 | 1.55 | 1.55 | 1.55 |
| | | tetraphenyl-1,2′-biimidazole | | | | | |
| | | [manufactured by Tokyo Chemical | | | | | |
| | | Industry Co., Ltd.] | | | | | |
| | Sensitizer | SB-PI 701 | 0.01 | 0.01 | 0.01 | 0.01 | 0.01 |
| | | [manufactured by SANYO | | | | | |
| | | TRADING CO., LTD.] | | | | | |
| | Photoacid | Photoacid generator X | — | — | 0.58 | — | — |
| | generator | TPS-102 | — | — | — | 0.58 | — |
| | | [manufactured by Midori | | | | | |
| | | Kagaku Co., Ltd.] | | | | | |
| | Chain | N-Phenylcarbamoylmethyl-N- | 0.13 | 0.13 | 0.13 | 0.13 | 0.13 |
| | transfer | carboxymethylaniline | | | | | |
| | agent | [manufactured by FUJIFILM | | | | | |
| | | Wako Pure Chemical Corporation] | | | | | |
| | | N-Phenylglycine | — | — | — | — | — |
| | | [manufactured by FUJIFILM | | | | | |
| | | Wako Pure Chemical Corporation] | | | | | |
| | Polymerization | TDP-G | 0.07 | 0.07 | 0.07 | 0.07 | 0.07 |
| | inhibitor | [manufactured by Kawaguchi | | | | | |
| | | Chemical Industry Co., LTD.] | | | | | |
| | Coloring | Compound (1) | — | — | — | — | — |
| | material | Compound (3) | — | — | — | — | — |
| | precursor | 2′-Anilino-6′-(dibutylamino)-3′- | 4.35 | — | 4.32 | 4.32 | — |
| | | methylfluoran | | | | | |
| | | [manufactured by Tokyo Chemical | | | | | |
| | | Industry Co., Ltd.] | | | | | |
| | | BLACK 305 | — | 4.35 | — | — | — |
| | | [manufactured by Fukui Yamada | | | | | |
| | | Chemical Co., Ltd.] | | | | | |
| | Coloring | Irgaphor Black S 0100CF | — | — | — | — | 4.35 |
| | material | [manufactured by BASF SE] | | | | | |
| | Additive | MEGAFACE F551A | 0.22 | 0.22 | 0.22 | 0.22 | 0.22 |
| | | [manufactured by DIC Corporation] | | | | | |
| | | XIRAN EF-40 | — | — | — | — | — |
| | | [manufactured by TOMOE | | | | | |
| | | Engineering Co., Ltd.] | | | | | |
| | | Benzoimidazole | — | — | — | — | — |
| | | [manufactured by FUJIFILM | | | | | |
| | | Wako Pure Chemical Corporation] | | | | | |
| | Solvent | 1-Methoxy-2-propyl acetate (MMPGAC) | 16.8 | 16.8 | 16.7 | 16.7 | 16.8 |
| | | Methyl ethyl ketone (MEK) | 30.3 | 30.3 | 30.1 | 30.1 | 30.3 |

TABLE 5

| | | | Photosensitive composition | |
|---|---|---|---|---|
| | | | Example 9A | Example 10A |
| | | | (X-9) | (X-10) |
| Formulation | Radically | 1,9-Nonanediol diacrylate | 6.45 | 6.45 |
| (part by | polymerizable | [A-NOD-N, manufactured by Shin-Nakamura Chemical Co., Ltd.] | | |
| mass) | monomer | Dipentaerythritol pentaacrylate | 3.02 | 3.02 |
| | | [KAYARAD DPHA, manufactured by Nippon Kayaku Co., Ltd.] | | |
| | | ARONIX TO-2349 [manufactured by Toagosei Co., Ltd.] | 1.45 | 1.45 |
| | | A-DCP [manufactured by Shin-Nakamura Chemical Co., Ltd.] | — | — |
| | | 8UX-015A [manufactured by Taisei Fine Chemical Co., Ltd.] | — | — |
| | | KAYARAD R-604 [manufactured by Nippon Kayaku Co., Ltd.] | — | — |
| | Alkali-soluble resin | Binder polymer P-1 | 41.8 | 41.8 |
| | | (solid content: 36.3% by mass, binder solution) | | |
| | | Binder polymer P-2 | — | — |
| | | (solid content: 36.3% by mass, binder solution) | | |
| | Photopolymerization | Irgacure OXE-02[ manufactured by BASF SE] | — | — |
| | initiator | Omnirad 379EG [manufactured by IGM Resins B. V.] | — | — |
| | | 1-(Bipheny1-4-y1)-2-methyl-2-morpholinopropan-1-one | — | — |
| | | [APi-307, manufactured by Shenzhen UV-Chem Tech Co., Ltd.] | | |
| | | 2,2′-Bis(2-chlorophenyl)-4,4′,5,5′-tetraphenyl-1,2′-biimidazole | 1.76 | 1.76 |
| | | [manufactured by Tokyo Chemical Industry Co., Ltd.] | | |
| | Sensitizer | SB-PI 701 [manufactured by SANYO TRADING CO., LTD.] | 0.02 | 0.02 |
| | Photoacid generator | Photoacid generator X | — | — |
| | | TPS-102 [manufactured by Midori Kagaku Co., Ltd.] | — | — |
| | Chain transfer agent | N-Phenylcarbamoylmethyl-N-carboxymethylaniline | 0.19 | 0.19 |
| | | [manufactured by FUJIFILM Wako Pure Chemical Corporation] | | |
| | | N-Phenylglycine | — | — |
| | | [manufactured by FUJIFILM Wako Pure Chemical Corporation] | | |
| | Polymerization | TDP-G | 0.09 | 0.09 |
| | inhibitor | [manufactured by Kawaguchi Chemical Industry Co., LTD.] | | |
| | Coloring material | Compound (2) | 7.02 | — |
| | precursor | Compound (65) | — | 7.02 |
| | | 2′-Anilino-6′-(dibutylamino)-3′-methylfluoran | — | — |
| | | [manufactured by Tokyo Chemical Industry Co., Ltd.] | | |
| | | BLACK 305 | — | — |
| | | [manufactured by Fukui Yamada Chemical Co.,Ltd.] | | |
| | Coloring material | Irgaphor Black S 0100CF [manufactured by BASF SE] | — | — |
| | Additive | MEGAFACE F551A [manufactured by DIC Corporation] | 0.31 | 0.31 |
| | | XIRAN EF-40 [manufactured by TOMOE Engineering Co., Ltd.] | — | — |
| | | Benzoimidazole | — | — |
| | | [manufactured by FUJIFILM Wako Pure Chemical Corporation] | | |
| | Solvent | 1-Methoxy-2-propyl acetate (MMPGAC) | 12.1 | 12.1 |
| | | Methyl ethyl ketone (MEK) | 25.7 | 25.7 |

### [Production of Transfer Film]

### Example 1B

The photosensitive composition X-1 of Example 1A was applied onto a temporary support [product name: LUMIRROR (registered trademark) 16KS40, biaxially stretched polyethylene terephthalate (PET) film, thickness: 16 μm, manufactured by Toray Industries, Inc.] using a slit-shaped nozzle with a coating amount such that a film thickness after drying was 15 μm, thereby forming a coating film. Next, the solvent in the formed coating film was volatilized in a drying zone at 100° C. to form a photosensitive composition layer. Next, a protective film [product name: LUMIRROR (registered trademark) 16KS40, biaxially stretched polyethylene terephthalate (PET) film, thickness: 16 μm, manufactured by Toray Industries, Inc.] was pressure-bonded to the formed photosensitive composition layer to produce a transfer film of Example 1B.

### Examples 2B to 16B

Transfer films of Examples 2B to 16B were produced by performing the same operation as in Example 1B, except that the type of the photosensitive composition and the film thickness of the photosensitive composition layer were as shown in Table 6.

### Comparative Examples 1B and 2B

Transfer films of Comparative Examples 1B and 2B were produced by performing the same operation as in Example 1B, except that the type of the photosensitive composition and the film thickness of the photosensitive composition layer were as shown in Table 6.

### [Measurement and Evaluation]

### <Measurement of Light Absorption Coefficient Before and After Coloring by Stimulus>

### 1. Absorbance and Light Absorption Coefficient Before Coloring

After peeling off the protective film from each of the transfer films of Examples 1B to 16B and Comparative Examples 1B and 2B, the exposed surface of the photosensitive composition layer was laminated with GORILLA GLASS (registered trademark) [thickness: 700 μm, manufactured by Corning Incorporated.] to obtain a laminate having a laminated structure of temporary support/photosensitive composition layer/GORILLA GLASS. As laminating conditions, a roll temperature was set to 110° C., a linear pressure was set to 0.6 MPa, and a linear speed (so-called laminating speed) was set to 2.0 m/min. The temporary support was peeled off from each of the produced laminates to produce a laminate X1.

An absorbance of the produced laminate X1 at a wavelength of 365 nm (denoted as “abs.” in the table; the same applies hereinafter) was measured using an ultraviolet-visible spectrophotometer [model number: UV-1800, manufactured by Shimadzu Corporation]. In addition, an absorbance per 1 μm of the film thickness (so-called light absorption coefficient) was determined by dividing the value of the absorbance obtained by the measurement by the film thickness. The results are shown in Table 6.

2. Absorbance and Light Absorption Coefficient after Coloring

### (1) Examples 1B to 6B and 9B to 16B, and Comparative Examples 1B and 2B

After peeling off the protective film from the transfer film, the exposed surface of the photosensitive composition layer was laminated with GORILLA GLASS (registered trademark) [thickness: 700 μm, manufactured by Corning Incorporated.] to obtain a laminate having a laminated structure of temporary support/photosensitive composition layer/GORILLA GLASS. As laminating conditions, a roll temperature was set to 110° C., a linear pressure was set to 0.6 MPa, and a linear speed (so-called laminating speed) was set to 2.0 m/min. Next, the produced laminate was exposed with i-rays (wavelength: 365 nm) at an exposure amount of 150 mJ/cm² using a proximity type exposure machine [manufactured by Hitachi High-Tech Electronics Engineering Co., Ltd.] having an ultra-high pressure mercury lamp, without peeling off the temporary support. After the exposure, the temporary support of the laminate was peeled off after being left to stand for 1 hour. Next, the laminate after peeling off the temporary support was further exposed with i-rays (wavelength: 365 nm) at an exposure amount of 1,000 mJ/cm², and then allowed to stand for 1 hour. Next, the laminate after the standing was subjected to a heating treatment for 5 minutes using convection in which the temperature in the chamber was set to 210° C., thereby producing a laminate Y¹.

### (2) Examples 7B and 8B

After peeling off the protective film from the transfer film, the exposed surface of the photosensitive composition layer was laminated with GORILLA GLASS (registered trademark) [thickness: 700 μm, manufactured by Corning Incorporated.] to obtain a laminate having a laminated structure of temporary support/photosensitive composition layer/GORILLA GLASS. As laminating conditions, a roll temperature was set to 110° C., a linear pressure was set to 0.6 MPa, and a linear speed (so-called laminating speed) was set to 2.0 m/min. Next, the produced laminate was exposed with i-rays (wavelength: 365 nm) at an exposure amount of 150 mJ/cm² using a proximity type exposure machine [manufactured by Hitachi High-Tech Electronics Engineering Co., Ltd.] having an ultra-high pressure mercury lamp, without peeling off the temporary support. After the exposure, the temporary support of the laminate was peeled off after being left to stand for 1 hour. Next, the laminate after peeling off the temporary support was further exposed with i-rays (wavelength: 365 nm) at an exposure amount of 1,000 mJ/cm², and then allowed to stand for 1 hour. Next, the laminate after the standing was immersed in a hydrochloric acid aqueous solution having a concentration of 10% by mass for 20 minutes in an environment of an atmosphere temperature of 25° C. Next, the laminate after the immersion was subjected to a heating treatment for 5 minutes using convection in which the temperature in the chamber was set to 210° C., thereby producing a laminate Y¹.

### (3) Observation and Measurement

The produced laminate Y¹ was visually observed. As a result, it was confirmed that all the laminates Y¹ appeared black.

In addition, an absorbance of the produced laminate Y¹ at a wavelength of 365 nm and an average absorbance of the produced laminate Y¹ in a wavelength of 400 nm to 700 nm (denoted as “Average abs.” in the table; the same applies hereinafter) was measured using an ultraviolet-visible spectrophotometer [model number: UV-1800, manufactured by Shimadzu Corporation]. In addition, an absorbance and average absorbance per 1 μm of the film thickness was determined by dividing the value of the absorbance of the laminate Y¹ at a wavelength of 365 nm and the value of the average absorbance in a wavelength of 400 nm to 700 nm, which were obtained by the measurement, by the film thickness, respectively. The results are shown in Table 6.

### 3. Aspect Ratio

### (1) Examples 1B to 6B and 9B to 16B, and Comparative Examples 1B and 2B

After peeling off the protective film from the transfer film, the exposed surface of the photosensitive composition layer was laminated with a PET film having a thickness of 50 μm [product name: COSMOSHINE (registered trademark) A⁴³⁶⁰, manufactured by TOYOBO Co., Ltd.] to obtain a laminate having a laminated structure of temporary support/photosensitive composition layer/PET film. As laminating conditions, a roll temperature was set to 110° C., a linear pressure was set to 0.6 MPa, and a linear speed (so-called laminating speed) was set to 2 m/min. Next, the produced laminate was exposed with i-rays (wavelength: 365 nm) at an exposure amount of 150 mJ/cm² using a proximity type exposure machine [manufactured by Hitachi High-Tech Electronics Engineering Co., Ltd.] having an ultra-high pressure mercury lamp and using a photo mask, without peeling off the temporary support. The photo mask had a line (L)/space(S) pattern in which a line width was changed every 1 μm in a range of 1 μm to 100 μm. After the exposure, the temporary support was peeled off from the laminate. Next, the photosensitive composition layer was developed for 30 seconds using a potassium carbonate aqueous solution having a concentration of 1% by mass (liquid temperature: 30° C.), rinsed with a shower of pure water, and dried at 75° C. for 13 seconds, thereby removing the photosensitive composition layer in a non-exposed portion. Furthermore, the photosensitive composition layer was exposed with i-rays (wavelength: 365 nm) at an exposure amount of 1,000 mJ/cm² to be cured. Next, the laminate in which the photosensitive composition layer was cured was subjected to a heating treatment for 10 minutes using convection in which the temperature in the chamber was set to 210° C., thereby producing a laminate Z1 having a pattern.

### (2) Examples 7B and 8B

After peeling off the protective film from the transfer film, the exposed surface of the photosensitive composition layer was laminated with a PET film having a thickness of 50 μm [product name: COSMOSHINE (registered trademark) A⁴³⁶⁰, manufactured by TOYOBO Co., Ltd.] to obtain a laminate having a laminated structure of temporary support/photosensitive composition layer/PET film. As laminating conditions, a roll temperature was set to 110° C., a linear pressure was set to 0.6 MPa, and a linear speed (so-called laminating speed) was set to 2 m/min. Next, the produced laminate was exposed with i-rays (wavelength: 365 nm) at an exposure amount of 150 mJ/cm² using a proximity type exposure machine [manufactured by Hitachi High-Tech Electronics Engineering Co., Ltd.] having an ultra-high pressure mercury lamp and using a photo mask, without peeling off the temporary support. The photo mask had a line (L)/space(S) pattern in which a line width was changed every 1 μm in a range of 1 μm to 100 μm. After the exposure, the temporary support was peeled off from the laminate. Next, the photosensitive composition layer was developed for 30 seconds using a potassium carbonate aqueous solution having a concentration of 1% by mass (liquid temperature: 30° C.), rinsed with a shower of pure water, and dried at 75° C. for 13 seconds, thereby removing the photosensitive composition layer in a non-exposed portion.

Furthermore, the photosensitive composition layer was exposed with i-rays (wavelength: 365 nm) at an exposure amount of 1,000 mJ/cm² to be cured. Next, the laminate in which the photosensitive composition layer was cured was immersed in a hydrochloric acid aqueous solution having a concentration of 10% by mass for 20 minutes in an environment of an atmosphere temperature of 25° C. Next, the laminate after the immersion was subjected to a heating treatment for 10 minutes using convection in which the temperature in the chamber was set to 210° C., thereby producing a laminate Z1 having a pattern.

### (3) Observation and Measurement

The produced laminate Z1 was visually observed. As a result, it was confirmed that all the laminates Z1 appeared black.

In addition, the cross section of the produced laminate Z1 was observed using a scanning electron microscope (SEM), a film thickness of the pattern and the minimum line width resolved were measured, and an aspect ratio was determined by the following expression. The “minimum line width resolved” refers to a line width of a bottom portion of a pattern having the smallest line width among patterns in which residues were not confirmed in a case where the space portion was observed with an optical microscope. The results are shown in Table 6.

“Aspect ratio”=“Film thickness”/“Minimum line width resolved”

### 4. Line Width of Uppermost Portion/Line Width of Bottom Portion

A laminate Z1 was produced by performing the same operation as in “3. Aspect ratio”.

A cross section of the produced laminate Z1 was observed using a scanning electron microscope (SEM), and a line width of the bottom portion and a line width of the uppermost portion of the pattern having the minimum line width resolved state were measured to obtain a ratio of the line width of the uppermost portion to the line width of the bottom portion (Line width of uppermost portion/Line width of bottom portion). The results are shown in Table 6.

As the ratio of the line width of the uppermost portion to the line width of the bottom portion is closer to 1, the pattern has more excellent rectangularity.

### 5. Thermal Stability

An absorbance of the laminate Y1 produced in “2. Absorbance and light absorption coefficient after coloring” at a wavelength of 550 nm was measured using an ultraviolet-visible spectrophotometer [model number: UV-1800, manufactured by Shimadzu Corporation], and the obtained value was divided by the film thickness to obtain an absorbance per 1 μm of the film thickness (so-called light absorption coefficient). The obtained light absorption coefficient is referred to as “light absorption coefficient before heating treatment”.

Next, the laminate Y1 was subjected to a heating treatment for 60 minutes using convection in which the temperature in the chamber was set to 230° C. An absorbance of a laminate B after the heating treatment at a wavelength of 550 nm was measured using an ultraviolet-visible spectrophotometer [model number: UV-1800, manufactured by Shimadzu Corporation], and the obtained value was divided by the film thickness to obtain an absorbance per 1 μm of the film thickness (so-called light absorption coefficient). The obtained light absorption coefficient is referred to as “light absorption coefficient after heating treatment”.

A difference in light absorption coefficient before and after the heating treatment was obtained by the following expression, and thermal stability after coloring or after coloration was evaluated according to the following evaluation standard. The evaluation results are shown in Table 6.

“Difference in light absorption coefficient before and after heating treatment”=“Light absorption coefficient before heating treatment”−“Light absorption coefficient after heating treatment”

### —Evaluation Standard—

A: difference in light absorption coefficient before and after the heating treatment was less than 0.01.
B: difference in light absorption coefficient before and after the heating treatment was in a range of 0.01 or more and less than 0.1.
C: difference in light absorption coefficient before and after the heating treatment was in a range of 0.1 or more and less than 0.5.
D: difference in light absorption coefficient before and after the heating treatment was 0.5 or more.

The evaluation result is preferably “A”, “B”, or “C”

As the difference in light absorption coefficient before and after the heating treatment is smaller, it is difficult for the film after coloring or after coloration to fade due to heat, and the thermal stability is excellent.

TABLE 6

| | | Film thick- | | | | | | | | | |
|---|---|---|---|---|---|---|---|---|---|---|---|
| | | ness of | Measurement and evaluation | | | | | | | | |
| | | photo- | | | | | | | | Line width | |
| | | sensitive | | | | | | | | of uppermost | |
| | Type of | compo- | | | | abs.@365 | abs.@365 | Average | | portion/line | |
| | photo- | sition | abs.@365 | abs.@365 | Average | nm before | nm after | abs. after | | width of | |
| | sensitive | layer | nm before | nm after | abs. after | coloring | coloring | coloring | Aspect | bottom | Thermal |
| | composition | [μm] | coloring | coloring | coloring | (per 1 μm) | (per 1 μm) | (per 1 μm) | ratio | portion | stability |
| Example 1B | X-1 | 15 | 0.3 | 3.3 | 2.9 | 0.02 | 0.22 | 0.19 | 1.9 | 1.1 | B |
| Example 2B | X-2 | 10 | 0.2 | 2.0 | 2.1 | 0.02 | 0.20 | 0.21 | 2.0 | 1.0 | B |
| Example 3B | X-2 | 15 | 0.3 | 3.0 | 3.1 | 0.02 | 0.20 | 0.21 | 1.9 | 1.0 | B |
| Example 4B | X-2 | 20 | 0.4 | 4.0 | 4.2 | 0.02 | 0.20 | 0.21 | 2.0 | 1.1 | B |
| Example 5B | X-3 | 15 | 0.3 | 2.9 | 3.0 | 0.02 | 0.19 | 0.20 | 1.9 | 1.0 | B |
| Example 6B | X-4 | 15 | 0.3 | 3.1 | 3.0 | 0.02 | 0.21 | 0.20 | 1.9 | 1.0 | B |
| Example 7B | X-5 | 15 | 0.3 | 2.4 | 2.1 | 0.02 | 0.16 | 0.14 | 1.0 | 1.0 | C |
| Example 8B | X-6 | 15 | 0.3 | 2.5 | 2.1 | 0.02 | 0.17 | 0.14 | 1.0 | 1.0 | C |
| Example 9B | X-7 | 15 | 0.4 | 3.3 | 3.2 | 0.02 | 0.22 | 0.21 | 1.3 | 1.2 | C |
| Example 10B | X-8 | 15 | 0.4 | 3.1 | 3.0 | 0.03 | 0.21 | 0.20 | 1.3 | 1.2 | C |
| Example 11B | X-9 | 10 | 0.2 | 2.1 | 2.1 | 0.02 | 0.21 | 0.21 | 2.0 | 1.0 | A |
| Example 12B | X-9 | 15 | 0.2 | 3.1 | 3.2 | 0.01 | 0.21 | 0.21 | 1.9 | 1.0 | A |
| Example 13B | X-9 | 20 | 0.2 | 4.2 | 4.3 | 0.01 | 0.21 | 0.22 | 2.0 | 1.0 | A |
| Example 14B | X-10 | 10 | 0.2 | 2.0 | 2.1 | 0.02 | 0.20 | 0.21 | 2.0 | 1.1 | B |
| Example 15B | X-10 | 15 | 0.2 | 3.0 | 3.1 | 0.01 | 0.20 | 0.21 | 1.9 | 1.0 | B |
| Example 16B | X-10 | 20 | 0.2 | 4.0 | 4.2 | 0.01 | 0.20 | 0.21 | 2.0 | 1.0 | B |
| Comparative | Y-1 | 10 | 2.2 | 2.2 | 2.1 | 0.22 | 0.22 | 0.21 | Less | 5.0 | A |
| Example 1B | | | | | | | | | than | | |
| | | | | | | | | | 0.1 | | |
| Comparative | Y-1 | 15 | 3.3 | 3.3 | 3.2 | 0.22 | 0.22 | 0.21 | Less | 6.7 | A |
| Example 2B | | | | | | | | | than | | |
| | | | | | | | | | 0.15 | | |

From the results shown in Table 6, it was found that the photosensitive compositions X-1 to X-10 according to the present disclosure could form a film having excellent light shielding properties and have excellent patterning properties.

In addition, it was found that, with the photosensitive compositions X-1 to X-10 according to the present disclosure, a pattern having excellent light shielding properties and rectangularity could be formed.

It was found that the photosensitive compositions X-1 to X-6, X-9, and X-10 according to the present disclosure, containing the coloring material precursor which colored black by heat, were less likely to fade after coloring by heat, and could form a film having more excellent thermal stability.

### Example 1C

The photosensitive composition X-1 was applied onto a glass substrate [product name: EAGLE (registered trademark) XG, thickness: 700 μm, manufactured by Corning Incorporated.] using a slit-shaped nozzle with a coating amount such that a film thickness after drying was 15 μm, thereby forming a coating film. Next, the solvent in the formed coating film was volatilized in a drying zone at 100° C. to form a photosensitive composition layer, thereby producing a laminate X² having a laminated structure of glass substrate/photosensitive composition layer.

In addition, in a case where an absorbance of the produced laminate X² at a wavelength of 365 nm was measured in the same manner as the laminate X¹ in Example 1B using an ultraviolet-visible spectrophotometer [model number: UV-1800, manufactured by Shimadzu Corporation], the same value as that of the laminate X¹ in Example 1B was obtained.

In addition, the laminate X² produced as described above was exposed with i-rays (wavelength: 365 nm) at an exposure amount of 150 mJ/cm² using a proximity type exposure machine [manufactured by Hitachi High-Tech Electronics Engineering Co., Ltd.] having an ultra-high pressure mercury lamp, without peeling off the temporary support, and than allowed to stand for 1 hour. Next, the laminate X² after the standing was further exposed with i-rays (wavelength: 365 nm) at an exposure amount of 1,000 mJ/cm², and then allowed to stand for 1 hour. Next, the laminate X² after the standing was subjected to a heating treatment for 5 minutes using convection in which the temperature in the chamber was set to 210° C., thereby producing a laminate Y².

The produced laminate Y² was visually observed, and it was confirmed that the laminate Y² appeared black.

In addition, in a case where an absorbance of the produced laminate Y² at a wavelength of 365 nm and an average absorbance in a wavelength of 400 nm to 700 nm were measured using an ultraviolet-visible spectrophotometer [model number: UV-1800, manufactured by Shimadzu Corporation], and an absorbance and average absorbance per 1 μm of the film thickness was determined in the same manner as the laminate Y¹ in Example 1B, the same values as those of the laminate Y¹ in Example 1B were obtained.

In addition, the laminate X² produced as described above was exposed with i-rays (wavelength: 365 nm) at an exposure amount of 150 mJ/cm² using a proximity type exposure machine [manufactured by Hitachi High-Tech Electronics Engineering Co., Ltd.] having an ultra-high pressure mercury lamp and using a photo mask, without peeling off the temporary support. The photo mask had a line (L)/space(S) pattern in which a line width was changed every 1 μm in a range of 1 μm to 100 μm. After the exposure, the temporary support was peeled off from the laminate. Next, the photosensitive composition layer was developed for 30 seconds using a potassium carbonate aqueous solution having a concentration of 1% by mass (liquid temperature: 30° C.), rinsed with a shower of pure water, and dried at 75° C. for 13 seconds, thereby removing the photosensitive composition layer in a non-exposed portion. Furthermore, the photosensitive composition layer was exposed with i-rays (wavelength: 365 nm) at an exposure amount of 1,000 mJ/cm² to be cured. Next, the laminate in which the photosensitive composition layer was cured was subjected to a heating treatment for 10 minutes using convection in which the temperature in the chamber was set to 210° C., thereby producing a laminate Z2 having a pattern.

The produced laminate Z2 was visually observed, and it was confirmed that the laminate Z2 appeared black.

In addition, in a case where an aspect ratio of the pattern of and a ratio of the line width of the uppermost portion to the line width of the bottom portion in the produced laminate Z2 were determined in the same manner as the laminate Z1 in Example 1B, the same values as those of the laminate Z1 in Example 1B were obtained.

In addition, in a case where the laminate Y² produced as described above was subjected to the evaluation test of thermal stability in the same manner as the laminate Y¹ in Example 1B, the same result as the result of the laminate Y¹ in Example 1B was obtained.

The disclosure of Japanese Patent Application No. 2022-106690 filed on Jun. 30, 2022 and the disclosure of Japanese Patent Application No. 2023-015691 filed on Feb. 3, 2023 are incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A photosensitive composition comprising:
a coloring material precursor which colors black by a stimulus.

2. The photosensitive composition according to claim 1,
wherein the stimulus is at least one selected from the group consisting of heat, light, acid, base, and radical.

3. The photosensitive composition according to claim 1,
wherein the stimulus is heat.

4. The photosensitive composition according to claim 1, further comprising:
an alkali-soluble resin;
a polymerizable monomer; and
a photopolymerization initiator.

5. The photosensitive composition according to claim 1,
wherein, in a case where a film having a film thickness of 1 μm is formed of the photosensitive composition, an absorbance of the film at a wavelength of 365 nm is 0.1 or less.

6. The photosensitive composition according to claim 1,
wherein, in a case where a black film having a film thickness of 1 μm is formed of the photosensitive composition by coloring the coloring material precursor by the stimulus in black, an absorbance of the film at a wavelength of 365 nm is 0.2 or more.

7. The photosensitive composition according to claim 1,
wherein, in a case where a black film having a film thickness of 1 μm is formed of the photosensitive composition by coloring the coloring material precursor by the stimulus in black, an average absorbance of the film in a wavelength of 400 nm to 700 nm is 0.2 or more.

8. The photosensitive composition according to claim 1,
wherein the coloring material precursor is a compound represented by Formula (1), 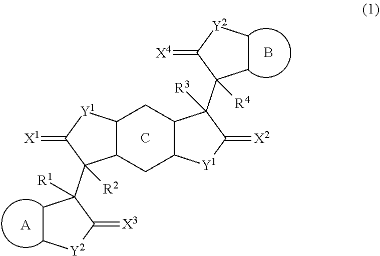
in Formula (1), X¹, X², X³, X⁴, Y¹, and Y² each independently represent an oxygen atom, a sulfur atom, or N-L¹, L¹ represents a hydrogen atom, an alkyl group, an acyl group, an alkoxycarbonyl group, or an aminocarbonyl group, R¹, R², R³, and R⁴ each independently represent a hydrogen atom, —O-L², —OCO-L³, —S-L², or —OSO-L³, L² represents a hydrogen atom or an alkyl group and L³ represents an alkyl group or an amino group, provided that at least one of R¹ or R² represents a hydrogen atom and at least one of R³ or R⁴ represents a hydrogen atom, and A, B, and C each independently represent an aromatic ring.

9. A photosensitive composition comprising:
a coloring material precursor which colors black by at least one stimulus selected from the group consisting of heat, light, acid, base, and radical;
an alkali-soluble resin;
a polymerizable monomer; and
a photopolymerization initiator,
wherein all of the following (1) to (3) are satisfied,
(1) in a case where a film having a film thickness of 1 μm is formed of the photosensitive composition, an absorbance of the film at a wavelength of 365 nm is 0.1 or less,
(2) in a case where a black film having a film thickness of 1 μm is formed of the photosensitive composition by coloring the coloring material precursor by the stimulus in black, an absorbance of the film at a wavelength of 365 nm is 0.2 or more,
(3) in a case where a black film having a film thickness of 1 μm is formed of the photosensitive composition by coloring the coloring material precursor by the stimulus in black, an average absorbance of the film in a wavelength of 400 nm to 700 nm is 0.2 or more.

10. The photosensitive composition according to claim 9,
wherein the coloring material precursor is a compound represented by Formula (1), 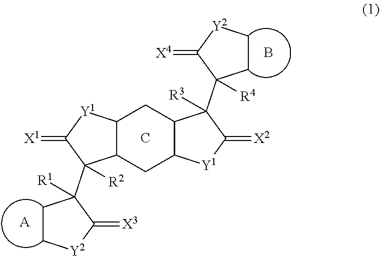
in Formula (1), X¹, X², X³, X⁴, Y¹, and Y² each independently represent an oxygen atom, a sulfur atom, or N-L¹, L¹ represents a hydrogen atom, an alkyl group, an acyl group, an alkoxycarbonyl group, or an aminocarbonyl group, R¹, R², R³, and R⁴ each independently represent a hydrogen atom, —O-L², —OCO-L³, —S-L², or —OSO-L³, L² represents a hydrogen atom or an alkyl group and L³ represents an alkyl group or an amino group, provided that at least one of R¹ or R² represents a hydrogen atom and at least one of R³ or R⁴ represents a hydrogen atom, and A, B, and C each independently represent an aromatic ring.

11. A transfer film comprising:
a temporary support; and
a photosensitive composition layer containing the photosensitive composition according to claim 1.

12. The transfer film according to claim 11,
wherein a film thickness of the photosensitive composition layer is 5 μm or more.

13. A manufacturing method of a laminate having a black pattern, the manufacturing method comprising, in the following order:
forming a photosensitive composition layer containing the photosensitive composition according to claim 1 on a base material;
performing pattern exposure on the photosensitive composition layer; and
developing the photosensitive composition layer,
wherein the manufacturing method further includes, after the pattern exposure, coloring the coloring material precursor in black.

14. The manufacturing method of a laminate according to claim 13,
wherein a film thickness of the black pattern is 5 μm or more.

15. A laminate having a black pattern, which is a laminate manufactured by the manufacturing method of a laminate according to claim 13.

16. The laminate according to claim 15,
wherein a film thickness of the black pattern is 5 μm or more.

17. The laminate according to claim 15,
wherein an absorbance of the black pattern at a wavelength of 365 nm is 2.0 or more.

18. The laminate according to claim 15,
wherein an average absorbance of the black pattern in a wavelength of 400 nm to 700 nm is 2.0 or more.

19. The laminate according to claim 15,
wherein an aspect ratio of the black pattern, which is a ratio of a film thickness to a line width of a bottom portion, is 1.0 or more.

20. A laminate comprising:
a base material; and
a black pattern,
wherein a film thickness of the black pattern is 5 μm or more,
an aspect ratio of the black pattern, which is a ratio of a film thickness to a line width of a bottom portion, is 1.0 or more, and
an average absorbance in a wavelength of 400 nm to 700 nm is 2.0 or more.

21. The laminate according to claim 20,
wherein a ratio of the black pattern of a line width of an uppermost portion to a line width of a bottom portion is 0.8 to 1.2.

22. The laminate according to claim 20,
wherein the black pattern contains a coloring material represented by Formula (I), 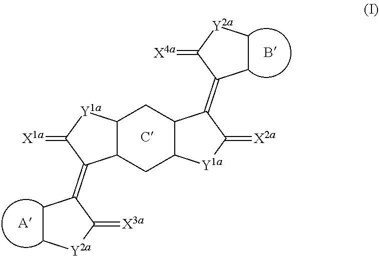
in Formula (I), X^{1a}, X^{2a}, X^{3a}, X^{4a}, Y^{1a}, and Y^{2a} each independently represent an oxygen atom, a sulfur atom, or N-L^{1a}, L^{1a} represents a hydrogen atom, an alkyl group, an acyl group, an alkoxycarbonyl group, or an aminocarbonyl group, and A′, B′, and C′ each independently represent an aromatic ring.

23. A micro LED display comprising:
the laminate according to claim 20.
